(19) United States
(12) Patent Application Publication
(10) Pub. No.: US 2024/0117250 A1
(43) Pub. Date: Apr. 11, 2024

(54) PHOTO-ALIGNMENT THERMOSETTING LIQUID CRYSTAL COMPOSITION, ALIGNMENT FILM-CUM-RETARDATION FILM AND PRODUCTION METHOD THEREFOR, RETARDATION PLATE AND PRODUCTION METHOD THEREFOR, OPTICAL MEMBER AND PRODUCTION METHOD THEREFOR, AND DISPLAY DEVICE

(71) Applicant: DAI NIPPON PRINTING CO., LTD., Tokyo-to (JP)

(72) Inventors: Shunsuke IRIE, Tokyo-to (JP); Ken-ichi OKUYAMA, Tokyo-to (JP); Kazuyuki OKADA, Tokyo-to (JP); Terutaka TAKAHASHI, Tokyo-to (JP); Kei AKIYAMA, Tokyo-to (JP)

(73) Assignee: DAI NIPPON PRINTING CO., LTD., Tokyo-to (JP)

(21) Appl. No.: 18/273,682

(22) PCT Filed: Jan. 21, 2022
(86) PCT No.: PCT/JP2022/002123

§ 371 Date: Jul. 21, 2023

(30) Foreign Application Priority Data
Jan. 25, 2021 (JP) 2021-009570
Jan. 25, 2021 (JP) 2021-009571

(51) Int. Cl. C09K 19/38; C09K 19/56; G02B 5/30; G02F 1/13363

(52) U.S. Cl. CPC C09K 19/3852; C09K 19/56; G02B 5/3016; G02F 1/133633

(57) ABSTRACT

A photo-alignment thermosetting liquid crystal composition including: a side-chain liquid crystal polymer which contains a liquid crystal constitutional unit containing a liquid crystal moiety in a side chain and a non-liquid crystal constitutional unit containing an alkylene group in a side chain, a copolymer which contains a photo-alignment constitutional unit containing a photo-alignment group in a side chain and a thermally crosslinkable constitutional unit containing a thermally crosslinkable group in a side chain, and in which the photo-alignment constitutional unit does not contain a linear alkylene group between the photo-alignment group and a monomer unit, and a thermal crosslinking agent for bonding to the thermally crosslinkable group of the thermally crosslinkable constitutional unit.

### TECHNICAL FIELD

The present disclosure relates to a photo-alignment thermosetting liquid crystal composition configured to form an alignment layer-cum-retardation layer that functions as both an alignment layer and a retardation layer solely. The present disclosure also relates to an alignment film-cum-retardation film, a method for producing the alignment film-cum-retardation film, a retardation plate, a method for producing the retardation plate, an optical member, a method for producing the optical member, and a display device.

### BACKGROUND ART

A retardation plate that gives desired retardation to incident light by its retardation layer, is one of optical films applicable to image display devices or the like. For example, in organic electroluminescent (organic EL) display devices, a combination of a quarter wavelength retardation plate and a linear polarizing plate is used as a circularly polarizing plate and functions as an external light antireflection film. In liquid crystal display devices such as an IPS mode, for the purpose of increasing contrast with respect to the field of view from an oblique direction, a retardation plate which is a combination of a positive A plate having a positive A property and a positive C plate having a positive C property, has been hitherto used as a part of a polarizing plate compensation film (for example, see Patent Document 1).

The positive A plate and the positive C plate have been hitherto stacked by bonding them with an adhesive layer or the like.

With the thickness reduction of display devices, a structure that enables thickness reduction, while maintaining the performance and improved efficiency of production processes, is required of retardation plates such as a broadband quarter wavelength retardation plate, which is composed of a combination of retardation plates and has been suggested as a solution to the above problem.

For the purpose of thickness reduction of retardation plates, an optical film laminate is disclosed in Patent Document 2. The optical film laminate includes a stack of a positive C plate and a positive A plate; in the positive C plate, the alignment of a homeotropic alignment layer formed from a first liquid crystal material having the photosensitive group, is fixed; in the positive A plate, the alignment of a homogeneous alignment layer formed from a second polymerizable liquid crystal material is fixed; the positive A plate is directly stacked on the positive C plate; and the photosensitive group in the positive C plate is anisotropically photoreacted.

In Patent Document 3, a photo-alignment thermosetting liquid crystal composition is disclosed by the inventors of the present disclosure, for the purpose of providing a high-sensitive, photo-alignment thermosetting liquid crystal composition comprising a copolymer having a photo-alignment moiety and a thermally-crosslinking moiety, and an alignment layer thereof. The thermosetting composition contains a crosslinking agent and a copolymer of a styrene monomer that contains a photo-alignment group and a monomer that contains a thermally crosslinkable group. In Patent Document 3, however, it is not mentioned that a retardation layer is formed by use of the thermosetting composition.

### CITATION LIST

### Patent Documents

Patent Document 1: Japanese Patent No. 4592005
Patent Document 2: Japanese Patent Application Laid-Open (JP-A) No. 2016-004142
Patent Document 3: Japanese Patent No. 5626493

### SUMMARY OF INVENTION

### Technical Problem

In Patent Document 2, the positive A plate is directly stacked on the positive C plate, for the purpose of thickness reduction of retardation plates. In Patent Document 2, however, the positive C plate is formed by use of the first liquid crystal material having a structure such that as the photosensitive group, a photo-alignment group is bound to the terminal of a liquid crystal component having a homeotropic alignment property. Accordingly, the homeotropic alignment property of the positive C plate itself is poor; moreover, a liquid crystal aligning ability, that is, the ability of aligning the liquid crystal material of the directly stacked positive A plate is poor. In addition, the positive C plate of Patent Document 2 has insufficient durability, and there is a problem in that the homeotropic alignment property of the positive C plate is likely to be changed by heating or solvent permeation when the liquid crystal material of the positive A plate is stacked on the positive C plate.

The retardation plate obtained by directly stacking the positive A plate on the positive C plate, which is a cured product of a photocurable resin composition containing a polymerizable liquid crystal compound, has the following problems: the adhesion between the positive C plate and the positive A plate is insufficient, and the flex resistance of the retardation plate is poor. This is because the positive C plate is the cured product of the photocurable resin composition, and when the photocurable resin composition is sufficiently cured to improve the homeotropic alignment property, the cured product becomes hard and brittle. When the adhesion is insufficient, there is a problem in that when transferring the positive A and positive C plates, the positive C plate cannot be transferred and is left on the substrate. When the flex resistance is poor, there is a problem in that the retardation plate is unsuitable for use in flexible displays.

The present disclosure was achieved in light of the above circumstances. The first object of the present disclosure is to provide the following: a photo-alignment thermosetting liquid crystal composition capable of forming an alignment layer-cum-retardation layer having an excellent homeotropic alignment property and an excellent ability of aligning the directly stacked liquid crystal material; an alignment film-cum-retardation film; a method for producing the alignment film-cum-retardation film; a retardation plate comprising the alignment layer-cum-retardation layer; a method for producing the retardation plate; an optical member; a method for producing the optical member; and a display device.

Also, the present disclosure was achieved in light of the above circumstances, and the second object of the present disclosure is to provide the following: a photo-alignment thermosetting liquid crystal composition capable of forming an alignment layer-cum-retardation layer having a good homeotropic alignment property, having an ability of aligning the directly stacked liquid crystal material and having durability; an alignment film-cum-retardation film; a method for producing the alignment film-cum-retardation film; a retardation plate comprising the alignment layer-cum-retardation layer; a method for producing the retardation plate; an optical member; a method for producing the optical member; and a display device.

Also, the present disclosure was achieved in light of the above circumstances, and the third object of the present disclosure is to provide the following: a retardation plate in which the positive C type retardation layer and the positive A type retardation layer are directly stacked in good adhesion and which has good flex resistance; a method for producing the retardation plate; an optical member; the method for producing the optical member; and a display device.

### Solution to Problem

To achieve the first object, in the present disclosure, there is provided a first photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a constitutional unit represented by the following formula (1) and a thermally crosslinkable constitutional unit containing a thermally crosslinkable group in a side chain, and
a thermal crosslinking agent (C) for bonding to the thermally crosslinkable group of the thermally crosslinkable constitutional unit:

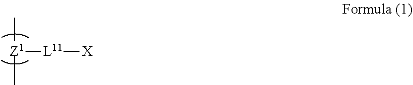

where Z¹ is at least one kind of monomer unit selected from the group consisting of the following formulae (1-1) to (1-6); X is a photo-alignment group; and L¹¹ is a single bond, —O—, —S—, —COO—, —COS—, —CO—, —OCO— or a combination of any of them with an arylene group:

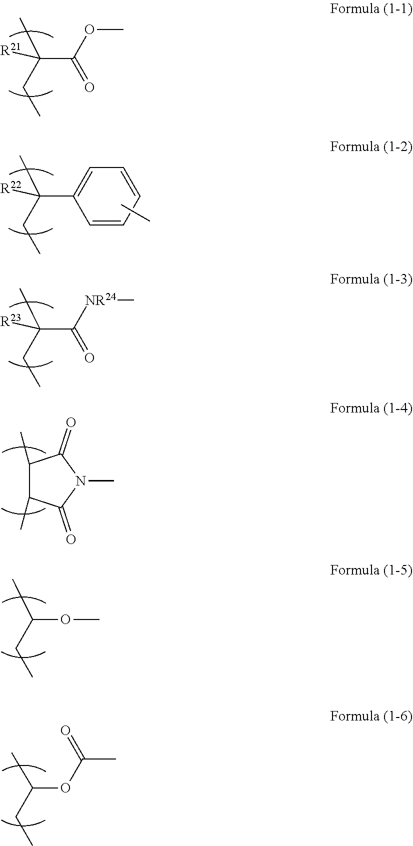

where R²¹ is a hydrogen atom, a methyl group, a chlorine atom or a phenyl group; R²² is a hydrogen atom or a methyl group; R²³ is a hydrogen atom, a methyl group, a chlorine atom or a phenyl group; and R²⁴ is a hydrogen atom or an alkyl group containing 1 to 4 carbon atoms).

In the first photo-alignment thermosetting liquid crystal composition of the present disclosure, the photo-alignment group of the copolymer (B) may be at least one kind selected from the group consisting of a cinnamoyl group, a chalcone group, a coumarin group, an anthracene group, a quinoline group, an azobenzene group and a stilbene group.

In the first photo-alignment thermosetting liquid crystal composition of the present disclosure, the thermally crosslinkable group may contain at least one kind selected from the group consisting of a hydroxy group, a carboxy group, a mercapto group, a glycidyl group, an amino group an amide group.

In the first photo-alignment thermosetting liquid crystal composition of the present disclosure, from the viewpoint of improving the homeotropic alignment property of the retardation layer, the liquid crystal constitutional unit of the side-chain liquid crystal polymer (A) preferably contain a constitutional unit represented by the following formula (I):

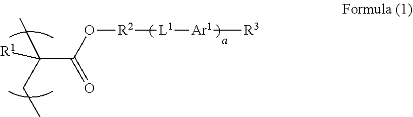

where R¹ is a hydrogen atom or a methyl group; R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; Lis may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.

To achieve the second object, in the present disclosure, there is provided a second photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a photo-alignment group in a side chain and a thermally crosslinkable constitutional unit containing a constitutional unit represented by the following formula (2), and
a thermal crosslinking agent (C) for bonding to a thermally crosslinkable group of the thermally crosslinkable constitutional unit,
wherein the side-chain liquid crystal polymer (A) satisfies any of the following (i) to (vi).

To achieve the second object, the structure of the second photo-alignment thermosetting liquid crystal composition may be applied to the first photo-alignment thermosetting liquid crystal composition.

(i) The side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a primary carbon of the alkylene group which optionally contains —O— in its carbon chain and in which a total of a carbon atom number and an oxygen atom number is smaller than a linear alkylene group which contains 4 to 11 carbon atoms and which optionally contains —O— in its carbon chain in the thermally crosslinkable constitutional unit of the copolymer (B);

(ii) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a secondary or tertiary carbon of the alkylene group;

(iii) the side-chain liquid crystal polymer (A) contains a non-liquid crystal, thermally crosslinkable constitutional unit containing, in a side chain, an arylene group, an alkylene group and at least one kind of thermally crosslinkable group selected from the group consisting of a hydroxy group, a mercapto group and an amino group, and the non-liquid crystal, thermally crosslinkable constitutional unit of the side-chain liquid crystal polymer (A) has a structure such that the thermally crosslinkable group is bound to the arylene group;

(iv) the side-chain liquid crystal polymer (A) contains a non-liquid crystal, thermally crosslinkable constitutional unit containing an arylene group, an alkylene group and at least one kind of thermally crosslinkable group selected from the group consisting of a carboxy group, a glycidyl group and an amide group; the non-liquid crystal, thermally crosslinkable constitutional unit of the side-chain liquid crystal polymer (A) has a structure such that the thermally crosslinkable group is bound to the arylene group; and the arylene group has a structure such that it is bound to a carbon or oxygen atom of the alkylene group which optionally contains —O— in its carbon chain or at its terminal and in which a total of a carbon atom number and an oxygen atom number is 3 or more smaller than the linear alkylene group which contains 4 to 11 carbon atoms and which optionally contains —O— in the carbon chain in the thermally crosslinkable constitutional unit of the copolymer (B);

(v) the side-chain liquid crystal polymer (A) contains a thermally crosslinkable constitutional unit containing no alkylene group in a side chain and a thermally crosslinkable group in the side chain; and

(vi) the side-chain liquid crystal polymer (A) does not contain a non-liquid crystal, thermally crosslinkable constitutional unit containing a thermally crosslinkable group and an alkylene group in a side chain and a thermally crosslinkable constitutional unit containing a thermally crosslinkable group in a side chain:

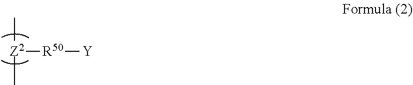

where Z² is at least one kind of monomer unit selected from the group consisting of the following formulae (2-1) to (2-6); R⁵⁰ is a linear alkylene group containing 4 to 11 carbon atoms and optionally containing—O— in its carbon chain; and Y is at least one kind of thermally crosslinkable group selected from the group consisting of a hydroxy group, a carboxy group, a mercapto group, a glycidyl group, an amino group and an amide group:

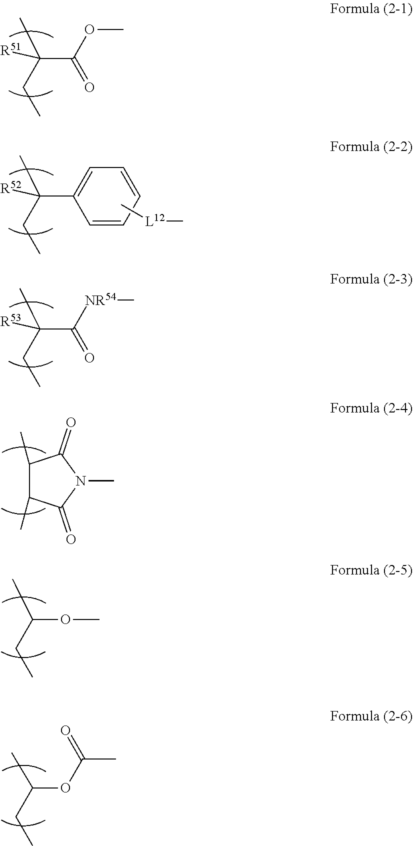

where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L¹² is a single bond, —O—, —S—, —COO—, —COS—, —CO— or —OCO—; and when L¹² is a single bond, R⁵⁰ is directly bound to a styrene skeleton.

In the second photo-alignment thermosetting liquid crystal composition of the present disclosure, from the viewpoint of raw material availability, the non-liquid crystal, thermally crosslinkable constitutional unit of the side-chain liquid crystal polymer (A) preferably contains a constitutional unit represented by the following formula (III).

In the first photo-alignment thermosetting liquid crystal composition, the constitutional unit represented by the following formula (III) of the second may be applied:

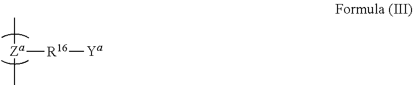

where Z^{a} is at least one kind of monomer unit selected from the group consisting of the following formulae (a-1) to (a-6); R¹⁶ is a group represented by -L^{2a}-R^{13′}— (where L^{2a} is a linear or branched alkylene group which contains 1 to 10 carbon atoms and which optionally contains —O— in its carbon chain; R^{13′} is —OR^{15′}, a residue obtained by removal of a hydrogen atom from an aryl group, or a residue obtained by removal of a hydrogen atom from a methyl group which optionally contains a substituent; and R^{5′} is a residue obtained by removal of a hydrogen atom from an aryl group); and Y^{a} is at least one kind of thermally crosslinkable group selected from the group consisting of a hydroxy group, a carboxy group, a mercapto group, a glycidyl group, an amino group and an amide group:

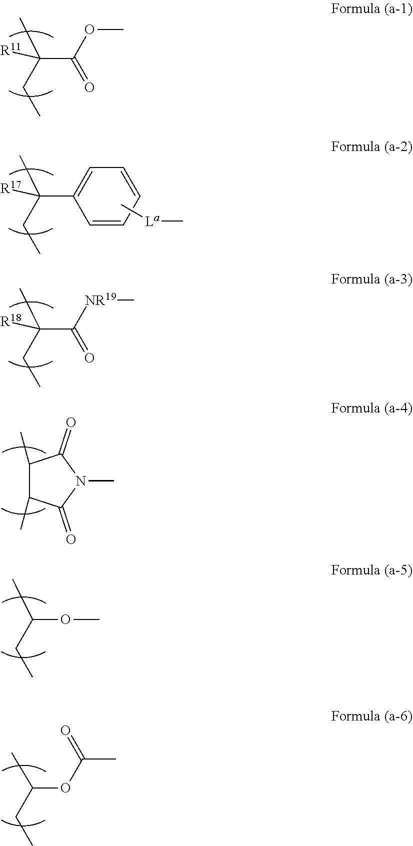

where R¹¹ is a hydrogen atom, a methyl group, a chlorine atom or a phenyl group; R¹⁷ is a hydrogen atom or a methyl group; R¹⁸ is a hydrogen atom, a methyl group, a chlorine atom or a phenyl group; R¹⁹ is a hydrogen atom or an alkyl group containing 1 to 4 carbon atoms; L^{a} is a single bond, —O—, —S—, —COO—, —COS—, —CO— or —OCO—; and when L^{a} is a single bond, R¹⁶ is directly bound to a styrene skeleton.

In the present disclosure, there is provided a first or second alignment film-cum-retardation film comprising an alignment layer-cum-retardation layer, wherein the alignment layer-cum-retardation layer is a cured film of the first or second photo-alignment thermosetting liquid crystal composition of the present disclosure.

In the present disclosure, there is provided a method for producing the first or second alignment film-cum-retardation film, the method comprising:
forming the first or second photo-alignment thermosetting liquid crystal composition of the present disclosure into a film,
forming a cured film having retardation by heating the thermosetting liquid crystal composition formed into the film, and
providing a liquid crystal aligning ability to the cured film having retardation by irradiating the cured film with polarized ultraviolet light.

In the present disclosure, there is provided a first or second retardation plate comprising a first retardation layer and a second retardation layer,
wherein the first retardation layer is a cured film of the first or second photo-alignment thermosetting liquid crystal composition of the present disclosure, and
wherein the second retardation layer is located directly adjacent to the first retardation layer and contains a cured product of a polymerizable liquid crystal composition.

In the first or second retardation plate of the present disclosure, the first retardation layer and the second retardation layer are preferably a positive C type retardation layer and a positive A type retardation layer, respectively, from the point of view that the retardation plate configured to improve optical properties can be efficiently produced, and the effects of the present disclosure can be effectively exerted.

In the present disclosure, there is provided a method for producing the first or second retardation plate, the method comprising:
forming the first or second photo-alignment thermosetting liquid crystal composition of the present disclosure into a film,
forming a cured film having retardation by heating the thermosetting liquid crystal composition formed into the film,
forming an alignment film-cum-first retardation layer by providing a liquid crystal aligning ability to the cured film having retardation by irradiating the cured film with polarized ultraviolet light,
aligning liquid crystal molecules by the alignment film-cum-retardation layer, by forming a coating film of a polymerizable liquid crystal composition by applying the polymerizable liquid crystal composition onto the alignment film-cum-first retardation layer and heating the coating film to a phase transition temperature of the polymerizable liquid crystal composition, and
forming a second retardation layer by curing the coating film of the polymerizable liquid crystal composition, in which the liquid crystal molecules are aligned, by light irradiation.

To achieve the third object, in the present disclosure, there is provided a third retardation plate comprising a positive C type retardation layer and a positive A type retardation layer,
wherein the positive C type retardation layer is a cured product of a thermosetting resin composition containing a photo-alignment component and a thermal crosslinking agent, and
wherein the positive A type retardation layer is located directly adjacent to the positive C type retardation layer and contains a cured product of a polymerizable liquid crystal composition.

In the third retardation plate of the present disclosure, a thickness direction retardation Rth at a wavelength of 550 nm may be from −35 nm to 35 nm; an in-plane retardation Re at a wavelength of 550 nm may be 100 nm or more; and a total thickness of the positive C type retardation layer and the positive A type retardation layer may be from 0.2 μm to 6 μm.

In the third retardation plate of the present disclosure, a composite modulus of the positive C type retardation layer may be 4.5 GPa or more and 9.0 GPa or less.

The third retardation plate of the present disclosure may further comprise a substrate, wherein the substrate is located directly adjacent to the positive C type retardation layer.

In the third retardation plate of the present disclosure, the positive C type retardation layer may contain a region which is permeated with a specific component contained in the positive A type retardation layer. The specific component may contain a polymerizable liquid crystal compound or a cured product thereof.

In the present disclosure, there is provided a method for forming a third retardation plate, the method comprising:
forming, into a film, a photo-alignment thermosetting liquid crystal composition comprising:
a side-chain liquid crystal polymer which contains a liquid crystal constitutional unit containing a liquid crystal moiety in a side chain,
a copolymer which contains a photo-alignment constitutional unit and a thermally crosslinkable constitutional unit containing a thermally crosslinkable group in a side chain, and
a thermal crosslinking agent for bonding to the thermally crosslinkable group of the thermally crosslinkable constitutional unit,
forming a cured film having retardation by heating the thermosetting liquid crystal composition formed into the film,
forming a positive C type retardation layer provided with a liquid crystal aligning ability by irradiating the cured film having retardation with polarized ultraviolet light,
aligning liquid crystal molecules by the positive C type retardation layer, by forming a coating film of a polymerizable liquid crystal composition by applying the polymerizable liquid crystal composition onto the positive C type retardation layer and heating the coating film to a phase transition temperature of the polymerizable liquid crystal composition, and
forming a positive A type retardation layer by curing the coating film of the polymerizable liquid crystal composition, in which the liquid crystal molecules are aligned, by light irradiation.

In the present disclosure, there is provided an optical member comprising the first, second or third retardation plate and a polarizing plate.

In the present disclosure, there is provided a method for producing an optical member, the method comprising:
preparing a polarizing plate,
preparing the first, second or third retardation plate, and
stacking the retardation plate and the polarizing plate.

In the present disclosure, there is provided a display device comprising the first, second or third retardation plate or comprising an optical member comprising the first, second or third retardation plate and a polarizing plate.

### Advantageous Effects of Invention

The first embodiment of the present disclosure exerts the effect of providing the following: a photo-alignment thermosetting liquid crystal composition capable of forming an alignment layer-cum-retardation layer having an excellent homeotropic alignment property and an excellent ability of aligning the directly stacked liquid crystal material; an alignment film-cum-retardation film; a method for producing the alignment film-cum-retardation film; a retardation plate comprising the alignment layer-cum-retardation layer; a method for producing the retardation plate; an optical member; a method for producing the optical member; and a display device.

The second embodiment of the present disclosure exerts the effect of providing the following: a photo-alignment thermosetting liquid crystal composition capable of forming an alignment layer-cum-retardation layer having a good homeotropic alignment property, having an ability of aligning the directly stacked liquid crystal material and having durability; an alignment film-cum-retardation film; a method for producing the alignment film-cum-retardation film; a retardation plate comprising the alignment layer-cum-retardation layer; a method for producing the retardation plate; an optical member; a method for producing the optical member; and a display device.

The third embodiment of the present disclosure exerts the effect of providing the following: a retardation plate in which the positive C type retardation layer and the positive A type retardation layer are directly stacked in good adhesion and which has good flex resistance; a method for producing the retardation plate; an optical member using the retardation plate; the method for producing the optical member; and a display device.

### BRIEF DESCRIPTION OF DRAWINGS

In the accompanying drawings,

FIG. 1 is a schematic sectional view of an example of the alignment film-cum-retardation film of the present disclosure;

FIG. 2 is a schematic sectional view of another example of the alignment film-cum-retardation film of the present disclosure;

FIG. 3 is a schematic sectional view of another example of the alignment film-cum-retardation film of the present disclosure;

FIG. 4 is a schematic sectional view of an example of the retardation plate of the present disclosure;

FIG. 5 is a schematic sectional view of another example of the retardation plate of the present disclosure;

FIG. 6 is a schematic sectional view of an example of the optical member of the present disclosure; and

FIG. 7 is a view illustrating a dynamic bending test method.

### DESCRIPTION OF EMBODIMENTS

Hereinafter, descriptions will be made about embodiments, examples and others in the present disclosure with reference to the drawings and so on. However, about the present disclosure, many different embodiments can be carried out. Thus, the present disclosure should not be interpreted with any limitation to described contents of the present embodiments, the examples, and the others, which will be given as examples. In order to make a description about each of the drawings clearer, the width, the thickness, the shape and any other factors of each part or portion therein may be schematically illustrated, differently from that of a part or portion in an actual form. However, the illustrated factors are each a mere example not to limit the interpretation of the present disclosure. In the document DESCRIPTION, and each of the drawings, to the same element as in any one of the drawings referred to already is attached the same reference number; thus, a detailed description thereabout is appropriately omitted. For the convenience of the descriptions, any word such as a word “upward” or “downward” may be used. However, the direction represented by the word may be flipped upside down.

In the DESCRIPTION, in a case where, for example, any member or a constituent of any region is “on (or beneath)” of a different member or a constituent of a different region, examples of this case include not only a case where the member is just on (or just beneath) of the different constituent, but also a case where the member or the constituent is over or above (or under or below) of the different constituent, that is, a case where an additional member is included between the two to be over or above (or under or below) the constituent unless otherwise specified.

In the present disclosure, an alignment-regulating force means an action that causes a liquid crystal compound in a retardation layer to be arranged in a specific direction.

In the present disclosure, the wording “(meth) acryl(ic)” denotes “acryl(ic)” or “methacryl(ic)”. The wording “(meth)acrylate” denotes “acrylate” or “methacrylate”.

In the present DESCRIPTION, the terms “plate”, “sheet” and “film” should not be distinguished from each other on the basis of a difference between their designations. The wording “film plane (plate plane or sheet plane)” denotes the following when a film-form (plate-form or sheet-form) member which is a target is viewed wholly and macroscopically: a plane of the film-form member (plate-form member or sheet-form member), which is the target, the direction of this plane being consistent with the flat plane direction of the member.

In the present DESCRIPTION, “to” which shows a numerical range is used to describe a range in which the numerical values described before and after “to” indicate the lower limit value and the upper limit value.

In the present disclosure, the “alignment layer-cum-retardation layer” is a layer that has the ability of aligning the directly stacked liquid crystal material while it is a retardation layer, and it can be reworded as a “retardation layer provided with a liquid crystal aligning ability”. Also in the present disclosure, the “alignment layer-cum-retardation layer” is a retardation layer that also functions as an alignment layer solely, and it can be reworded as a “retardation layer that functions as an alignment layer”.

In the present disclosure, in the same manner as above, the “alignment film-cum-retardation film” can be reworded as a “retardation film that functions as an alignment film” or “retardation film provided with a liquid crystal aligning ability”.

Also in the present disclosure, the wording “alkylene group . . . which optionally contains —O— in its carbon chain” means “an alkylene group . . . optionally containing —O— in its carbon chain, that is, any position other than its terminal, and a case where both of the terminals the alkylene group are carbon atoms”. The wording “alkylene group . . . which optionally contains —O— in its carbon chain or at its terminal” means “an alkylene group . . . optionally containing —O— not only in its carbon chain but also at its terminal, and a case where both of the terminals of the alkylene group are carbon or oxygen atoms”.

First, the photo-alignment thermosetting liquid crystal composition of the present disclosure, the alignment film-cum-retardation film using the photo-alignment thermosetting liquid crystal composition, the method for producing the alignment film-cum-retardation film, the retardation plate and the method for producing the retardation plate will be described in detail.

### I. The First Embodiment

### A. Photo-Alignment Thermosetting Liquid Crystal Composition

The photo-alignment thermosetting liquid crystal composition of the present disclosure is a photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a constitutional unit represented by the following formula (1) and a thermally crosslinkable constitutional unit containing a thermally crosslinkable group in a side chain, and
a thermal crosslinking agent (C) for bonding to the thermally crosslinkable group of the thermally crosslinkable constitutional unit:

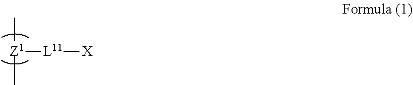

where Z¹ is at least one kind of monomer unit selected from the group consisting of the following formulae (1-1) to (1-6); X is a photo-alignment group; and L¹¹ is a single bond, —O—, —S—, —COO—, —COS—, —CO—, —OCO— or a combination of any of them with an arylene group:

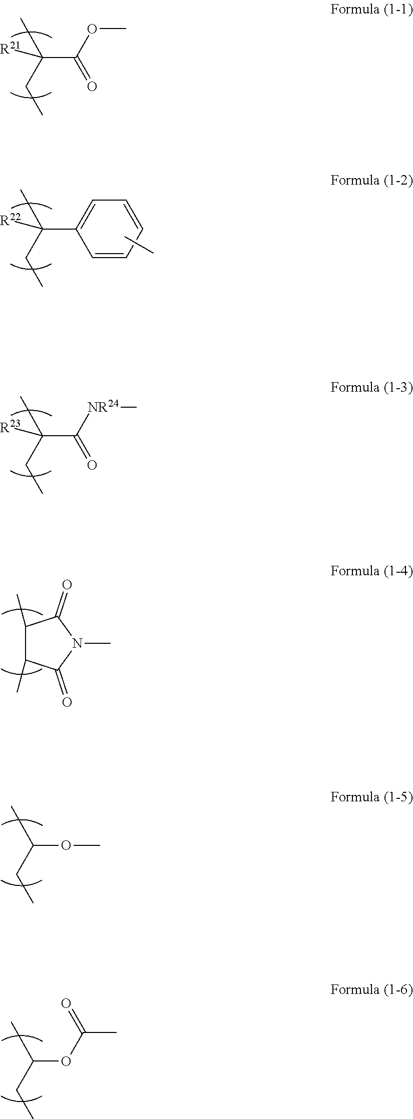

where R²¹ is a hydrogen atom, a methyl group, a chlorine atom or a phenyl group; R²² is a hydrogen atom or a methyl group; R²³ is a hydrogen atom, a methyl group, a chlorine atom or a phenyl group; and R²⁴ is a hydrogen atom or an alkyl group containing 1 to 4 carbon atoms).

The photo-alignment thermosetting liquid crystal composition of the present disclosure comprises the side-chain liquid crystal polymer (A), the copolymer (B) containing the thermally crosslinkable constitutional unit and the photo-alignment constitutional unit which exhibits the ability of aligning the directly stacked liquid crystal material, and the thermal crosslinking agent (C) for bonding to the thermally crosslinkable group of the thermally crosslinkable constitutional unit. Accordingly, by forming the cured film of the composition, the alignment layer-cum-retardation layer can be formed, which has an excellent homeotropic alignment property and an excellent ability of aligning the directly stacked liquid crystal material, while it functions as both an alignment layer and a retardation layer solely.

In the copolymer (B) of the photo-alignment thermosetting liquid crystal composition of the present disclosure, the photo-alignment constitutional unit of the copolymer (B) has a structure such that the photo-alignment constitutional unit does not contain an alkylene chain between the photo-alignment group and the main chain of the copolymer. Since the copolymer (B) has the structure such that the photo-alignment constitutional unit does not contain an alkylene chain, the copolymer (B) becomes more non-liquid crystal. As a result, it is estimated that the compatibility of the copolymer (B) with the side-chain liquid crystal polymer (A) decreases, and the copolymer (B) phase-separates from the side-chain liquid crystal polymer (A) with ease. Since the copolymer (B) has the structure such that the photo-alignment constitutional unit does not contain an alkylene chain, it is estimated that the rigidity of the copolymer (B) increases; the distance between the photo-alignment groups decreases with ease; and the photo-alignment property (the liquid crystal aligning ability) improves. Unlike a polymerizable liquid crystal compound of a low-molecular-weight compound, the side-chain liquid crystal polymer (A) is disposed on the substrate side with ease even when mixed with the copolymer (B), and the homeotropic alignment property easily improves. As a result, the copolymer (B) is also disposed on an air interface side with ease, and the photo-alignment property easily improves. In the photo-alignment thermosetting liquid crystal composition of the present disclosure, due to these synergetic effects, the side-chain liquid crystal polymer (A) which is homeotropically aligned to exhibit retardation and the copolymer (B) which contains the photo-alignment constitutional unit that exhibits the alignment property of the directly stacked liquid crystal material, are less likely to hinder the performance of one another, and the cured film of the composition is formed. Accordingly, it is thought that the alignment layer-cum-retardation layer which solely has the excellent homeotropic alignment property and the excellent ability of aligning the directly stacked liquid crystal material, can be achieved.

The photo-alignment thermosetting liquid crystal composition of the present disclosure contains the thermal crosslinking agent and the copolymer containing both the photo-alignment constitutional unit and the thermally crosslinkable constitutional unit. Accordingly, when the thermosetting liquid crystal composition is thermally cured, due to its crosslinked structure, the heat resistance and solvent resistance of the thus-obtained film are improved, thereby obtaining the alignment layer-cum-retardation layer with high durability.

Due to crosslinking the polymers by the thermal crosslinking agent, the alignment layer-cum-retardation layer, which is the cured product of the photo-alignment thermosetting liquid crystal composition of the present disclosure, is less likely to be hard, has flexibility, and shows good adhesion to the directly stacked liquid crystal material, compared to the case where the alignment layer-cum-retardation layer is a cured product of a photocurable resin composition containing a polymerizable liquid crystal compound. Accordingly, by the alignment layer-cum-retardation layer, which is the cured product of the photo-alignment thermosetting liquid crystal composition of the present disclosure, a thin retardation plate which has good flex resistance and in which the first retardation layer and the second retardation layer are directly stacked in good adhesion, is obtained as in the third embodiment of the present disclosure described below.

Hereinafter, the components of the photo-alignment thermosetting liquid crystal composition of the present disclosure will be described.

### 1. Side-Chain Liquid Crystal Polymer (A)

The side-chain liquid crystal polymer (A) used in the present disclosure is a side-chain liquid crystal polymer which contains a liquid crystal constitutional unit containing a liquid crystal moiety in a side chain and a non-liquid crystal constitutional unit containing an alkylene group in a side chain.

Hereinafter, the constitutional units of the side-chain liquid crystal polymer (A) will be described.

### (1) Liquid Crystal Constitutional Unit

In the embodiment of the present disclosure, the liquid crystal constitutional unit contains a side chain including a liquid crystal moiety, that is, a moiety showing a liquid crystal property. The liquid crystal constitutional unit is preferably a constitutional unit containing, in a side chain, a mesogen showing a liquid crystal property. The liquid crystal constitutional unit is preferably a constitutional unit derived from a compound showing a liquid crystal property in which a polymerizable group is bonded to a mesogen group to interpose a spacer therebetween. In the present disclosure, the mesogen denotes a moiety having a high rigidity so as to show a liquid crystal property. Examples thereof include a partial structure which contains two or more cyclic structures, preferably three or more cyclic structures and which is a structure in which the cyclic structures are bonded directly to each other or the cyclic structures are bonded to each other to interpose 1 to 3 atoms therebetween. When the side chain contains such a moiety showing a liquid crystal property, the liquid crystal constitutional unit is homeotropically aligned with ease.

The cyclic structures may each be an aromatic ring such as benzene, naphthalene or anthracene, or may be a cyclic aliphatic hydrocarbon such as cyclopentyl or cyclohexyl.

When the cyclic structures are bound to each other via 1 to 3 atoms, examples of the structure of this linking moiety include —O—, —S—, —O—C(═O)—, —C(═O)—O—, —O—C(═O)—O—, —NR—C(═O)—, —C(═O)—NR—, —O—C(═O)—NR—, —NR—C(═O)—O—, —NR—C(═O)—NR—, —O—NR—, and —NR—O— where Rs are each a hydrogen atom or a hydrocarbon group.

The mesogen is particularly preferably a rodlike mesogen in which, for example, benzene rings are bound to each other at their para-positions, or naphthalene rings are bound to each other at their 2- and 6-positions to make the linkage of the cyclic structures into a rod form.

When the liquid crystal constitutional unit is a constitutional unit containing, in a side chain, a mesogen showing a liquid crystal property, the terminal of the side chain of the constitutional unit is preferably a polar group or preferably contains an alkyl group, from the viewpoint of the homeotropic alignment property. As the polar group, examples include, but are not limited to, —F, —Cl, —CN, —OCF₃, —OCF₂H, —NCO, —NCS, —NO₂, —NHC(═O)—R′, —C(═O)—OR′, —OH, —SH, —CHO, —SO₃H, —NR′₂, —R″ and —OR″ where R′s are each a hydrogen atom or a hydrocarbon, and R″s are each an alkyl group.

As the liquid crystal constitutional unit, examples include a constitutional unit containing, as a side chain, a group represented by —R²-(L¹-Ar¹)ₐ—R³ (where R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; L¹s may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.)

In R², m and m′ are each independently an integer of from 2 to 10. From the viewpoint of the homeotropic alignment property, m and m are preferably from 2 to 8, and more preferably from 2 to 6.

As the arylene group containing 6 to 10 carbon atoms in Ar², examples include, but are not limited to, a phenylene group and a naphthylene group. Of these groups, a phenylene group is more preferred. The arylene group may contain a substituent besides R¹³, and as the substituent, examples include, but are not limited to, an alkyl group containing 1 to 5 carbon atoms, and a halogen atom such as a fluorine atom, a chlorine atom and a bromine atom.

In R³, R⁴ is a hydrogen atom or an alkyl group containing 1 to 6 carbon atoms. R⁴ is particularly preferably a hydrogen atom or an alkyl group containing 1 to 3 carbon atoms. In R³, R⁵ is an alkyl group containing 1 to 6 carbon atoms. R⁵ is particularly preferably an alkyl group containing 1 to 5 carbon atoms.

The liquid crystal constitutional unit is preferably a constitutional unit derived from a polymerizable monomer which contains an ethylenic double bond-containing group. As the monomer which contains an ethylenic double bond-containing group, examples include, but are not limited to, a derivative such as a (meth)acrylic acid ester, styrene, (meth)acrylamide, maleimide, vinyl ether and vinyl ester. The liquid crystal constitutional unit is particularly preferably a constitutional unit derived from a (meth)acrylic acid ester, from the viewpoint of the homeotropic alignment property.

In the embodiment of the present disclosure, the liquid crystal constitutional unit preferably contains a constitutional unit represented by the following general formula (I) from the viewpoint of the homeotropic alignment property:

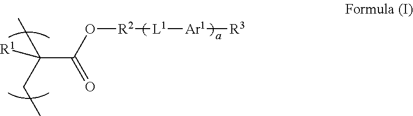

where R¹ is a hydrogen atom or a methyl group; R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; L¹s may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.

In the constitutional unit represented by the general formula (I), the group represented by —R²-(L¹-Ar¹)ₐ-R³ may be the same as described above.

The liquid crystal constitutional unit represented by the general formula (I) is preferably a constitutional unit represented by the following chemical formula (I-1), a constitutional unit represented by the following chemical formula (I-2), or a constitutional unit represented by the following chemical formula (I-3), for example. However, the liquid crystal constitutional unit is not limited to these examples.

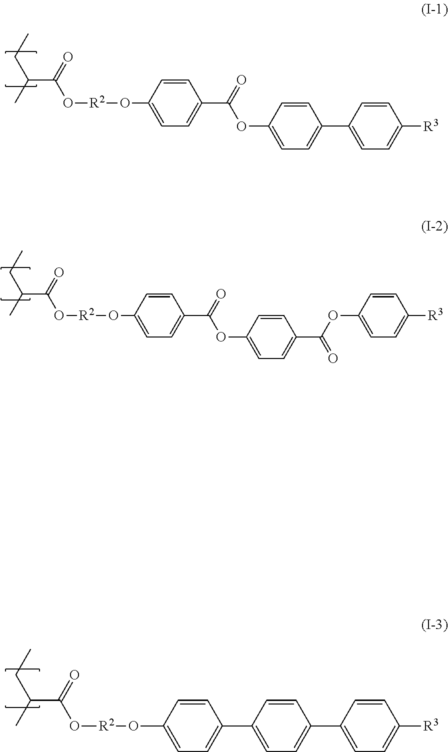

In the constitutional units represented by the general formulae (I-1) to (I-3), R² and R³ are the same as R² and R³ in the general formula (I).

In the embodiment of the present disclosure, the liquid crystal constitutional units may be used solely or in combination of two or more.

For the synthesis of the copolymer, monomers from which the liquid crystal constitutional unit is derived, such as a (meth)acrylic acid ester derivative, can be used. The monomers from which the liquid crystal constitutional unit is derived, such as a (meth)acrylic acid ester derivative, may be used solely or in combination of two or more.

From the viewpoint of improving the homeotropic alignment property of the liquid crystal constitutional unit and obtaining a sufficient liquid crystal aligning property, when the amount of the constitutional units contained in the whole copolymer is 100% by mole, the content of the liquid crystal constitutional unit in the copolymer is preferably in a range of from 40% by mole to 90% by mole, more preferably in a range of from 40% by mole to 80% by mole, still more preferably in a range of from 45% by mole to 70% by mole, and particularly preferably in a range of from 50% by mole to 65% by mole.

The content of the constitutional units in the copolymer can be calculated from integral values obtained by ¹H-NMR measurement.

### (2) Non-Liquid Crystal Constitutional Unit Containing an Alkylene Group in a Side Chain

In the non-liquid crystal constitutional unit containing an alkylene group in a side chain, the side chain containing an alkylene group has the effect of promoting, when the side-chain liquid crystal polymer enters a liquid crystal state, the homeotropic alignment of the moiety showing a liquid crystal property (i.e., a mesogen) of the side chain of the liquid crystal constitutional unit. By containing the non-liquid crystal constitutional unit containing an alkylene group in a side chain, the homeotropic alignment property of the side-chain liquid crystal polymer (A) is improved, and the solvent solubility is also improved.

As the non-liquid crystal constitutional unit containing an alkylene group in a side chain, examples include, but are not limited to, a constitutional unit containing, as a side chain, a group represented by -L²-R¹³ or -L^{2′}-R¹⁴ (where L² is —(CH₂)ₙ—; L^{2′} is a linking group represented by —(C₂H₄O)_{n′}—; R¹³ is a methyl group optionally containing a substituent, an aryl group optionally containing an alkyl group, or —OR¹⁵; R¹⁴ and R¹⁵ are each independently an alkyl group optionally containing a substituent, or an aryl group optionally containing a substituent; and n and n′ are each independently an integer of from 1 to 18.)

L² is —(CH₂)ₙ—, and L^{2′} is a linking group represented by —(C₂H₄O)_{n′}—. From the viewpoint of improving the homeotropic alignment property with ease, L² is preferably —(CH₂)ₙ—. Also, n is an integer of from 1 to 18, and it is preferably an integer of from 2 to 18. When R¹³ is a methyl group containing a substituent or an alkyl group containing a substituent, n is also preferably an integer of 1. Also, n′ is an integer of from 1 to 18, preferably an integer of from 1 to 8, and more preferably an integer of from 2 to 8.

In R¹⁴ and R¹⁵, the alkyl group may be a linear, branched or cyclic alkyl group, and it is preferably a linear alkyl group.

In R¹⁴ and R¹⁵, the alkyl group is preferably an alkyl group containing 1 to 20 carbon atoms. As the alkyl group containing 1 to 20 carbon atoms, examples include, but are not limited to, a linear alkyl group such as a methyl group, an ethyl group, an n-propyl group, an n-butyl group, an n-pentyl group, an n-hexyl group, an n-octyl group and an n-decyl group; a branched alkyl group such as an i-propyl group, an i-butyl group and a t-butyl group; an alkenyl group such as a 1-propenyl group and a 1-butenyl group; an alkynyl group such as an ethynyl group and a 2-propynyl group; a cycloalkyl group such as a cyclopropyl group, a cyclobutyl group, a cyclopentyl group, a cyclohexyl group, a cycloheptyl group, a cyclooctyl group, a cyclodecyl group, a norbornyl group and an adamantyl group; and a cycloalkenyl group such as a 1-cyclohexenyl group. When the alkyl group is a cycloalkyl group, it is preferably a cycloalkyl group substituted with a linear alkyl group.

The alkyl group in R¹⁴ and R¹⁵ is not particularly limited, and it is preferably an alkyl group containing 1 to 12 carbon atoms, from the viewpoint of in-plane uniformity of retardation.

The aryl group in R¹³, R¹⁴ and R¹⁵ is not particularly limited, and it is preferably an aryl group containing 6 to 20 carbon atoms. As the aryl group, examples include, but are not limited to, a phenyl group, a naphthyl group and an antracenyl group. Of them, a phenyl or naphthyl group is preferred, and a phenyl group is more preferred. The aryl group is preferably an aryl group substituted with a linear alkyl group.

The non-liquid crystal constitutional unit containing an alkylene group in a side chain may contain, as a substituent, a reactive group reactive with other components. For example, it may contain the same thermally crosslinkable group as the copolymer (B) described below.

As the non-liquid crystal constitutional unit containing an alkylene group in a side chain, examples include a non-liquid crystal, non-crosslinkable constitutional unit and a non-liquid crystal, thermally crosslinkable constitutional unit. The non-liquid crystal constitutional unit containing an alkylene group in a side chain may contain only a non-liquid crystal, non-crosslinkable constitutional unit, or it may contain only a non-liquid crystal, thermally crosslinkable constitutional unit.

From the viewpoint of improving the homeotropic alignment property with ease, the non-liquid crystal constitutional unit containing an alkylene group in a side chain preferably contains at least a non-liquid crystal, non-crosslinkable constitutional unit. From the viewpoint of improving the homeotropic alignment property and the durability with ease, the non-liquid crystal constitutional unit containing an alkylene group in a side chain more preferably contains a non-liquid crystal, non-crosslinkable constitutional unit and a non-liquid crystal, thermally crosslinkable constitutional unit.

In the non-liquid crystal, non-crosslinkable constitutional unit containing an alkylene group in a side chain, the substituent optionally contained in the methyl group in R¹³ and the substituent optionally contained in the alkyl group in R¹⁴ and R¹⁵ may each be a non-crosslinkable substituent, for example. As the non-crosslinkable substituent, examples include, but are not limited to, an alkoxy group, a nitro group, and a halogen atom such as a fluorine atom, a chlorine atom and a bromine atom. Of them, preferred is a halogen atom such as a fluorine atom, a chlorine atom and a bromine atom.

In the non-liquid crystal, non-crosslinkable constitutional unit containing an alkylene group in a side chain, the substituent optionally contained in the aryl group in R¹³, R¹⁴ and R¹⁵ may each be a non-crosslinkable substituent, for example. As the non-crosslinkable substituent, examples include, but are not limited to, an alkyl group, an alkoxy group, a nitro group, and a halogen atom such as a fluorine atom, a chlorine atom and a bromine atom. As the alkyl group, examples include, but are not limited to, an alkyl group containing 1 to 12 carbon atoms, and an alkyl group containing 1 to 9 carbon atoms. The alkyl group may be a linear alkyl group, or it may be an alkyl group containing a branched structure or a cyclic structure. As the non-crosslinkable substituent, preferred is an alkyl group containing 1 to 9 carbon atoms or a halogen atom such as a fluorine atom, a chlorine atom and a bromine atom. As the alkyl group, examples include, but are not limited to, a methyl group, an ethyl group, a propyl group, a butyl group, a pentyl group, a hexyl group, a heptyl group, an octyl group, a nonyl group, a decyl group, a cyclopentyl group, a cyclohexyl group, a cyclohexylmethyl group, a cyclohexylethyl group, and a cyclohexylpropyl group. A hydrogen atom contained in the alkyl group may be substituted with a halogen atom.

In the non-liquid crystal, thermally crosslinkable constitutional unit containing an alkylene group in a side chain, the substituent optionally contained in the methyl group in R¹³, in the alkyl group in R¹⁴ and R¹⁵, and in the aryl group in R¹³, R¹⁴ and R¹⁵ is preferably a thermally crosslinkable group. As the thermally crosslinkable group, examples include, but are not limited to, the same thermally crosslinkable group as the copolymer (B) described below. For example, the thermally crosslinkable group may be at least one kind selected from the group consisting of a hydroxy group, a carboxy group, a mercapto group, a glycidyl group, an amino group, an amide group, a hydroxymethyl group, an alkoxymethyl group, a trialkoxysilyl group, a blocked isocyanate group, and a methyl group substituted with an alkoxy group. The hydroxymethyl group and the alkoxymethyl group, which are self-crosslinkable groups, may each be a group that is changed into a hydroxymethyl group or an alkoxymethyl group when the methyl group in R¹³ is substituted with a hydroxy group or an alkoxy group.

From the viewpoint of reactivity, the thermally crosslinkable group is preferably a hydroxy group, and more preferably a primary hydroxy group. The primary hydroxy group refers to a hydroxy group such that the carbon atom to which the hydroxy group is bound is a primary carbon atom.

The non-liquid crystal constitutional unit is preferably a constitutional unit derived from a polymerizable monomer which contains an ethylenic double bond-containing group. As the monomer which contains an ethylenic double bond-containing group, examples include, but are not limited to, a derivative such as a (meth)acrylic acid ester, styrene, (meth)acrylamide, maleimide, vinyl ether and vinyl ester. From the viewpoint of the homeotropic alignment property, the non-liquid crystal constitutional unit is preferably a constitutional unit derived from a (meth)acrylic acid ester derivative or styrene, and more preferably a constitutional unit derived from a (meth)acrylic acid ester derivative.

In the embodiment of the present disclosure, the non-liquid crystal constitutional unit preferably contains the constitutional unit represented by the following formula (II):

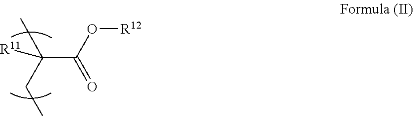

where R¹¹ is a hydrogen atom or a methyl group; R¹² is a group represented by -L²-R¹³ or -L^{2′}-R¹⁴; L² is —(CH₂)ₙ—; L^{2′} is a linking group represented by —(C₂H₄O)_{n′}—; R¹³ is a methyl group optionally containing a substituent, an aryl group optionally containing an alkyl group, or —OR¹⁵; R¹⁴ and R¹⁵ are each independently an alkyl group optionally containing a substituent, or an aryl group optionally containing a substituent; and n and n′ are each independently an integer of from 1 to 18.

In the constitutional unit represented by the formula (II), the group represented by -L²-R¹³ or -L^{2′}-R⁴ may be the same as described above.

In the embodiment of the present disclosure, when the non-liquid crystal constitutional unit is the non-liquid crystal, non-crosslinkable constitutional unit, as the substituent optionally contained in the constitutional unit represented by the formula (II), examples include, but are not limited to, the above-described non-crosslinkable substituent.

Also in the embodiment of the present disclosure, when the non-liquid crystal constitutional unit is the non-liquid crystal, thermally crosslinkable constitutional unit, as the substituent optionally contained in the constitutional unit represented by the formula (II), examples include, but are not limited to, the above-described thermally crosslinkable group. It is preferable that one thermally crosslinkable group is contained per non-liquid crystal, thermally crosslinkable constitutional unit, or two or more thermally crosslinkable groups may be contained per non-liquid crystal, thermally crosslinkable constitutional unit.

In the embodiment of the present disclosure, when the non-liquid crystal constitutional unit contains the non-liquid crystal, thermally crosslinkable constitutional unit, the non-liquid crystal, thermally crosslinkable constitutional unit preferably contains the constitutional unit represented by the following formula (III), from the viewpoint of increasing the reactivity and thereby improving the durability:

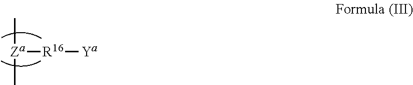

where Z^{a} is at least one kind of monomer unit selected from the group consisting of the following formulae (a-1) to (a-6); R¹⁶ is a linear alkylene group which contains 1 to 11 carbon atoms and which optionally contains —O— in its carbon chain; and Y^{a} is a thermally crosslinkable group:

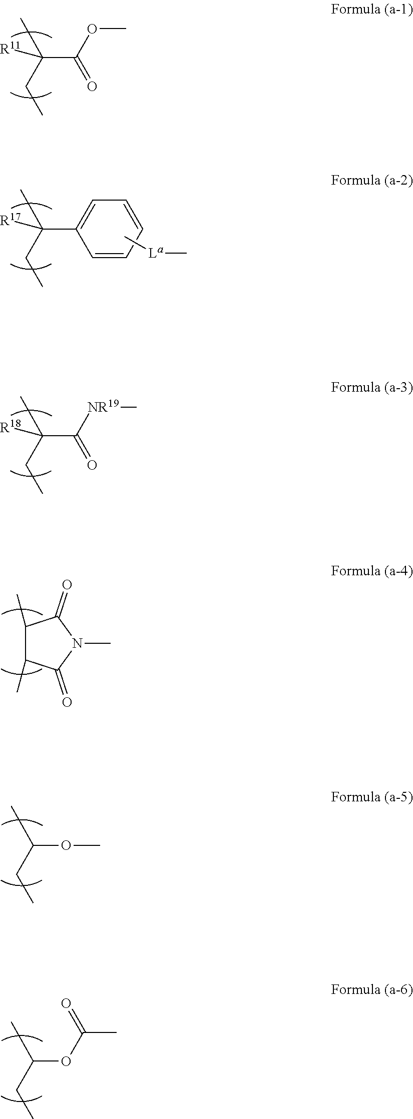

where R¹¹ is a hydrogen atom, a methyl group, a chlorine atom or a phenyl group; R¹⁷ is a hydrogen atom or a methyl group; R¹⁸ is a hydrogen atom, a methyl group, a chlorine atom or a phenyl group; R¹⁹ is a hydrogen atom or an alkyl group containing 1 to 4 carbon atoms; L^{a} is a single bond, —O—, —S—, —COO—, —COS—, —CO— or —OCO—; and when L^{a} is a single bond, R¹⁶ is directly bound to a styrene skeleton.

R¹⁶ is a linear alkylene group which contains 1 to 11 carbon atoms and which may contain —O— in its carbon chain. R¹⁶ is preferably —(CH₂)_{n″}— or —(C₂H₄O)ₘ″—C₂H₄— where n″ is from 1 to 11, and m″ is from 1 to 4. It is preferable that n″ is from 2 to 11 and m″ is from 1 to 4. It is more preferable that n″ is from 4 to 11 and m″ is from 2 to 4. When n″ and m″ are too small, in the thermally crosslinkable constitutional unit, the distance between the thermally crosslinkable group and the main skeleton of the copolymer is short. Accordingly, there is a possibility that the thermal crosslinking agent is less likely to bind to the thermally crosslinkable group, and the reactivity between the thermally crosslinkable constitutional unit and the thermal crosslinking agent decreases. On the other hand, when n″ and m″ are too large, the chain length of the linking group in the thermally crosslinkable constitutional unit increases. Accordingly, there is a possibility that the thermally crosslinkable group at the terminal is less likely to appear on the surface; the thermal crosslinking agent is less likely to bind to the thermally crosslinkable group; and the reactivity between the thermally crosslinkable constitutional unit and the thermal crosslinking agent decreases.

The thermally crosslinkable group as Y° may be the same as the above-described thermally crosslinkable group. For example, the thermally crosslinkable group may be at least one kind selected from the group consisting of a hydroxy group, a carboxy group, a mercapto group, a glycidyl group, an amino group, an amide group, a hydroxymethyl group, an alkoxymethyl group, a trialkoxysilyl group, a blocked isocyanate group, and a methyl group substituted with an alkoxy group. The hydroxymethyl group and the alkoxymethyl group, which are self-crosslinkable groups, may each be a group that is changed into a hydroxymethyl group or an alkoxymethyl group when the methyl group (the methylene group in R⁶) is substituted with a hydroxy group or an alkoxy group.

In the embodiment of the present disclosure, when the non-liquid crystal constitutional unit contains the non-liquid crystal, thermally crosslinkable constitutional unit, as the non-liquid crystal, thermally crosslinkable constitutional unit, the same constitutional unit as the constitutional unit represented by the formula (III) described below in “1. Side-chain liquid crystal polymer (A)” under “II. The second embodiment” may be used.

The copolymer may contain one kind of the non-liquid crystal constitutional unit or may contain two or more kinds of such non-liquid crystal constitutional units.

Non-liquid crystal, non-crosslinkable constitutional units represented by the general formula (II) include the following chemical formulae (II-1) to (II-10).

Non-liquid crystal, thermally crosslinkable constitutional units represented by the general formula (II) include structures in which one of the hydrogen atoms of a hydrocarbon group in the following chemical formulae (II-1) to (II-10) is substituted with the thermally crosslinkable group. In addition, non-liquid crystal, thermally crosslinkable constitutional units represented by the general formula (II) include the following chemical formulae (III-1) to (III-11).

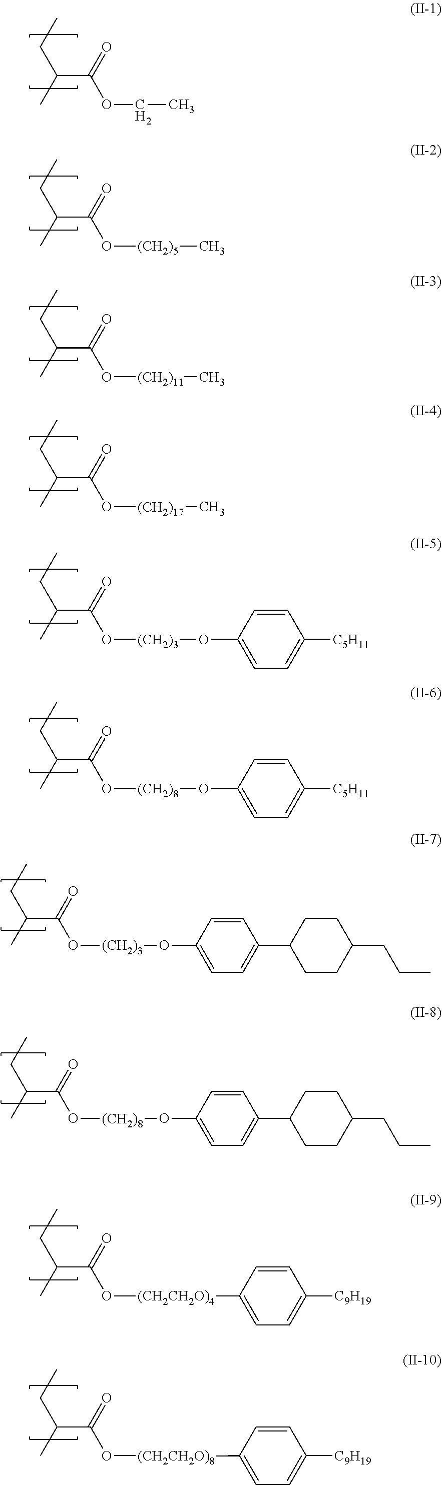

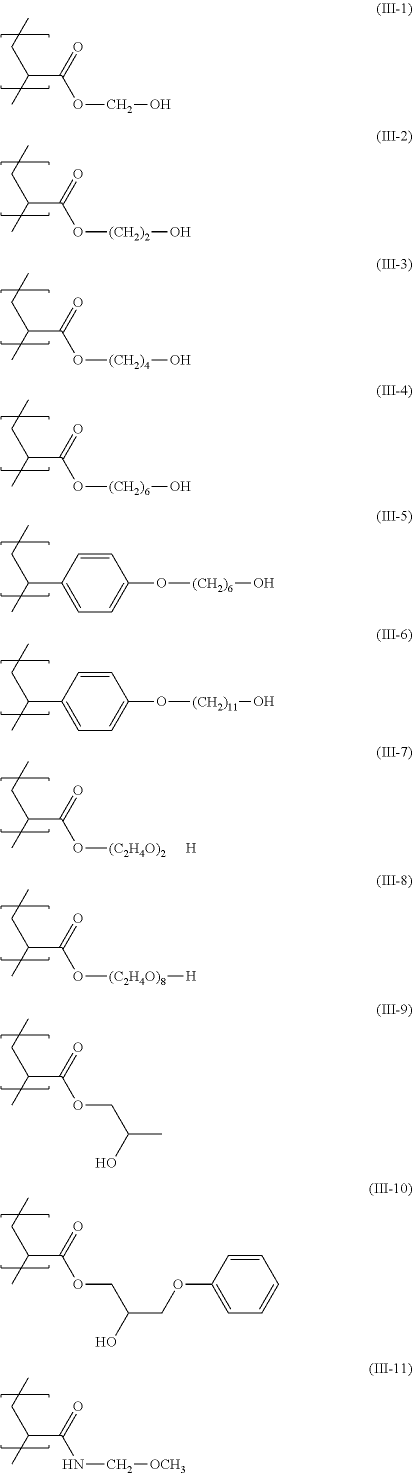

Also, constitutional units represented by the chemical formulae (III-1) to (III-12) of the second embodiment of the present disclosure can be used, which are described below in “1. Side-chain liquid crystal polymer (A)” under “II. The second embodiment”.

For the synthesis of the copolymer, monomers from which the non-liquid crystal constitutional unit is derived, such as a (meth)acrylic acid ester derivative, can be used. The monomers from which the non-liquid crystal constitutional unit is derived, such as a (meth)acrylic acid ester derivative, may be used solely or in combination of two or more.

From the viewpoint of improving the homeotropic alignment property of the liquid crystal constitutional unit and obtaining a sufficient liquid crystal aligning property, when the amount of the constitutional units contained in the whole copolymer is 100% by mole, the content of the non-liquid crystal constitutional unit in the copolymer is preferably in a range of from 10% by mole to 60% by mole, more preferably in a range of from 15% by mole to 50% by mole, still more preferably in a range of from 15% by mole to 45% by mole, and particularly preferably in a range of from 20% by mole to 40% by mole.

In the case where both the non-liquid crystal, non-crosslinkable constitutional unit and the non-liquid crystal, thermally crosslinkable constitutional unit are contained as the non-liquid crystal constitutional unit of the copolymer, when the total amount of the non-liquid crystal constitutional units contained in the whole copolymer is 100% by mole, the content of the non-liquid crystal, thermally crosslinkable constitutional unit is preferably in a range of from 10% by mole to 70% by mole, and more preferably in a range of from 30% by mole to 50% by mole.

The content of the constitutional units in the copolymer can be calculated from integral values obtained by 1H-NMR measurement.

### (3) Other Constitutional Units

The side-chain liquid crystal polymer (A) used in the present disclosure contains at least the liquid crystal constitutional unit and the non-liquid crystal constitutional unit containing an alkylene group in a side chain. The side-chain liquid crystal polymer (A) may further contain other constitutional units.

Other constitutional units include, for example, a thermally crosslinkable constitutional unit containing the thermally crosslinkable group and containing no alkylene group in a side chain, and a photo-alignment constitutional unit containing the photo-alignment group of the below-described copolymer (B) in a side chain.

As the thermally crosslinkable constitutional unit containing the thermally crosslinkable group and containing no alkylene group in a side chain, examples include, but are not limited to, (meth)acrylic acid, 4-hydroxystyrene and 4-carboxystyrene.

From the viewpoint of improving the endurance reliability of the retardation layer, the side-chain liquid crystal polymer (A) used in the present disclosure preferably contains at least one kind of thermally crosslinkable constitutional unit containing a thermally crosslinkable group in a side chain, which is selected from the group consisting of the non-liquid crystal, thermally crosslinkable constitutional unit containing an alkylene group in a side chain and the thermally crosslinkable constitutional unit containing the thermally crosslinkable group and containing no alkylene group in a side chain.

The photo-alignment constitutional unit may be the same as the photo-alignment constitutional unit which contains a photo-alignment group in a side chain and which is contained in the copolymer (B) described below.

From the viewpoint of improving the homeotropic alignment property of the liquid crystal constitutional unit and obtaining a sufficient liquid crystal aligning property, when the amount of the constitutional units contained in the whole copolymer is 100% by mole, the content of other constitutional units in the copolymer is preferably in a range of 30% by mole or less, and more preferably in a range of 20% by mole or less.

### (4) Copolymer of the Side-Chain Liquid Crystal Polymer (A)

In the embodiment of the present disclosure, the side-chain liquid crystal polymer (A) may be a block copolymer containing block moieties made of the liquid crystal constitutional unit and block moieties made of the non-liquid crystal constitutional unit containing an alkylene group in a side chain, or it may be a random copolymer in which the liquid crystal constitutional unit and the non-liquid crystal constitutional unit containing an alkylene group in a side chain are irregularly arranged. In the present embodiment, the random copolymer is preferred in order to improve the homeotropic alignment property of the side-chain liquid crystal polymer and the in-plane uniformity of the retardation value.

The mass average molecular weight Mw of the side-chain liquid crystal polymer (the copolymer) is not particularly limited, and it is preferably in a range of from 5000 to 80000, more preferably in a range of from 8000 to 50000, and still more preferably in a range of from 10000 to 36000. When the mass-average molecular weight is in any one of the ranges, the resultant liquid crystal composition is excellent in stability, and the composition is excellent in handleability when made into a retardation layer.

The mass average molecular weight Mw is a value measured by gel permeation chromatography (GPC). The measurement is made using an instrument HLC-8120GPC manufactured by Tosoh Corp., using N-methylpyrrolidone into which 0.01 mole/L of lithium bromide is added as an eluting solvent, using polymers of Mw 377400, 210500, 96000, 50400, 206500, 10850, 5460, 2930, 1300, and 580 (Easi PS-2 series, each manufactured by Polymer Laboratories Ltd.) and a polymer of Mw 1090000 (manufactured by Tosoh Corp.) as polystyrene standards for calibration curves, and using two columns TSK-GEL ALPHA-M (manufactured by Tosoh Corp.) as measuring columns.

As the method for synthesizing the copolymer of the side-chain liquid crystal polymer (A), examples include, but are not limited to, copolymerization of a monomer from which the liquid crystal constitutional unit is derived and a monomer from which the non-liquid crystal constitutional unit containing an alkylene group in a side chain is derived, by a conventional production method.

The side-chain liquid crystal polymer (A) may be used in any of the following forms: the form of a solution in synthesizing the copolymer, the form of a powder, and the form of a solution obtained by re-dissolving a refined powder in a solvent described below.

As the side-chain liquid crystal polymer (A), one kind of the side-chain liquid crystal polymer may be used solely, or two or more kinds of such polymers may be used in combination. From the viewpoint of exhibiting the homeotropic alignment property, with respect to 100 parts by mass of the solid content of the liquid crystal composition, the content of the side-chain liquid crystal polymer is preferably from 20 parts by mass to 80 parts by mass, more preferably from 25 parts by mass to 70 parts by mass, and even more preferably from 30 parts by mass to 60 parts by mass.

In the present disclosure, the solid content denotes all components from which any solvent is removed. Examples thereof include the below-described polymerizable liquid crystal compound even when this compound is in a liquid form.

### 2. Copolymer (B)

The copolymer (B) used in the present disclosure contains a photo-alignment constitutional unit containing a photo-alignment group in a side chain by a specific structure and a thermally crosslinkable constitutional unit containing a thermally crosslinkable group in a side chain.

The copolymer (B) is a photo-alignment copolymer.

Hereinafter, the constitutional units of the copolymer will be described.

### (1) Photo-Alignment Constitutional Unit

The photo-alignment constitutional unit of the present disclosure contains a constitutional unit represented by the following formula (1):

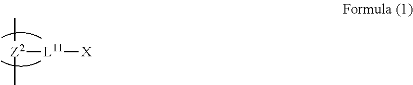

where Z¹ is at least one kind of monomer unit selected from the group consisting of the following formulae (1-1) to (1-6); X is a photo-alignment group; and L¹¹ is a single bond, —O—, —S—, —COO—, —COS—, —CO—, —OCO— or a combination of any of them with an arylene group:

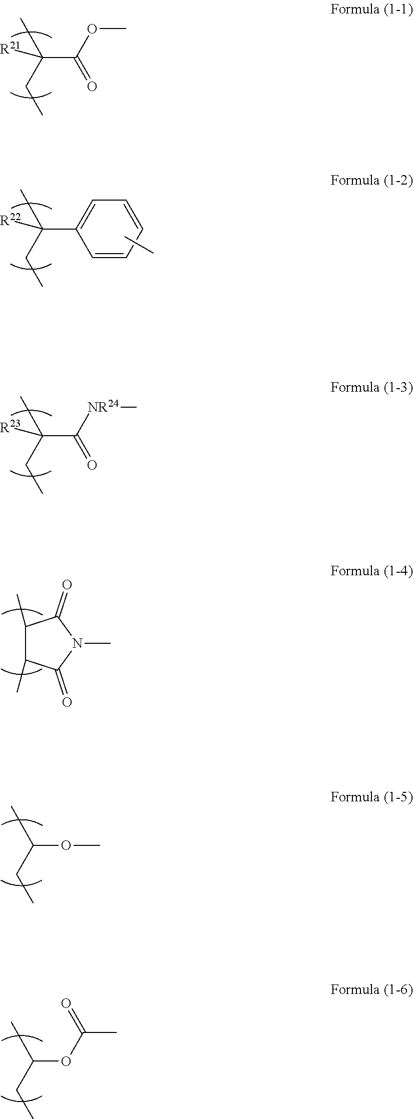

where R²¹ is a hydrogen atom, a methyl group, a chlorine atom or a phenyl group; R²² is a hydrogen atom or a methyl group; R²³ is a hydrogen atom, a methyl group, a chlorine atom or a phenyl group; and R²⁴ is a hydrogen atom or an alkyl group containing 1 to 4 carbon atoms).

As the monomer unit constituting the photo-alignment constitutional unit, examples include at least one kind selected from the group consisting of the formulae (1-1) to (1-6). When Z¹ is at least one kind selected from the group consisting of constitutional units represented by the formula (1-2), -L¹¹-X may be bound to any of the ortho-, meta- and para-positions. Of them, -L¹¹-X is preferably bound to the para-position, since the distance between the photo-alignment groups decreases with ease, and the photo-alignment property is easily obtained.

As the monomer unit constituting the photo-alignment constitutional unit, from the viewpoint of raw material availability, at least one kind selected from the group consisting of constitutional units represented by the formulae (1-1) and (1-2) is preferred. The monomer unit constituting the photo-alignment constitutional unit is more preferably at least one kind selected from the group consisting of constitutional units represented by the formula (1-2), due to the following reasons. The copolymer (B) is more likely to be non-liquid crystal; the copolymer (B) phase-separates from the side-chain liquid crystal polymer (A) with ease; the homeotropic alignment property of the side-chain liquid crystal polymer (A) improves; and since the rigidity of the photo-alignment constitutional unit of the copolymer (B) increases, the distance between the photo-alignment groups decreases with ease, and the excellent photo-alignment property is easily obtained.

When the copolymer contains a styrene skeleton and thereby contains many n-electron systems, due to the interaction of the r-electron systems, the adhesion of the alignment layer-cum-retardation layer formed from the photo-alignment thermosetting liquid crystal composition of the present disclosure to the liquid crystal material directly stacked on the alignment layer-cum-retardation layer, is thought to increase.

L¹¹ is a single bond, —O—, —S—, —COO—, —COS—, —CO—, —OCO— or a combination of any of them with an arylene group, and L¹¹ binds the monomer unit to the photo-alignment group X. In the copolymer (B) of the present disclosure, the photo-alignment constitutional unit does not have a linear alkylene chain between the photo-alignment group and the monomer unit. Accordingly, as described above, the copolymer (B) is likely to be non-liquid crystal. As a result, it is estimated that the compatibility of the copolymer (B) with the side-chain liquid crystal polymer (A) decreases; the copolymer (B) phase-separates from the side-chain liquid crystal polymer (A) with ease; the rigidity of the copolymer (B) increases; the distance between the photo-alignment groups decreases; and the excellent photo-alignment property is obtained.

When L¹¹ is a single bond, the photo-alignment group X is directly bound to a monomer unit Z¹. As the divalent linking group, examples include, but are not limited to, —O—, —S—, —COO—, —COS—, —CO—, —OCO—, —C₆H₄—, —C₆H₄O—, —OCOC₆H₄O—, —COOC₆H₄O— and —OC₆H₄O— (where —C₆H₄— is a phenylene group).

The photo-alignment group is a functional group that exhibits anisotropy by causing a photoreaction by light irradiation. The photo-alignment group is preferably a functional group that causes a photodimerization reaction or a photoisomerization reaction.

As the photo-alignment group that causes a photodimerization reaction, examples include, but are not limited to, a cinnamoyl group, a chalcone group, a coumarin group, an anthracene group, a quinoline group, an azobenzene group and a stilbene group. The benzene ring of these functional groups may contain a substituent. The substituent is not particularly limited, as long as it does not interfere with a photodimerization reaction. As the substituent, examples include, but are not limited to, an alkyl group, an aryl group, a cycloalkyl group, an alkoxy group, an aryloxy group, a hydroxy group, a halogen atom, a trifluoromethyl group and a cyano group.

The photo-alignment group that causes a photoisomerization reaction, is preferably a photo-alignment group that causes a cis-trans isomerization reaction, such as a cinnamoyl group, a chalcone group, an azobenzene group and a stilbene group. The benzene ring of these functional groups may contain a substituent. The substituent is not particularly limited, as long as it does not interfere with a photoisomerization reaction. As the substituent, examples include, but are not limited to, an alkoxy group, an alkyl group, a halogen atom, a trifluoromethyl group and a cyano group.

Of them, the photo-alignment group is preferably a cinnamoyl group. More specifically, the photo-alignment group is preferably at least one kind of cinnamoyl group selected from the group consisting of the following formulae (x-1) and (x-2).

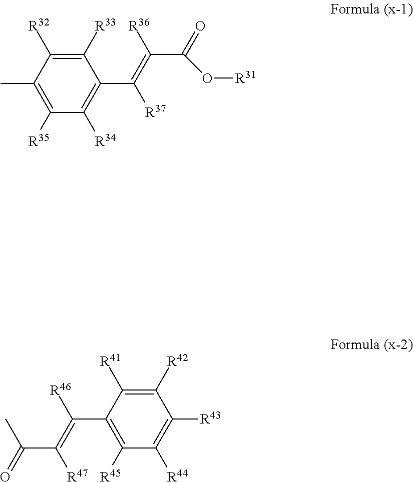

In the formula (x-1), R³¹ is a hydrogen atom, an alkyl group containing 1 to 18 carbon atoms, an aryl group containing 1 to 18 carbon atoms, or a cycloalkyl group containing 1 to 18 carbon atoms. However, the alkyl group, the aryl group and the cycloalkyl group may be bound via an ether bond, an ester bond, an amide bond or a urea bond and may contain a substituent. R³², R³³, R³⁴ and R³⁵ are each independently a hydrogen atom, a halogen atom, an alkyl group containing 1 to 18 carbon atoms, an aryl group containing 1 to 18 carbon atoms, a cycloalkyl group containing 1 to 18 carbon atoms, an alkoxy group containing 1 to 18 carbon atoms, or a cyano group. However, the alkyl group, the aryl group and the cycloalkyl group may be bound via an ether bond, an ester bond, an amide bond or a urea bond and may contain a substituent. R³⁶ and R³⁷ are each independently a hydrogen atom, a halogen atom, an alkyl group containing 1 to 18 carbon atoms, an aryl group containing 1 to 18 carbon atoms, or an alkoxy group containing 1 to 18 carbon atoms.

In the formula (x-2), R⁴¹, R⁴², R⁴³, R⁴⁴ and R⁴⁵ are each independently a hydrogen atom, a halogen atom, an alkyl group containing 1 to 18 carbon atoms, an aryl containing 1 to 18 carbon atoms, a cycloalkyl group containing 1 to 18 carbon atoms, an alkoxy group containing 1 to 18 carbon atoms, or a cyano group. However, the alkyl group, the aryl group and the cycloalkyl group may be bound via an ether bond, an ester bond, an amide bond or a urea bond and may contain a substituent. R⁴⁶ and R⁴⁷ are each independently a hydrogen atom, a halogen atom, an alkyl group containing 1 to 18 carbon atoms, an aryl group containing 1 to 18 carbon atoms, or an alkoxy group containing 1 to 18 carbon atoms.

When the photo-alignment group is a cinnamoyl group and is a group represented by the formula (x-1), the benzene ring of the styrene skeleton (the formula (1-2) contained in the monomer unit may be the benzene ring of the cinnamoyl group.

The cinnamoyl group represented by the formula (x-1) is more preferably a group represented by the following formula (x-3):

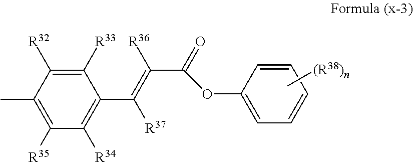

where R³² to R³⁷ are the same as those of the formula (x-1); R³⁸ is a hydrogen atom, an alkoxy group containing 1 to 18 carbon atoms, a cyano group an alkyl group containing 1 to 18 carbon atoms, a phenyl group, a biphenyl group or a cyclohexyl group (however, the alkyl group, the phenyl group, the biphenyl group and the cyclohexyl group may be bound via an ether bond, an ester bond, an amide bond or a urea bond); n is from 1 to 5; and R³⁸ may be bound to any of the ortho-, meta- and para-positions. When n is from 2 to 5, R³⁸s may be the same or different from each other. It is preferable that n is 1 and R³⁸ is bound to the para-position.

The copolymer may contain one kind of the photo-alignment constitutional unit or may contain two or more kinds of such photo-alignment constitutional units.

For the synthesis of the copolymer, monomers which contain a photo-alignment group and from which the photo-alignment constitutional unit is derived, can be used. The monomers containing a photo-alignment group may be used solely or in combination of two or more.

When the amount of the constitutional units contained in the whole copolymer is 100% by mole, the content of the photo-alignment constitutional unit in the copolymer is in a range of from 10% by mole to 90% by mole, and preferably in a range of from 20% by mole to 80% by mole. When the content of the photo-alignment constitutional unit is small, a decrease in sensitivity may be obtained, thereby making it difficult to provide a good liquid crystal aligning ability. On the other hand, when the content of the photo-alignment constitutional unit is large, the content of the thermally crosslinkable constitutional unit is relatively small. Accordingly, a sufficient thermosetting property may not be obtained, thereby making it difficult to maintain a good liquid crystal aligning ability.

### (2) Thermally Crosslinkable Constitutional Unit

In the present disclosure, the thermally crosslinkable constitutional unit is a moiety that binds to the thermal crosslinking agent by heating.

The thermally crosslinkable constitutional unit may be a constitutional unit containing a thermally crosslinkable group. The thermally crosslinkable group is not particularly limited, as long as it is a group that is crosslinkable by heating at a temperature of from 30° C. to 250° C. As the group, examples include, but are not limited to, a hydroxy group, a carboxy group, a phenolic hydroxy group, a mercapto group, a glycidyl group, an amino group and an amide group. From the viewpoint of reactivity, the thermally crosslinkable group is preferably an aliphatic hydroxy group, and more preferably a primary hydroxy group. The primary hydroxy group is a hydroxy group such that the carbon atom to which the hydroxy group is bound is a primary carbon atom.

The thermally crosslinkable group may be a self-crosslinkable group capable of crosslinking between crosslinkable groups of the same type. As the self-crosslinkable group, examples include, but are not limited to, a hydroxymethyl group, an alkoxymethyl group, a trialkoxysilyl group and a blocked isocyanate group.

The thermally crosslinkable constitutional unit preferably contains the self-crosslinkable group, since the thermally crosslinkable constitutional unit can also function as the thermal crosslinking agent, and the photo-alignment performance and the solvent resistance improve with ease. It is thought that when the thermally crosslinkable constitutional unit contains the self-crosslinkable group, the thermally crosslinkable constitutional unit easily reacts with the thermally crosslinkable constitutional unit in the molecules.

The thermally crosslinkable constitutional unit preferably contains at least one kind selected from the group consisting of a hydroxy group, a carboxy group and a mercapto group, from the viewpoint of the photo-alignment performance and solvent resistance.

From the point of view that the photo-alignment performance and solvent resistance can be improved more easily, the thermally crosslinkable constitutional unit preferably contains a constitutional unit containing at least one kind of thermally crosslinkable group selected from the group consisting of a hydroxy group, a carboxy group and a mercapto group, and a constitutional unit containing at least one kind of self-crosslinkable group selected from the group consisting of a hydroxymethyl group, an alkoxymethyl group, a trialkoxysilyl group and a blocked isocyanate group.

The alkoxymethyl group as the self-crosslinkable group is preferably an alkoxymethyl group containing an alkoxy group containing 1 to 6 carbon atoms, such as a methoxymethyl group, an ethoxymethyl group, various kinds of propoxymethyl groups, various kinds of butoxymethyl groups, and various kinds of pentoxymethyl groups. The alkoxymethyl group is more preferably an alkoxymethyl group containing an alkoxy group containing 1 to 4 carbon atoms, and still more preferably an alkoxymethyl group containing an alkoxy group containing 1 or 2 carbon atoms. In particular, a methoxymethyl group and an ethoxymethyl group are preferred from the viewpoint of a better crosslinking property.

As the monomer unit constituting the thermally crosslinkable constitutional unit, examples include, but are not limited to, acrylic ester, methacrylic ester, styrene, acrylamide, methacrylamide, maleimide, vinyl ether and vinyl ester.

When the thermally crosslinkable group is a carboxy group, the thermally crosslinkable constitutional unit may be a constitutional unit derived from acrylic acid or methacrylic acid. When the thermally crosslinkable group is a hydroxy group, the thermally crosslinkable constitutional unit may be a constitutional unit derived from vinyl alcohol.

For example, the thermally crosslinkable constitutional unit may be a constitutional unit represented by the following formula (2):

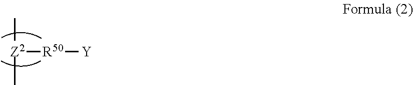

where Z² is at least one kind of monomer unit selected from the group consisting of the following formulae (2-1) to (2-6); R⁵⁰ is a linear alkylene group containing 4 to 11 carbon atoms and optionally containing —O— in its carbon chain; and Y is a thermally crosslinkable group:

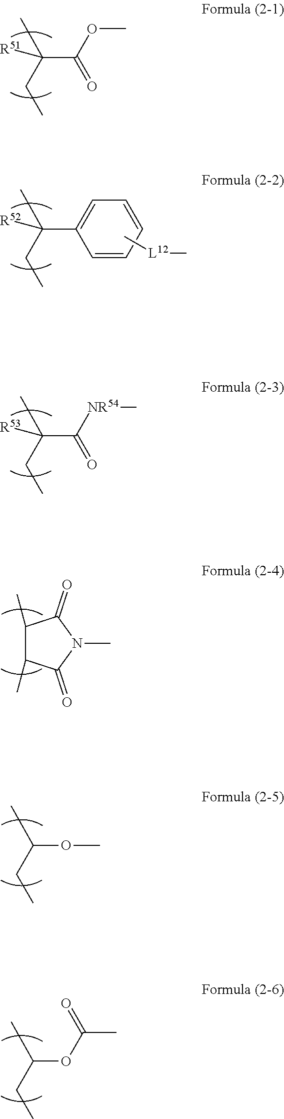

where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L¹² is a single bond, —O—, —S—, —COO—, —COS—, —CO— or —OCO—; and when L¹² is a single bond, R⁵⁰ is directly bound to a styrene skeleton.

When Z² is at least one kind selected from the group consisting of constitutional units represented by the formula (2-2), -L¹²-Y may be bound to any of the ortho-, meta- and para-positions. Of them, -L¹²-Y is preferably bound to the para-position, from the viewpoint of excellent crosslinking reactivity.

As the monomer unit constituting the thermally crosslinkable constitutional unit, from the viewpoint of raw material availability, at least one kind selected from the group consisting of constitutional units represented by the formulae (2-1) and (2-2) is preferred. The monomer unit constituting the thermally crosslinkable constitutional unit is more preferably at least one kind selected from the group consisting of constitutional units represented by the formula (2-2), due to the following reason. The copolymer (B) is more likely to be non-liquid crystal; the copolymer (B) phase-separates from the side-chain liquid crystal polymer (A) with ease; and the homeotropic alignment property of the side-chain liquid crystal polymer (A) improves.

In the formula (2), the thermally crosslinkable group as Y may be the same as the above-described thermally crosslinkable group. For example, the thermally crosslinkable group may be a self-crosslinkable group.

In the formula (2), the thermally crosslinkable group as Y may be at least one kind of thermally crosslinkable group selected from the group consisting of a hydroxy group, a carboxy group, a mercapto group, a glycidyl group, an amino group, an amide group, a hydroxymethyl group, an alkoxymethyl group, a trialkoxysilyl group, a blocked isocyanate group, and a methyl group substituted with an alkoxy group, and the thermally crosslinkable group as Y may be at least one kind of thermally crosslinkable group selected from the group consisting of a hydroxy group, a carboxy group, a mercapto group, a glycidyl group, an amino group and an amide group. The hydroxymethyl group and the alkoxymethyl group, which are self-crosslinkable groups, may each be a group that is changed into a hydroxymethyl group or an alkoxymethyl group when the methyl group (the methylene group in R⁵⁰) is substituted with a hydroxy group or an alkoxy group.

From the viewpoint of reactivity, the thermally crosslinkable group as Y preferably contains an aliphatic hydroxy group, and more preferably a primary hydroxy group.

In the formula (2), L¹² is a single bond, —O—, —S—, —COO—, —COS—, —CO— or —OCO—. When L¹² is a single bond, the thermally crosslinkable group Y is directly bound to the monomer unit Z².

R⁵⁰ is a linear alkylene group containing 1 to 11 carbon atoms and optionally containing —O— in its carbon chain. R⁵⁰ is preferably —(CH₂)ⱼ— or —(C₂H₄O)ₖ—C₂H₄— where j is from 1 to 11, and k is from 1 to 4. It is preferable that j is from 2 to 11 and k is from 1 to 4. It is more preferable that j is from 4 to 11 and k is from 2 to 4. When j and k are too small, in the thermally crosslinkable constitutional unit, the distance between the thermally crosslinkable group and the main skeleton of the copolymer decreases. Accordingly, there is a possibility that the thermal crosslinking agent is less likely to bind to the thermally crosslinkable group, and the reactivity between the thermally crosslinkable constitutional unit and the thermal crosslinking agent decreases. On the other hand, when j and k are too large, the chain length of the linking group in the thermally crosslinkable constitutional unit increases. Accordingly, there is a possibility that the thermally crosslinkable group at the terminal is less likely to appear on the surface; the thermal crosslinking agent is less likely to bind to the thermally crosslinkable group; and the reactivity between the thermally crosslinkable constitutional unit and the thermal crosslinking agent decreases.

The copolymer may contain one kind of the thermally crosslinkable constitutional unit or may contain two or more kinds of such thermally crosslinkable constitutional units.

For the synthesis of the copolymer, monomers which contain a thermally crosslinkable group and from which the thermally crosslinkable constitutional unit is derived, can be used. The monomers containing a thermally crosslinkable group may be used solely or in combination of two or more.

As the monomers containing a thermally crosslinkable group, examples include, but are not limited to, the following.

As acrylic ester compounds and methacrylic ester compounds, examples include, but are not limited to, monomers containing a hydroxy group and an acrylic group or a methacrylic group, such as 2-hydroxyethyl acrylate, 2-hydroxyethyl methacrylate, 3-hydroxypropyl acrylate, 3-hydroxylpropyl methacrylate, 4-hydroxybutyl acrylate, 4-hydroxybutyl methacrylate, 2,3-dihydroxypropyl acrylate, 2,3-dihydroxylpropyl methacrylate, diethylene glycol monoacrylate, diethylene glycol monomethacrylate, triethylene glycol monoacrylate, tetraethylene glycol monoacrylate, dipropylene glycol monoacrylate, tripropylene glycol monoacrylate and tetrapropylene glycol monoacrylate.

As styrene compounds, examples include, but are not limited to, monomers containing a hydroxy group and a styrene group, such as an esterified product of 4-vinylbenzoic acid and diol, an esterified product of 4-vinylbenzoic acid and diethylene glycol, an etherified product of hydroxystyrene and diol, and an etherified product of hydroxystyrene and diethylene glycol.

Also, monomers for forming the thermally crosslinkable constitutional unit can be used, such as monomers described in Paragraphs 0075 to 0079 in Japanese Patent No. 5626493. Also, the above-exemplified monomers in which the hydroxy group is substituted with a carboxy group or glycidyl group, can be used.

Among the monomers containing a thermally crosslinkable group, the monomers containing a self-crosslinkable group are, for example, acrylamide compounds or methacrylamide compounds substituted with a hydroxymethyl group or an alkoxymethyl group, such as N-hydroxymethylacrylamide, N-hydroxymethylmethacrylamide, N-methoxymethylacrylamide, N-methoxymethylmethacrylamide, N-ethoxymethylacrylamide, N-ethoxymethylmethacrylamide, N-butoxymethylacrylamide and N-butoxymethylmethacrylamide; monomers containing a trialkoxysilyl group, such as 3-trimethoxysilylpropyl acrylate, 3-triethoxysilylpropyl acrylate, 3-trimethoxysilylpropyl methacrylate and 3-triethoxysilylpropyl methacrylate; and monomers containing a blocked isocyanate group, such as 2-(0-(1′-methylpropylideneamino)carboxyamino)ethyl methacrylate and 2-(3,5-dimethylpyrazolyl)carbonylamino ethyl methacrylate.

When the amount of the constitutional units contained in the whole copolymer is 100% by mole, the content of the thermally crosslinkable constitutional unit in the copolymer is in a range of from 5% by mole to 90% by mole, and preferably in a range of from 20% by mole to 80% by mole. When the content of the thermally crosslinkable constitutional unit is small, a sufficient thermosetting property may not be obtained, thereby making it difficult to maintain a good liquid crystal aligning ability. On the other hand, when the content of the thermally crosslinkable constitutional unit is large, the content of the photo-alignment constitutional unit is relatively small. Accordingly, a decrease in sensitivity may be obtained, thereby making it difficult to provide a good liquid crystal aligning ability.

### (3) Different Constitutional Unit

In the present disclosure, the copolymer may contain, besides the photo-alignment constitutional unit and the thermally crosslinkable constitutional unit, a different constitutional unit which has neither a photo-alignment group nor a thermally crosslinkable group. When the copolymer contains the different constitutional unit, the copolymer can be heightened in, for example, solvent solubility, heat resistance and reactivity.

As the monomer unit constituting the constitutional unit which does not contain a photo-alignment group and a thermally crosslinkable group, examples include, but are not limited to, acrylic ester, methacrylic ester, maleimide, acrylamide, acrylonitrile, maleic anhydride, styrene and vinyl. As with the thermally crosslinkable constitutional unit described above, preferred are acrylic ester, methacrylic ester and styrene.

Such monomers for forming the constitutional unit which does not contain a photo-alignment group and a thermally crosslinkable group include, for example, an acrylic ester compound, a methacrylic ester compound, a maleimide compound, an acrylamide compound, acrylonitrile, maleic anhydride, a styrene compound and a vinyl compound.

More specifically, among the monomers described in Paragraphs 0036 to 0040 in International Publication No. WO2010/150748, monomers which does not contain any of a photo-alignment group and a thermally crosslinkable group, may be used.

Also, another constitutional unit such as a constitutional unit derived from a monomer containing a fluorinated alkyl group, may be contained. In this case, the copolymer (B) localizes on the surface of the coating film with ease, and the photo-alignment group is easily aligned on the surface of the coating film. From the viewpoint of localizing the copolymer (B) on the surface of the coating film with ease, the fluorinated alkyl group of the fluorinated alkyl group-containing monomer may be a fluorinated alkyl group in which the number of carbon atoms to which a fluorine atom is directly bound, is from 2 to 8.

The copolymer may contain one kind of the constitutional unit which does not contain a photo-alignment group and a thermally crosslinkable group or may contain two or more kinds of such constitutional units.

When the amount of the constitutional units contained in the whole copolymer is 100% by mole, the content of the constitutional unit which does not contain a photo-alignment group and a thermally crosslinkable group in the copolymer is preferably in a range of from 0 by mole to 50% by mole, and more preferably in a range of from 0% by mole to 30% by mole. When the content of the constitutional unit is large, the content of the photo-alignment constitutional unit and the thermally crosslinkable constitutional unit is relatively small. Accordingly, a decrease in sensitivity may be obtained, thereby making it difficult to provide a good liquid crystal aligning ability; moreover, a sufficient thermosetting property may not be obtained, thereby making it difficult to maintain a good liquid crystal aligning ability.

### (4) Copolymer (B)

The mass average molecular weight of the copolymer (B) is not particularly limited, and it may be from about 3,000 to 200,000, and preferably in a range of from 4,000 to 100,000. When the mass average molecular weight is too large, there is a possibility that a decrease in solubility in solvents or an increase in viscosity occurs and causes poor handleability and difficulty in forming a uniform film. When the mass average molecular weight is too small, there is a possibility that insufficient curing occurs during thermal curing, and a reduction in solvent resistance or heat resistance occurs.

The mass average molecular weight can be measured by gel permeation chromatography (GPC).

As the method for synthesizing the copolymer (B), examples include, but are not limited to, copolymerization of a monomer which contains a photo-alignment group and a monomer which contains a thermally crosslinkable group, by a conventional production method.

The copolymer (B) may be used in any of the following forms: the form of a solution in synthesizing the copolymer, the form of a powder, and the form of a solution obtained by re-dissolving a refined powder in a solvent described below.

As the copolymer (B), one kind of the copolymer may be used solely, or two or more kinds of such copolymers may be used in combination. From the viewpoint of exhibiting aligning ability with respect to the directly stacked liquid crystal material, with respect to 100 parts by mass of the solid content of the liquid crystal composition, the content of the copolymer (B) is preferably from 1 part by mass to 50 parts by mass, more preferably from 5 parts by mass to 40 parts by mass, still more preferably from 10 parts by mass to 30 parts by mass.

### 3. Thermal Crosslinking Agent

The photo-alignment thermosetting liquid crystal composition of the present disclosure contains the thermal crosslinking agent for bonding to the thermally crosslinkable group of the thermally crosslinkable constitutional unit. The thermal crosslinking agent can increase heat resistance and solvent resistance by bonding at least to the thermally crosslinkable group of the copolymer. The thermal crosslinking agent also binds to an optionally contained compound containing a thermally crosslinkable group or to the optionally contained side-chain liquid crystal polymer (A) containing a thermally crosslinkable group in a side chain, thereby improving the durability of the cured film or contributing to the improvement of functions.

As the thermal crosslinking agent, a compound that can bind to the thermally crosslinkable group of the thermally crosslinkable constitutional unit, is selected for use.

As the thermal crosslinking agent, examples include, but are not limited to, a compound containing a crosslinkable group that is reactive with the thermally crosslinkable group. As the crosslinkable group contained in the thermal crosslinking agent, examples include, but are not limited to, an epoxy group, a methylol group, an isocyanate group, a blocked isocyanate group, a carboxyl group, a blocked carboxyl group and a maleimide group. The thermal crosslinking agent preferably contains two or more crosslinkable groups, and more preferably 2 to 6 crosslinkable groups. As the thermal crosslinking agent, examples include, but are not limited to, an epoxy compound, a methylol compound and an isocyanato compound. Of them, a methylol compound is preferred.

As the methylol compound, examples include, but are not limited to, compounds such as alkoxymethylated glycoluril, alkoxymethylated benzoguanamine and alkoxymethylated melamine.

As the alkoxymethylated glycoluril, examples include, but are not limited to, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis (hydroxymethyl) urea, 1, 1, 3, 3-tetrakis (butoxymethyl) urea, 1, 1, 3, 3-tetrakis(methoxymethyl) urea, 1,3-bis(hydroxymethyl)-4,5-dihydroxy-2-imidazolinone and 1, 3-bis(methoxymethyl)-4, 5-dimethoxy-2-imidazolinone. Commercially-available products include the following, for example: compounds manufactured by Mitsui Cytec, Inc., such as glycoluril compounds (product names: CYMEL 1170 and POWDERLINK1174); methylated urea resin (product name: UFR65) and butylated urea resin (product names: UFR300, U-VAN10S60, U-VAN10R and U-VAN11HV); and urea/formaldehyde resin manufactured by Dainippon Ink and Chemicals Inc. (high condensation type, product names: BECKAMINE J-300S, BECKAMINE P-955 and BECKAMINE N).

As the alkoxymethylated benzoguanamine, examples include, but are not limited to, tetramethoxymethylbenzoguanamine. Commercially-available products include the following, for example: CYMEL 1123 (product name, manufactured by Mitsui Cytec, Inc.) and NIKALAC BX-4000, NIKALAC BX-37, NIKALAC BL-60 and NIKALAC BX-55H (product names, manufactured by SANWA Chemical Co., Ltd.)

As the alkoxymethylated melamine, examples include, but are not limited to, hexamethoxymethylmelamine. Commercially-available products include the following, for example: methoxymethyl-type melamine compounds (product names: CYMEL 300, CYMEL 301, CYMEL 303 and CYMEL 350, manufactured by Mitsui Cytec, Inc.); butoxymethyl-type melamine compounds (product names: MYCOAT 506 and MYCOAT 508, manufactured by Mitsui Cytec, Inc.); methoxymethyl-type melamine compounds (product names: NIKALAC MW-30, NIKALAC MW-22, NIKALAC MW-11, NIKALAC MS-001, NIKALAC MX-002, NIKALAC MX-730, NIKALAC MX-750 and NIKALAC MX-035, manufactured by SANWA Chemical Co., Ltd.); and butoxymethyl-type melamine compounds (product names: NIKALAC MX-45, NIKALAC MX-410 and NIKALAC MX-302, manufactured by: SANWA Chemical Co., Ltd.)

Also, a compound obtained by condensation of the melamine, urea, glycoluril and/or benzoguanamine compound in which the hydrogen atom of an amino group is substituted with a methylol or alkoxymethyl group, may be used. For example, high-molecular-weight compounds produced from the melamine compound and benzoguanamine compound described in U.S. Pat. No. 6,323,310, may be used. Commercially-available products of the melamine compound includes CYMEL 303 (product name, manufactured by Mitsui Cytec, Inc.), for example. Commercially-available products of the benzoguanamine compound include CYMEL 1123 (product name, manufactured by Mitsui Cytec, Inc.), for example.

As the thermal crosslinking agent, a polymer produced by use of an acrylamide or methacrylamide compound substituted with a hydroxymethyl or alkoxymethyl group, may be used.

For example, the thermal crosslinking agent described in Paragraphs 0049 and 0050 in International Publication No. WO2010/150748, may be used.

Also, a thermal crosslinking agent containing several benzene rings per molecule, may be used. As such a thermal crosslinking agent, examples include, but are not limited to, a phenol derivative which contains two or more hydroxymethyl or alkoxymethyl groups and which has a molecular weight of 1200 or less, a melamine-formaldehyde derivative which contains at least two free N-alkoxymethyl groups, and an alkoxymethyl glycoluril derivative. The phenol derivative containing hydroxymethyl groups can be obtained by reacting a counterpart phenol compound not containing a hydroxymethyl group with formaldehyde in the presence of a base catalyst.

As the epoxy compound, examples include, but are not limited to, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexylcarboxylate, 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexane carboxylate, ε-caprolactone—modified 3,4-epoxycyclohexylmethyl-3′,4′-epoxycyclohexane carboxylate, trimethylcaprolactone-modified 3,4-epoxycyclohexylmethyl-3′,4′-epoxycyclohexane carboxylate, R-methyl-5-valerolactone-modified 3,4-epoxycyclohexylmethyl-3′,4′-epoxycyclohexane carboxylate, methylene bis(3,4-epoxycyclohexane), di(3,4-epoxycyclohexylmethyl)ether of ethylene glycol, ethylene bis(3,4-epoxycyclohexane carboxylate), dioctyl epoxycyclohexahydrophthalate, di-2-ethylhexyl epoxycyclohexahydrophthalate, 1,4-butanediol diglycidyl ether, 1,6-hexanediol diglycidyl ether, neopentyl glycol diglycidyl ether, trimethylolpropane triglycidyl ether, polyethylene glycol diglycidyl ether, glycerin triglycidyl ether, and polypropylene glycol diglycidyl ethers; polyglycidyl ethers of polyether polyols each of which is obtained by adding one or more kinds of alkylene oxides to an aliphatic polyhydric alcohol (such as ethylene glycol, propylene glycol and glycerol); diglycidyl esters of aliphatic long-chain dibasic acids; monoglycidyl ethers of higher fatty alcohols; monoglycidyl ethers of phenol, cresol, butylphenol or polyether alcohols, each of which is obtained by adding alkylene oxide; glycidyl esters of higher fatty acids; epoxidized soybean oil; butyl epoxystearate; octyl epoxystearate; epoxidized linseed oil; and epoxidized polybutadiene.

Commercially-available products of the epoxy compounds include the following, for example: UVR-6100, UVR-6105, UVR-6110, UVR-6128, UVR-6200 and UVR-6216 (all manufactured by Union Carbide Corporation); CELLOXIDE 2021, CELLOXIDE 2021P, CELLOXIDE 2081, CELLOXIDE 2083, CELLOXIDE 2085, EPOLEAD GT-300, EPOLEAD GT-301, EPOLEAD GT-302, EPOLEAD GT-400, EPOLEAD 401 and EPOLEAD 403 (all manufactured by DAICEL Chemical Industries, Ltd.); KRM-2100, KRM-2110, KRM-2199, KRM-2400, KRM-2410, KRM-2408, KRM-2490, KRM-2200, KRM-2720 and KRM-2750 (all manufactured by Asahi Denka Co., Ltd.); CER-4221, CER-4221-E and CER-4221-H (all manufactured by Achiewell, LLC; Rapi-cure DVE-3, CHVE and PEPC (all manufactured by ISP); EPIKOTE 828, EPIKOTE 812, EPIKOTE 1031, EPIKOTE 872 and EPIKOTE CT508 (all manufactured by Japan Epoxy Resins Co., Ltd.); XDO (manufactured by Toagosei Co., Ltd.); and VECOMER 2010, VECOMER 2020, VECOMER 4010, VECOMER 4020 (all manufactured by AlliedSignal).

These thermal crosslinking agents may be used solely or in combination of two or more kinds.

In the present disclosure, from the viewpoint of improving the durability of the cured film, with respect to 100 parts by mass of the solid content of the photo-alignment thermosetting liquid crystal composition, the content of the thermal crosslinking agent is preferably from 0.1 parts by mass to 30 parts by mass, more preferably from 0.5 parts by mass to 25 parts by mass, and still more preferably from 1 part by mass to 20 parts by mass.

Also in the present disclosure, with respect to a total of 100 parts by mass of the side-chain liquid crystal polymer (A) and the copolymer (B), the content of the thermal crosslinking agent in the photo-alignment thermosetting liquid crystal composition is preferably from 1 part by mass to 30 parts by mass, more preferably from 2 parts by mass to 25 parts by mass, and still more preferably from 3 parts by mass to 25 parts by mass.

When the content of the thermal crosslinking agent is too small, there is a possibility that the heat resistance and solvent resistance of the cured film formed from the photo-alignment thermosetting liquid crystal composition decreases, and the homeotropic alignment property or liquid crystal aligning ability deteriorates. On the other hand, when the content is too large, there is a possibility that the homeotropic alignment property or liquid crystal aligning ability and the storage stability deteriorate.

### 4. Acid or Acid Generator

In the present disclosure, the photo-alignment thermosetting liquid crystal composition may contain an acid or an acid generator. By the acid or acid generator, the thermosetting reaction of the photo-alignment thermosetting liquid crystal composition of the present disclosure can be promoted.

The acid or acid generator is not particularly limited, as long as it is a sulfonic acid group-containing compound, hydrochloric acid, a salt of hydrochloric acid, or a compound that is pyrolyzed when drying or thermally curing the coating film to generate acid, that is, a compound that is pyrolyzed at a temperature of from 50° C. to 250° C. to generate acid. More specifically, those described in Paragraph 0054 in International Publication No. WO2010/150748 may be used.

In the present disclosure, with respect to 100 parts by mass of the solid content of the photo-alignment thermosetting liquid crystal composition, the content of the acid or acid generator in the photo-alignment thermosetting liquid crystal composition is preferably from 0.01 parts by mass to 20 parts by mass, more preferably from 0.05 parts by mass to 10 parts by mass, and still more preferably from 0.05 parts by mass to 5 parts by mass.

Also in the present disclosure, with respect to a total of 100 parts by mass of the side-chain liquid crystal polymer (A) and the copolymer (B), the content of the acid or acid generator in the photo-alignment thermosetting liquid crystal composition is preferably from 0.05 parts by mass to 20 parts by mass, more preferably from 0.1 parts by mass to 15 parts by mass, and still more preferably from 0.1 parts by mass to 10 parts by mass. By controlling the content of the acid or acid generator in the above ranges, a sufficient thermosetting property and solvent resistance can be provided, and high sensitivity to light irradiation can be also provided. On the other hand, when the content is too large, there is a possibility that the storage stability of the photo-alignment thermosetting liquid crystal composition deteriorates.

### 5. Solvent

The photo-alignment thermosetting liquid crystal composition of the present disclosure may contain a solvent from the viewpoint of the coatability thereof. The solvent may be appropriately selected from solvents known in the prior art in each of which the components contained in the photo-alignment thermosetting liquid crystal composition of the present disclosure can be dissolved or dispersed. Specific examples thereof include a hydrocarbon solvent such as hexane, cyclohexane and toluene; a ketone solvent such as methyl ethyl ketone, methyl isobutyl ketone, cyclopentanone and cyclohexanone; an ether solvent such as tetrahydrofuran, 1,3-dioxolan and propylene glycol monoethyl ether (PGME); a halogenated alkyl solvent such as chloroform and dichloromethane; an ester solvent such as ethyl acetate and propylene glycol monomethyl ether acetate; an amide solvent such as N, N-dimethylformamide and N-methylpyrrolidone; a sulfoxide solvent such as dimethylsulfoxide; and an alcohol solvent such as methanol, ethanol and propanol. In the present embodiment, one kind of solvent may be singly used, or two or more kinds of solvents may be used in combination.

In the photo-alignment thermosetting liquid crystal composition of the present disclosure, the content of the solvent is not particularly limited, as long as the components are uniformly dissolved in the solvent. In the composition containing the solvent, the solvent content is preferably from 50% by mass to 99% by mass, more preferably from 60% by mass to 95% by mass, and still more preferably from 70% by mass to 90% by mass.

When the solvent content is too large and the solid content is too small, there is a possibility that it is difficult to provide a retardation property, a liquid crystal aligning ability and a thermosetting property. When the solvent content is too small and the solid content is too large, the viscosity of the photo-alignment thermosetting liquid crystal composition increases, and it is difficult to form a uniform film.

The solid content denotes all the components of the photo-alignment thermosetting liquid crystal composition, from which any solvent is removed.

### 6. Other Components

The photo-alignment thermosetting liquid crystal composition of the present disclosure may contain other components, as far as advantageous effects thereof are not impaired. More specifically, as the other components, the composition may contain the following, for example: a polymerizable liquid crystal compound different from the side-chain liquid crystal polymer (A); a polymerizable compound containing, per molecule, two or more polymerizable groups which can improve the hardness and durability of the coating film; a photopolymerization initiator; a compound containing a polymerizable group and a thermally crosslinkable group; a compound containing a photo-alignment group and a thermally crosslinkable group, which is different from the copolymer (B); a sensitizer; a levelling agent; a polymerization inhibitor; an antioxidant and a light stabilizer. These components may be appropriately selected from materials known in the prior art.

(1) Polymerizable Liquid Crystal Compound Different from the Side-Chain Liquid Crystal Polymer (A)

From the viewpoint of controlling the retardation and improving the durability, as needed, the photo-alignment thermosetting liquid crystal composition of the present disclosure may further contain the polymerizable liquid crystal compound different from the side-chain liquid crystal polymer (A).

In one embodiment of the present disclosure, the polymerizable liquid crystal compound different from the side-chain liquid crystal polymer (A) may be appropriately selected from polymerizable liquid crystal compounds known in the prior art. As the polymerizable liquid crystal compound, examples include, but are not limited to, a so-called low-molecular-weight polymerizable liquid crystal monomer. In the present embodiment, the polymerizable liquid crystal compound is preferably a polymerizable liquid crystal compound containing a polymerizable group at least at one terminal of its rod-shaped mesogen, and is more preferably a polymerizable liquid crystal compound containing polymerizable groups at both terminals of its rod-shaped mesogen, from the viewpoint of ease of homeotropic alignment when combined with the side-chain liquid crystal polymer (A).

The mesogen or rod-shaped mesogen contained in the polymerizable liquid crystal compound may be the same mesogen or rod-shaped mesogen contained in the liquid crystal constitutional unit contained in the above-mentioned side-chain liquid crystal polymer.

As the polymerizable group contained in the polymerizable liquid crystal compound, examples include, but are not limited to, a cyclic-ether-containing group such as an oxirane ring and an oxetane ring, and an ethylenic double bond-containing group. Out of these examples, an ethylenic double bond-containing group is preferred since the liquid crystal compound shows light curability and is excellent in handleability. As the ethylenic-double-bond-containing group, examples include, but are not limited to, a vinyl group, an allyl group and a (meth)acryloyl group. Out of these examples, a (meth)acryloyl group is preferred.

In the present embodiment, the polymerizable liquid crystal compound is preferably one or more kinds of compounds selected from a compound represented by the following general formula (IV) and a compound represented by the following general formula (V) from the viewpoint of exhibiting a liquid crystal aligning property and being excellent in heat resistance.

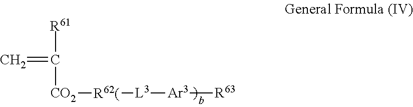

where R⁶¹ is a hydrogen atom or a methyl group; R⁶² is a group represented by —(CH₂)ₚ—, or —(C₂H₄O)_{p′}—; L³ is a direct bond or a linking group represented by —O—, —O—C(═O)—, or —C(═O)—O—; Ar³ is an arylene group containing 6 to 10 carbon atoms and optionally containing a substituent; plural L³s, as well as plural Ar³s, may be the same or different from each other; R⁶³ is —F, —Cl, —CN, —OCF₃, —OCF₂H, —NCO, —NCS, —NO₂, —NHC(═O)—R⁶⁴, —C(═O)—OR⁶⁴, —OH, —SH, —CHO, —SO₃H, —NR⁶⁴₂, —R⁶⁵, or —OR⁶⁵; R⁶⁴ is a hydrogen atom or an alkyl group containing 1 to 6 carbon atoms; R⁶⁵ is an alkyl group containing 1 to 6 carbon atoms; b is an integer of from 2 to 4; and p and p′ are each independently an integer of from 2 to 10.

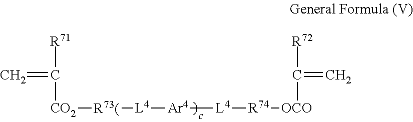

where each R⁷¹ is independently a hydrogen atom or a methyl group; each R¹² is independently a hydrogen atom or a methyl group; R⁷³ is a group represented by —(CH₂)_{q}— or —(C₂H₄O)_{q′}—; R⁷⁴ is a group represented by —(CH₂)ᵣ— or —(OC₂H₄)_{r′}—; L⁴ is a direct bond or a linking group represented by —O—, —O—C(═O)— or —C(═O)—O—; Ar⁴ is an arylene group containing 6 to 10 carbon atoms and optionally containing a substituent; plural L⁴s, as well as Ar⁴s, may be the same as or different from each other; c is an integer of from 2 to 4; and q, q′, r and r′ are each independently an integer of from 2 to 10.

L³ and L⁴ may be the same as L² in the general formula (I).

Ar³ and Ar⁴ may be the same as Ar¹ in the general formula (I).

More specifically, as the compounds represented by the general formulae (IV) and (V), polymerizable liquid crystal compounds described in Paragraphs 0057 to 0064 in International Publication No. WO2018/003498, may be used, for example.

In the present embodiment, as the polymerizable liquid crystal compound different from the side-chain liquid crystal polymer (A), one kind of polymerizable liquid crystal compound may be used solely, or two or more kinds of polymerizable liquid crystal compounds may be used in combination.

When the polymerizable liquid crystal compound different from the side-chain liquid crystal polymer (A) is used in the photo-alignment thermosetting liquid crystal composition of the present disclosure, the content of the polymerizable liquid crystal compound is not particularly limited, as long as the retardation or the improvement of the durability is appropriately controlled. With respect to 100 parts by mass of the solid content of the photo-alignment thermosetting liquid crystal composition, the content of the polymerizable liquid crystal compound is preferably from 1 part by mass to 90 parts by mass, more preferably from 5 parts by mass to 50 parts by mass, and still more preferably from 10 parts by mass to 30 parts by mass.

When the polymerizable liquid crystal compound different from the side-chain liquid crystal polymer (A) is used in the photo-alignment thermosetting liquid crystal composition of the present disclosure, with respect to 100 parts by mass of the side-chain liquid crystal polymer (A), the content of the polymerizable liquid crystal compound is preferably from 5 parts by mass to 100 parts by mass, more preferably from 10 parts by mass to 60 parts by mass, and still more preferably from 20 parts by mass to 40 parts by mass.

### (2) Polymerizable Compound Containing Two or More Polymerizable Groups Per Molecule

From the viewpoint of improving the hardness and durability of the coating film, as needed, the photo-alignment thermosetting liquid crystal composition of the present disclosure may further contain a polymerizable compound containing two or more polymerizable groups per molecule. As the polymerizable compound having two or more polymerizable groups per molecule, besides the above-described polymerizable liquid crystal compound, a polymerizable compound not having a liquid crystal property may be used.

As the polymerizable compound having two or more polymerizable groups per molecule, a so-called polyfunctional monomer may be used, such as diethylene glycol di(meth)acrylate, dipropylene glycol di(meth)acrylate, 1,6-hexanediol di(meth)acrylate, neopentyl glycol di(meth)acrylate, pentaerythritol tri(meth)acrylate, pentaerythritol tetra(meth)acrylate, dipentaerythritol hexa(meth)acrylate, trimethylolpropane tri(meth)acrylate, ditrimethylolpropane tetra(meth)acrylate, dipentaerythritol penta(meth)acrylate, tripentaerythritol octa(meth)acrylate, tetrapentaerythritol deca(meth)acrylate, isocyanuric acid tri(meth)acrylate, isocyanuric acid di(meth)acrylate, polyester tri(meth)acrylate, polyester di(meth)acrylate, bisphenol di(meth)acrylate, diglycerin tetra(meth)acrylate, adamantyl di(meth)acrylate, isobornyl di(meth)acrylate, dicyclopentane di(meth)acrylate, tricyclodecane di(meth)acrylate, ditrimethylolpropane tetra(meth)acrylate, and these (meth)acrylates modified with PO, EO or the like. From the viewpoint of promoting a crosslinking reaction and improving the durability of the coating film, the polymerizable compound having two or more polymerizable groups per molecule, may be a polymerizable compound containing three or more polymerizable groups per molecule, such as pentaerythritol triacrylate (PETA), dipentaerythritol hexaacrylate (DPHA), pentaerythritol tetraacrylate (PETTA), dipentaerythritol pentaacrylate (DPPA) and trimethylolpropane triacrylate (TMPTA).

When a polymerizable compound containing two or more polymerizable groups per molecule and not having a liquid crystal property, is used in the photo-alignment thermosetting liquid crystal composition of the present disclosure, the content of the polymerizable compound is not particularly limited, as long as the improvement of the hardness and durability of the coating film is appropriately controlled. With respect to 100 parts by mass of the solid content of the photo-alignment thermosetting liquid crystal composition, the content of the polymerizable compound is preferably from 1 part by mass to 40 parts by mass, more preferably from 5 parts by mass to 35 parts by mass, and still more preferably from 10 parts by mass to 30 parts by mass.

### (3) Photopolymerization Initiator

When the photo-alignment thermosetting liquid crystal composition of the present disclosure contains the compound containing polymerizable groups such as an ethylenic double bond-containing group, it is preferable that the photo-alignment thermosetting liquid crystal composition further contains a photopolymerization initiator, from the viewpoint of obtaining the alignment layer-cum-retardation layer having better adhesion to the stacked liquid crystal layer.

As the photopolymerization initiator, a radical photopolymerization initiator is preferably used, which produces a radical species by light irradiation. The photopolymerization initiator may be appropriately selected from photopolymerization initiators known in the prior art. As the photopolymerization initiator, examples include, but are not limited to, an aromatic ketone such as thioxanthone, an α-aminoalkylphenone, an α-hydroxyketone, an acylphosphine oxide, an oxime ester, an aromatic onium salt, an organic peroxide, a thio compound, a hexaaryl biimidazole compound, a ketoxime ester compound, a borate compound, an azinium compound, a metallocene compound, an active ester compound, a compound containing a carbon-halogen bond, and an alkylamine compound. When the photo-alignment thermosetting liquid crystal composition of the present disclosure contains the acid or acid generator, it is preferable that the photopolymerization initiator is not a basic photopolymerization initiator such as an aminoalkylphenone-based photopolymerization initiator, and it is preferable that the photopolymerization initiator is a photopolymerization initiator not containing a basic group. From the viewpoint of curing the inside of the coating film and increasing the durability, at least one kind selected from the group consisting of an acylphosphine oxide-based polymerization initiator, an α-hydroxyketone-based polymerization initiator and an oxime ester-based polymerization initiator, is preferred.

More specifically, as the photopolymerization initiator, photopolymerization initiators described in Paragraphs 0067 to 0070 in International Publication No. WO2018/003498, may be used, for example.

In the present embodiment, one kind of the photopolymerization initiator may be used solely, or two or more kinds of such initiators may be used in combination.

When the photopolymerization initiator is used in the photo-alignment thermosetting liquid crystal composition of the present disclosure, the content of the photopolymerization initiator is not particularly limited, as long as the curing of the compound containing polymerizable groups is promoted. With respect to 100 parts by mass of the solid content of the photo-alignment thermosetting liquid crystal composition, the content of the photopolymerization initiator is preferably from 0.1 parts by mass to 10 parts by mass, more preferably from 0.5 parts by mass to 9 parts by mass, and still more preferably from 1 part by mass to 8 parts by mass.

### (4) Compound Containing a Polymerizable Group and a Thermally Crosslinkable Group

From the viewpoint of improving the hardness and durability of the coating film and improving interlayer adhesion, as needed, the photo-alignment thermosetting liquid crystal composition of the present disclosure may further contain a compound containing a polymerizable group and a thermally crosslinkable group. The polymerizable group may be the same as the polymerizable group of the polymerizable liquid crystal compound described above. The thermally crosslinkable group may be the same as the thermally crosslinkable group of the copolymer (B) described above.

The compound containing a polymerizable group and a thermally crosslinkable group is preferably a compound containing an ethylenically unsaturated double bond group and at least one of a hydroxy group and a carboxy group, and more preferably a compound containing an ethylenically unsaturated double bond group, an aromatic hydrocarbon group, and at least one of a hydroxy group and a carboxy group. The compound containing an ethylenically unsaturated double bond group, an aromatic hydrocarbon group, and at least one of a hydroxy group and a carboxy group is preferred because, when the compound is contained, the alignment layer-cum-retardation layer having better adhesion to the stacked liquid crystal layer is obtained, without inhibiting the liquid crystal aligning ability of the surface.

Also, a hydroxy group-containing polyfunctional acrylate, which is a compound containing a hydroxy group and two or more ethylenically unsaturated double bond groups, is preferably used from the viewpoint of improving the hardness and durability of the coating film and improving the interlayer adhesion.

More specifically, as the compound containing a polymerizable group and a thermally crosslinkable group, such a compound described in Paragraphs 0106 to 0112 in International Publication No. WO2014/073658, an aromatic hydrocarbon group-containing, thermally-crosslinkable polymerizable compound described in Paragraphs 0087 to 0100 in JP-A No. 2017-068019, or a hydroxy group-containing polyfunctional acrylate described in Paragraphs 0125 to 0126 in International Publication No. WO2013/054784 may be used, for example.

In the present embodiment, one kind of the compound containing a polymerizable group and a thermally crosslinkable group may be used solely, or two or more kinds of such compounds may be used in combination.

When the compound containing a polymerizable group and a thermally crosslinkable group is used in the photo-alignment thermosetting liquid crystal composition of the present disclosure, the content of the compound is not particularly limited, as long as the durability and interlayer adhesion are improved. With respect to 100 parts by mass of the solid content of the photo-alignment thermosetting liquid crystal composition, the content of the compound is preferably from 1 part by mass to 50 parts by mass, more preferably from 5 parts by mass to 40 parts by mass, and still more preferably from 10 parts by mass to 30 parts by mass.

(5) Compound Containing a Polymerizable Group and a Thermally Crosslinkable Group, which is Different from the Copolymer (B)

From the viewpoint of improving the durability and photo-alignment property of the coating film, as needed, the photo-alignment thermosetting liquid crystal composition of the present disclosure may further contain a compound containing a photo-alignment group and a thermally crosslinkable group, which is different from the copolymer (B). The photo-alignment group may be the same as the photo-alignment group of the copolymer (B) described above. The thermally crosslinkable group may be the same as the thermally crosslinkable group of the copolymer (B) described above.

As the compound containing a photo-alignment group and a thermally crosslinkable group, which is different from the copolymer (B), examples include, but are not limited to, a low-molecular-weight compound of a non-polymer. The compound containing a photo-alignment group and a thermally crosslinkable group, which is different from the copolymer (B), is preferably a compound containing at least one of a cinnamoyl group, a chalcone group, an azobenzene group and a stilbene group and at least one of a hydroxy group and a carboxy group, and more preferably a compound containing a cinnamoyl group and at least one of a hydroxy group and a carboxy group. The compound containing at least one of a hydroxy group and a carboxy group, an aromatic hydrocarbon group and an ethylenically unsaturated double bond group is preferred because, when the compound is contained, the alignment layer-cum-retardation layer having better adhesion to the stacked liquid crystal layer is obtained, without inhibiting the liquid crystal aligning ability of the surface.

More specifically, as the compound containing a photo-alignment group and a thermally crosslinkable group, the compound containing a photo-alignment group and thermally crosslinkable group described in Paragraphs 0064 to 0074 in International Publication No. WO2013/054784, may be used, for example.

In the present embodiment, one kind of the compound containing a photo-alignment group and a thermally crosslinkable group, which is different from the copolymer (B), may be used solely, or two or more kinds of such compounds may be used in combination.

When the compound containing a photo-alignment group and a thermally crosslinkable group, which is different from the copolymer (B), is used in the photo-alignment thermosetting liquid crystal composition of the present disclosure, the content of the compound is not particularly limited, as long as the durability and photo-alignment property of the coating film are improved. With respect to 100 parts by mass of the solid content of the photo-alignment thermosetting liquid crystal composition, the content of the compound is preferably from 1 part by mass to 50 parts by mass, more preferably from 10 parts by mass to 40 parts by mass, and still more preferably from 15 parts by mass to 30 parts by mass.

### (6) Sensitizer

The photo-alignment thermosetting liquid crystal composition of the present disclosure may contain a sensitizer. By the sensitizer, a photoreaction such as a photodimerization reaction and a photoisomerization reaction are promoted.

More specifically, as the sensitizer, a sensitizer described in Paragraph 0057 in International Publication No. WO2010/150748 may be used.

The sensitizer is preferably a benzophenone derivative or a nitrophenyl compound. As the sensitizer, one kind of compound may be used solely, or two or more kinds of compounds may be used in combination.

When the sensitizer is used in the photo-alignment thermosetting liquid crystal composition of the present disclosure, the content of the sensitizer is not particularly limited, as long as the durability and photo-alignment property of the coating film are improved. With respect to 100 parts by mass of the solid content of the photo-alignment thermosetting liquid crystal composition, the content of the sensitizer is preferably from 0.1 parts by mass to 20 parts by mass, more preferably from 0.2 parts by mass to 10 parts by mass, and still more preferably from 0.5 parts by mass to 10 parts by mass.

To achieve the second object, in the first photo-alignment thermosetting liquid crystal composition, the composition of the below-described second photo-alignment thermosetting liquid crystal composition may be applied.

More specifically, the first photo-alignment thermosetting liquid crystal composition may be a photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a photo-alignment group in a side chain and a thermally crosslinkable constitutional unit containing a constitutional unit represented by the following formula (2), and
a thermal crosslinking agent (C) for bonding to a thermally crosslinkable group of the thermally crosslinkable constitutional unit,
wherein the side-chain liquid crystal polymer (A) satisfies any of the following (i) to (vi):
   (i) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a primary carbon of the alkylene group which optionally contains —O— in its carbon chain and in which a total of a carbon atom number and an oxygen atom number is smaller than a linear alkylene group which contains 4 to 11 carbon atoms and which optionally contains —O— in its carbon chain in the thermally crosslinkable constitutional unit of the copolymer (B);
   (ii) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a secondary or tertiary carbon of the alkylene group;
   (iii) the side-chain liquid crystal polymer (A) contains a non-liquid crystal, thermally crosslinkable constitutional unit containing, in a side chain, an arylene group, an alkylene group and at least one kind of thermally crosslinkable group selected from the group consisting of a hydroxy group, a mercapto group and an amino group, and the non-liquid crystal, thermally crosslinkable constitutional unit of the side-chain liquid crystal polymer (A) has a structure such that the thermally crosslinkable group is bound to the arylene group;
   (iv) the side-chain liquid crystal polymer (A) contains a non-liquid crystal, thermally crosslinkable constitutional unit containing an arylene group, an alkylene group and at least one kind of thermally crosslinkable group selected from the group consisting of a carboxy group, a glycidyl group and an amide group; the non-liquid crystal, thermally crosslinkable constitutional unit of the side-chain liquid crystal polymer (A) has a structure such that the thermally crosslinkable group is bound to the arylene group; and the arylene group has a structure such that it is bound to a carbon or oxygen atom of the alkylene group which optionally contains —O— in its carbon chain or at its terminal and in which a total of a carbon atom number and an oxygen atom number is 3 or more smaller than the linear alkylene group which contains 4 to 11 carbon atoms and which optionally contains —O— in the carbon chain in the thermally crosslinkable constitutional unit of the copolymer (B);
   (v) the side-chain liquid crystal polymer (A) contains a thermally crosslinkable constitutional unit containing no alkylene group in a side chain and a thermally crosslinkable group in the side chain; and
   (vi) the side-chain liquid crystal polymer (A) does not contain a non-liquid crystal, thermally crosslinkable constitutional unit containing a thermally crosslinkable group and an alkylene group in a side chain and a thermally crosslinkable constitutional unit containing a thermally crosslinkable group in a side chain:

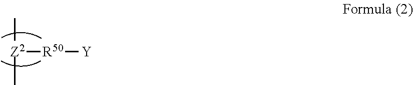

where Z² is at least one kind of monomer unit selected from the group consisting of the following formulae (2-1) to (2-6); R⁵⁰ is a linear alkylene group containing 4 to 11 carbon atoms and optionally containing —O— in its carbon chain; and Y is at least one kind of thermally crosslinkable group selected from the group consisting of a hydroxy group, a carboxy group, a mercapto group, a glycidyl group, an amino group and an amide group:

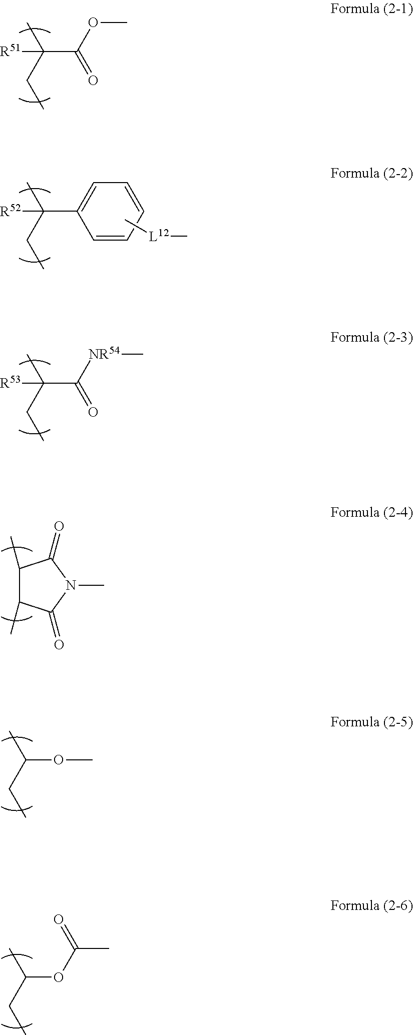

where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L¹² is a single bond, —O—, —S—, —COO—, —COS—, —CO— or —OCO—; and when L² is a single bond, R⁵⁰ is directly bound to a styrene skeleton.

### 7. Photo-Alignment Thermosetting Liquid Crystal Composition

The method for preparing the photo-alignment thermosetting liquid crystal composition of the present disclosure is not particularly limited. From the viewpoint of long storage stability, it is preferable to mix the side-chain liquid crystal polymer (A), the copolymer (B), the thermal crosslinking agent (C) and other components, followed by the addition of the acid or acid generator. In the case of adding the acid or acid generator at the beginning, a compound which is pyrolyzed to produce acid when drying and thermally curing the coating film, is preferably used as the acid or acid generator.

In the preparation of the photo-alignment thermosetting liquid crystal composition of the present disclosure, the solution of the side-chain liquid crystal polymer (A), which is obtained by a polymerization reaction in the solvent, or the solution of the copolymer (B) can be used as it is. In this case, as described above, the thermal crosslinking agent, other components and so on are added to the solution of the side-chain liquid crystal polymer (A) or the solution of the copolymer (B); the solution is made into a uniform solution; and then the acid or acid generator is added thereto. At this time, another solution may be further added for the purpose of controlling the concentration. The solvent used in the copolymer production step and the solvent used to control the concentration of the photo-alignment thermosetting liquid crystal composition may be the same or different from each other.

The thus-prepared solution of the photo-alignment thermosetting liquid crystal composition is preferably filtered through a filter having a pore diameter of about 0.2 μm or the like before being used.

The applications of the photo-alignment thermosetting liquid crystal composition of the present disclosure includes the following: since the side-chain liquid crystal polymer (A) is homeotropically aligned with ease and the copolymer (B) has an excellent ability to align the liquid crystal material directly stacked thereon, the photo-alignment thermosetting liquid crystal composition is suitable for producing the alignment layer-cum-retardation layer that functions as both the alignment layer and the retardation layer solely or for producing the alignment film-cum-retardation film.

### B. Alignment Film-Cum-Retardation Film

The alignment film-cum-retardation film of the present disclosure is an alignment film-cum-retardation film comprising an alignment layer-cum-retardation layer, wherein the alignment layer-cum-retardation layer is a cured film of the photo-alignment thermosetting liquid crystal composition of the present disclosure.

Hereinafter, the components of the alignment film-cum-retardation film of the present disclosure will be described.

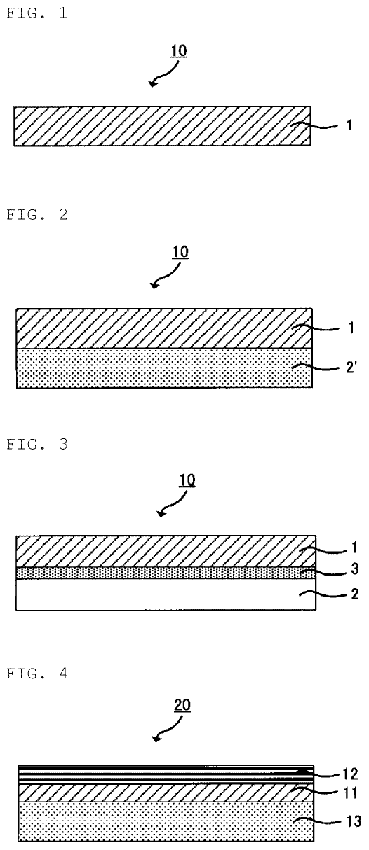

The layer configuration of the alignment film-cum-retardation film will be described with reference to figures. Each of FIGS. 1 to 3 shows an embodiment of the alignment film-cum-retardation film of the present disclosure. An embodiment of an alignment film-cum-retardation film 10 shown in FIG. 1 is an alignment film-cum-retardation film made of only an alignment layer-cum-retardation layer 1. In an embodiment of the alignment film-cum-retardation film 10 shown in FIG. 2, the alignment layer-cum-retardation layer 1 is directly formed on a substrate 2′. The alignment film-cum-retardation film shown in FIG. 2 may be provided with a means to exhibit an alignment-regulating force on the alignment layer-cum-retardation layer 1-side surface of the substrate 2′. In an embodiment of the alignment film-cum-retardation film 10 shown in FIG. 3, an alignment film 3 and the alignment layer-cum-retardation layer 1 are stacked in this order on the substrate 2.

The photo-alignment thermosetting liquid crystal composition containing the side-chain liquid crystal polymer (A) can show homeotropic alignment property without the use of the alignment film 3 because, as described above, the side-chain liquid crystal polymer is homeotropically aligned with ease and, consequently, the optionally contained polymerizable liquid crystal compound is homeotropically aligned with ease, too.

### 1. Alignment Layer-Cum-Retardation Layer

The alignment layer-cum-retardation layer 1 of the present disclosure is the cured film of the photo-alignment thermosetting liquid crystal composition of the present disclosure, and it is formed from the photo-alignment thermosetting liquid crystal composition of the present disclosure. The alignment layer-cum-retardation layer of the present disclosure is a cured film in which the liquid crystal moiety of the side-chain liquid crystal polymer (A) is homeotropically aligned and the photo-alignment group present on the surface of the alignment layer-cum-retardation layer has a photodimerization structure or photoisomerization structure.

The alignment layer-cum-retardation layer of the present disclosure is a single layer containing the homeotropically aligned side-chain liquid crystal polymer and the copolymer which has the photodimerization or photoisomerization structure of the photo-alignment group of the photo-alignment constitutional unit and which has the crosslinked structure formed by binding of the thermal crosslinking agent to the thermally crosslinkable group of the thermally crosslinkable constitutional unit. When the side-chain liquid crystal polymer contains the a thermally crosslinkable constitutional unit containing a thermally crosslinkable group in a side chain, the alignment layer-cum-retardation layer may further have the crosslinked structure formed by binding of the thermally crosslinkable group of the thermally crosslinkable constitutional unit in the side-chain liquid crystal polymer to the thermal crosslinking agent.

The crosslinked structure is a three-dimensional network structure. It encompasses the crosslinked structure formed by binding of the thermally crosslinkable group of the thermally crosslinkable constitutional unit in the copolymer to the thermal crosslinking agent, and the crosslinked structure formed by binding of the thermally crosslinkable group of another component which is added as needed to the thermal crosslinking agent. It does not encompass the structure in which the photo-alignment groups are crosslinked by a photodimerization reaction and the structure in which the ethylenically unsaturated double bond groups are polymerized. However, the alignment layer-cum-retardation layer of the present disclosure may further have a structure in which the ethylenically unsaturated double bond groups are polymerized.

In the alignment layer-cum-retardation layer of the alignment film-cum-retardation film of the present disclosure, the side-chain liquid crystal polymer which has the specific structure and which is homeotropically aligned to exhibit retardation and the copolymer which has the photodimerization structure or photoisomerization structure of the photo-alignment group of the photo-alignment constitutional unit having the specific structure and the crosslinked structure formed by binding of the thermally crosslinkable group of the thermally crosslinkable constitutional unit to the thermal crosslinking agent, are less likely to inhibit the performance of one another. Accordingly, it is estimated that the alignment layer-cum-retardation layer exhibits both the excellent homeotropic alignment property and the excellent liquid crystal aligning ability (the ability of aligning the directly stacked liquid crystal material) solely.

Since the alignment layer-cum-retardation layer in the alignment film-cum-retardation film of the present disclosure is the cured film of the photo-alignment thermosetting liquid crystal composition of the present disclosure, due to its crosslinked structure, the heat resistance and solvent resistance of the film are improved, thereby obtaining high durability.

The side-chain liquid crystal polymer which is homeotropically aligned to exhibit retardation, will not be described here since it may be the same as the side-chain liquid crystal polymer described above under “A. Photo-alignment thermosetting liquid crystal composition”.

The alignment layer-cum-retardation layer of the present disclosure contains the copolymer which has the photodimerization structure or photoisomerization structure of the photo-alignment group of the photo-alignment constitutional unit and the crosslinked structure formed by binding of the thermally crosslinkable group of the thermally crosslinkable constitutional unit to the thermal crosslinking agent.

The copolymer contained in the alignment layer-cum-retardation layer of the present disclosure can be formed by thermally curing and photo-aligning the copolymer having the photo-alignment constitutional unit and the thermally crosslinkable constitutional unit, which is described under “A. Photo-alignment thermosetting liquid crystal composition”. In the present disclosure, the thermal crosslinking agent is used, and the thermally crosslinkable group of the thermally crosslinkable constitutional unit is bound to the thermal crosslinking agent. Accordingly, the crosslinked structure becomes the structure in which the thermally crosslinkable group and the thermal crosslinking agent are bound by heating. When the non-liquid crystal, thermally crosslinkable constitutional unit of the side-chain liquid crystal polymer contains a thermally crosslinkable group, as the crosslinked structure, the crosslinked structure formed by binding of the thermally crosslinkable group of the side-chain liquid crystal polymer to the thermal crosslinking agent, may be contained.

As the thermal crosslinking agent, the thermal crosslinking agent described under “A. Photo-alignment thermosetting liquid crystal composition” may be used. The crosslinked structure contains a residue of the thermal crosslinking agent left after the reaction of the thermal crosslinking agent.

For example, when the thermal crosslinking agent is hexamethoxymethylmelamine, the crosslinked structure becomes a structure as shown below. Reference characters shown in the following formula are the same as those shown in the formula (1). The following copolymer is an example, and the monomer units, the residue of the thermally crosslinkable group and so on are not limited to the following.

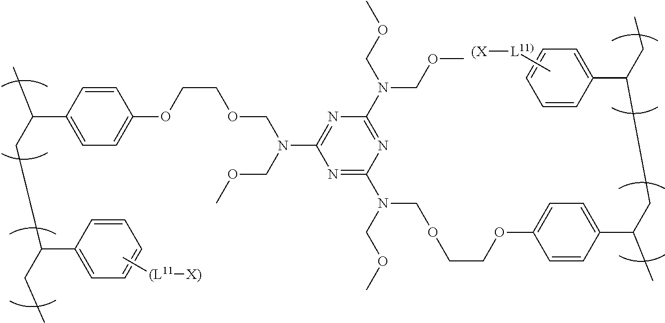

The constitutional units of the copolymer will not be described here, since they are described in detail under “A. Photo-alignment thermosetting liquid crystal composition”.

By collecting a material from the alignment layer and analyzing the material, it can be verified that the alignment layer contains the copolymer. A method for the analysis can make use of NMR, IR, GC-MS, XPS, TOF-SIMS and any combination thereof.

The photodimerization structure of the copolymer is the structure in which the photo-alignment groups of the photo-alignment constitutional unit represented by the formula (1) are crosslinked by a photodimerization reaction, and it is a structure containing a cyclobutane skeleton.

The photodimerization reaction is a reaction as shown below, and it is a reaction in which the olefin structure contained in the photo-alignment group forms a cyclobutane skeleton by a photoreaction. Depending on the type of the photo-alignment group, Xa to Xd and Xa′ to Xd′ vary.

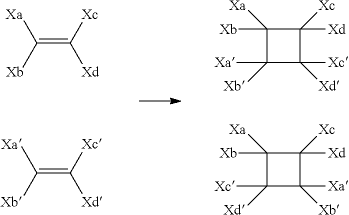

The photodimerization structure is preferably the photodimerization structure of the cinnamoyl group. More specifically, the structure in which the cinnamoyl groups described under “A. Photo-alignment thermosetting liquid crystal composition” are crosslinked by a photodimerization reaction, is preferred. The alignment layer preferably has photodimerization structure as represented by the following formula (x-4) or (x-5). Reference characters shown in the following formulae are the same as those of the formulae (x-1), (x-2) and (x-3).

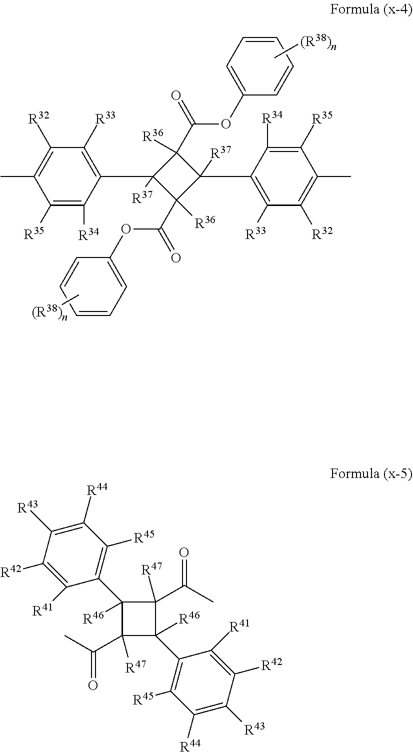

When the alignment layer has the photodimerization structure as represented by the formula (x-4) or (x-5), many aromatic rings are arranged, and many n electrons are contained. Accordingly, it is thought that affinity for the liquid crystal layer formed on the alignment layer increases; the liquid crystal aligning ability improves; and the adhesion to the liquid crystal layer further increases.

The photoisomerization structure of the copolymer is a structure in which the photo-alignment group of the photo-alignment constitutional unit is isomerized by a photoisomerization reaction. For example, in the case of a cis-trans isomerization reaction, the photoisomerization structure may be any of the structure of a cis isomer changed into a trans isomer or the structure of a trans isomer changed into a cis isomer.

For example, when the photo-alignment group is a cinnamoyl group, the photoisomerization reaction is a reaction shown below, and it is a reaction in which the olefin structure contained in the photo-alignment group forms a cis or trans isomer by a photoreaction. Depending on the type of the photo-alignment group, Xa to Xd vary.

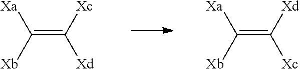

The photoisomerization structure is preferably the photoisomerization structure of the cinnamoyl group. More specifically, the structure in which the cinnamoyl group described under “A. Photo-alignment thermosetting liquid crystal composition” is isomerized by a photoisomerization reaction, is preferred. In this case, the photoisomerization structure may be any of the structure of a cis isomer changed into a trans isomer or the structure of a trans isomer changed into a cis isomer. The alignment layer preferably has photoisomerization structures of the cinnamoyl group represented by the formulae (x-1) and (x-2), which are photoisomerization structures as represented by the following formulae (x-6) and (x-7).

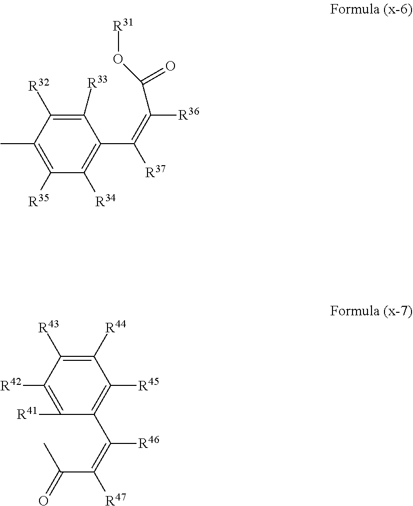

By NMR or IR, it can be analyzed whether the alignment layer has the photodimerization structure or the photoisomerization structure.

The alignment layer-cum-retardation layer may further contain other components that may be further contained in the photo-alignment thermosetting liquid crystal composition.

For example, the alignment layer-cum-retardation layer may contain a structure in which the ethylenically unsaturated double bond groups of at least one kind selected from the group consisting of the polymerizable liquid crystal compound different from the side-chain liquid crystal polymer (A), the polymerizable compound containing two or more polymerizable groups per molecule, and the compound containing a polymerizable group and a thermally crosslinkable group, are polymerized.

For example, the alignment layer-cum-retardation layer may contain the crosslinked structure formed by binding of at least one of the compound containing a polymerizable group and a thermally crosslinkable group and the compound containing the photo-alignment group and thermally crosslinkable group, which is different from the copolymer (B), to the thermal crosslinking agent. The alignment layer-cum-retardation layer may further contain the photodimerization or photoisomerization structure of the photo-alignment group of the compound containing the photo-alignment group and thermally crosslinkable group, which is different from the copolymer (B).

The alignment layer-cum-retardation layer may further contain an acid or acid generator, a photopolymerization initiator, a sensitizer, other additives, and decomposition products thereof. These additives are the same as those described above under “A. Photo-alignment thermosetting liquid crystal composition”.

By collecting a material from the alignment layer-cum-retardation layer and analyzing the material, it can be verified that the alignment layer-cum-retardation layer is formed from the photo-alignment thermosetting liquid crystal composition. A method for the analysis can make use of NMR, IR, GC-MS, XPS, TOF-SIMS, and any combination thereof.

By measuring the retardation using an automatically birefringence measuring instrument (for example, trade name: KOBRA-WR, manufactured by Oji Scientific Instruments Co., Ltd.), it can be verified that the liquid crystal component contained in the alignment layer-cum-retardation layer, such as the liquid crystal moiety of the side-chain liquid crystal polymer, is homeotropically aligned.

The retardation can be measured by use of an automatically birefringence measuring instrument (for example, trade name: KOBRA-WR, manufactured by Oji Scientific Instruments Co., Ltd.) Measuring-light is radiated into the retardation layer perpendicularly or obliquely to a surface of this layer. From a chart of the optical retardation of the retardation layer and the incident angle of the measuring-light, verification can be attained about the anisotropy of increasing the retardation of the retardation layer.

The thickness of the alignment layer-cum-retardation layer may be appropriately set in accordance with the intended application thereof. In particular, the thickness is preferably from 0.1 μm to 5 μm, and more preferably from 0.5 μm to 3 μm.

### 2. Substrate

In the alignment film-cum-retardation film of the present disclosure, as the substrate, examples include, but are not limited to, a glass substrate, a metal foil and a resin substrate. In particular, the substrate preferably has transparency, and it is appropriately selectable from transparent substrates known in the prior art. The transparent substrate may be, besides a glass substrate, a transparent resin substrate formed by use of an acetylcellulose resin such as triacetylcellulose, a polyester resin such as polyethylene terephthalate, polyethylene naphthalate, polybutylene terephthalate and polylactic acid, an olefin-based resin such as polypropylene, polyethylene and polymethylpentene, an acrylic resin, a polyurethane resin, or a resin such as polyethersulfone, polycarbonate, polysulfone, polyether, polyetherketone, acrylonitrile, methacrylonitrile, a cycloolefin polymer and a cycloolefin copolymer.

The transmittance of the transparent substrate in the visible light region is preferably 80% or more, and more preferably 90% or more. The transmittance of the transparent substrate is measurable in accordance with JIS K7361-1 (Test Method for Total Light Transmittance of Plastic-Transparent Material).

When the retardation layer is formed in a roll-to-roll manner, the transparent substrate is preferably made of a flexible material having a flexibility permitting the substrate to be wound into a roll form.

As the flexible material, examples include, but are not limited to, a cellulose derivative, a norbornene-based polymer, a cycloolefin polymer, a polymethyl methacrylate, a polyvinyl alcohol, a polyimide, a polyarylate, a polyethylene terephthalate, a polysulfone, a polyethersulfone, an amorphous polyolefin, a modified acrylic polymer, a polystyrene, an epoxy resin, a polycarbonate and a polyester. It is particularly preferred in the present embodiment to use a cellulose derivative or polyethylene terephthalate. This is because cellulose derivatives are especially excellent in optical isotropy, so that the substrate can be made excellent in optical properties. Moreover, this is because polyethylene terephthalate is high in transparency and excellent in mechanical properties.

The thickness of the substrate used in the present embodiment is not particularly limited, as far as the thickness is in a range making it possible to give a required self-supporting performance to the substrate in accordance with the intended application of the alignment film-cum-retardation film, etc. The thickness is usually in a range of from about 10 μm to 200 μm.

The thickness of the substrate is preferably in a range of from 25 μm to 125 μm, and particularly preferably in a range of from 30 μm to 100 μm. If the thickness is larger than in the former range, the following may be caused, for example, at the time of forming a long retardation film and subsequently cutting the film to be made into alignment film-cum-retardation film pieces: processing wastes are increased or the cutting edge is worn away earlier than usual.

The structure of the substrate used in the present embodiment is not limited to a structure made of a single layer. Thus, the structure may be a structure composed of a stack of layers. When the substrate has the structure composed of a stack of layers, layers having the same composition may be stacked, or layers having different compositions may be stacked.

When the below-described alignment film used in the present embodiment contains an ultraviolet curable resin, a primer layer may be formed on the substrate to improve adhesion between the transparent substrate and the ultraviolet curable resin. This primer layer is not particularly limited, as long as it is a primer layer which has adhesion to both the substrate and the ultraviolet curable resin and is visible-ray-optically transparent to transmit ultraviolet light. This layer can make use of, for example, a material selected appropriately from vinyl-chloride/vinyl-acetate copolymer-based materials, urethane-based materials, and the like.

When a homeotropic alignment film described below is not disposed on the substrate, an anchor coat layer may be stacked onto the substrate. The anchor coat layer can improve the substrate in strength and cause the retardation layer to keep a good homeotropic alignment. The material of the anchor coat layer may be a metal alkoxide, in particular, a metal silicon alkoxide sol. The metal alkoxide is usually used in the form of a solution in an alcohol. The anchor coat layer needs to be an even and flexible film. Thus, the thickness of the anchor coat layer is preferably from about 0.04 μm to 2 μm, and more preferably from about 0.05 μm to 0.2 μm.

When the substrate contains the anchor coat layer, the substrate and the anchor coat layer may be improved in close adhesion between the two by disposing a binder layer between the substrate and the anchor coat layer, or by incorporating, into the anchor coat layer, a material for enhancement of close adhesion to the substrate. A binder material used to form the binder layer is usable without any especial restriction, as far as the material is a material that can improve the close adhesion between the substrate and the anchor coat layer. As the binder material, examples include, but are not limited to, a silane coupling agent, a titanium coupling agent and a zirconium coupling agent.

### 3. Alignment Film

As the alignment film 3 used in the embodiment of the alignment film-cum-retardation film of the present disclosure, a homeotropic alignment film may be used since the liquid crystal composition of the alignment layer-cum-retardation layer 1 in the present disclosure is homeotropically aligned with ease.

The homeotropic alignment film is an alignment film having a function of homeotropically aligning the long axis of the mesogen of the liquid crystal component contained in the alignment layer-cum-retardation layer 1, such as the liquid crystal moiety of the side-chain liquid crystal polymer, by disposing this film as a coating film.

The homeotropic alignment film is an alignment film having an alignment-regulating force in the perpendicular direction to the film, and it may be any one of various homeotropic alignment films supplied to produce a C plate and various homeotropic alignment films applied to a VA liquid crystal display device and the like. The homeotropic alignment film may be, for example, a polyimide alignment film, or an alignment film based on an LB film. As the materials for forming the alignment film, examples include, but are not limited to, lectin; a silane surfactant; a titanate surfactant; a pyridinium salt polymeric surfactant; a silane coupling type composition for homeotropic alignment films, which contains, for example, n-octadecyltriethoxysilane; and a polyimide type composition for homeotropic alignment films, which contains, for example, a soluble polyimide containing, in its side chains, a long-chain alkyl group or an alicyclic structure, or a polyamic acid containing, in its side chains, a long-chain alkyl group or an alicyclic structure.

As the composition for homeotropic alignment films, examples include, but are not limited to, commercially available products such as “JALS-2021” and “JALS-204” (product names, polyimide type compositions for homeotropic alignment films, manufactured by JSR Corp.) and “RN-1517”, “SE-1211” and “EXPOA-018” (product names, manufactured by Nissan Chemical Corp.) The homeotropic alignment film may also be a homeotropic alignment film described in JP 2015-191143 A.

The method for forming the alignment film 3 is not particularly limited. The alignment film can be formed, for example, by applying the composition for alignment films onto the substrate 2 and providing an alignment-regulating force thereto. The means for providing an alignment-regulating force to the alignment film may be any means known in the prior art.

The thickness of the alignment film 3 is not particularly limited, as long as the liquid crystal component in the alignment layer-cum-retardation layer 1 can be arranged in a predetermined direction, and the thickness may be appropriately set. The thickness of the alignment film 3 is usually in a range of from 1 nm to 10 μm, and preferably in a range of from 60 nm to 5 μm.

### 4. Applications

The alignment film-cum-retardation film of the present disclosure is favorably used as a retardation film including a positive C type retardation layer which also functions as an alignment film for aligning the directly stacked liquid crystal material.

The positive C property is characterized by Nz>Nx≈Ny where Nx is the refractive index in the x axis direction along the layer surface; Ny is the refractive index in the Y axis direction perpendicular to the x axis in the direction along the layer surface; Nz is the refractive index in the layer thickness direction; and the optical axis is in the Nz direction.

The alignment film-cum-retardation film of the present disclosure is favorably used as, for example, a part of an external light antireflection film or as a part of a polarizing plate compensation film. Also, it is favorably used for a retardation plate for various display devices or an optical member.

### C. Method for Producing an Alignment Film-Cum-Retardation Film

The method for producing the alignment film-cum-retardation film of the present disclosure comprises:
forming the photo-alignment thermosetting liquid crystal composition of the present disclosure into a film,
forming a cured film having retardation by heating the thermosetting liquid crystal composition formed into the film, and
providing a liquid crystal aligning ability to the cured film having retardation by irradiating the cured film with polarized ultraviolet light.
   (1) Forming the Photo-Alignment Thermosetting Liquid Crystal Composition into a Film

The photo-alignment thermosetting liquid crystal composition of the present disclosure is formed into a film by uniformly applying the liquid crystal composition onto a support.

As the support, examples include, but are not limited to, the above-defined substrate and the alignment film on the substrate.

The method for applying the liquid crystal composition is not particularly limited, as long as it is a method capable of forming a film having a desired thickness with a good precision, and the method may be appropriately selected. As the method, examples include, but are not limited to, gravure coating, reverse coating, knife coating, dip coating, spray coating, air knife coating, spin coating, roll coating, printing, dip pulling-up, curtain coating, die coating, casting, bar coating, extrusion coating, and E type coating methods.

### (2) Forming a Cured Film Having Retardation

Next, a cured film having retardation is formed by heating the thermosetting liquid crystal composition formed into the film. The cured film has the function of the retardation layer.

This step includes aligning at least the liquid crystal moiety of the side-chain liquid crystal polymer (A) in the thermosetting liquid crystal composition formed into the film, by heating the thermosetting liquid crystal composition formed into the film.

More specifically, the heating temperature is adjusted to a temperature at which the liquid crystal moiety of the liquid crystal constitutional unit of the side-chain liquid crystal polymer in the liquid crystal composition film, is homeotropically alignable, and heating is conducted. When the polymerizable liquid crystal compound is optionally further contained, the heating temperature is adjusted to a temperature at which the polymerizable liquid crystal compound is also homeotropically alignable. This heating treatment at least makes it possible that the liquid crystal moiety of the liquid crystal constitutional unit of the side-chain liquid crystal polymer is homeotropically aligned, and the film is dried and fixed while keeping the alignment state.

The homeotropically alignable temperature is varied in accordance with the substances in the liquid crystal composition. Thus, the temperature needs to be appropriately adjusted. The heating treatment is conducted, for example, preferably in a range of from 40° C. to 200° C., and more preferably in a range of from 40° C. to 150° C. Since the photo-alignment thermosetting liquid crystal composition of the present disclosure contains the side-chain liquid crystal polymer, the homeotropically alignable temperature range is wide, and it is easy to control the temperature.

The heating means is appropriately selectable from known heating and drying means to be usable, such as a hot plate and an oven.

The heating time may be appropriately selected. For example, it is selected in a range of from 10 seconds or more and 2 hours or less, and preferably in a range of from 20 seconds or more and 30 minutes or less.

This step includes a step of curing, by heating the thermosetting liquid crystal composition formed into the film, the thermosetting liquid crystal composition formed into the film while the liquid crystal moiety is in the aligned state, by reacting the thermally crosslinkable group of the copolymer (B) in the thermosetting liquid crystal composition formed into the film with the thermal crosslinking agent (C) therein.

When, by the heating for at least aligning the liquid crystal moiety of the side-chain liquid crystal polymer (A) in the thermosetting liquid crystal composition formed into the film, the thermally crosslinkable group of the copolymer (B) in the thermosetting liquid crystal composition formed into the film is reacted with the thermal crosslinking agent (C) therein to cure the thermosetting liquid crystal composition formed into the film, the heating may be one-step heating.

Also, after the heating for at least aligning the liquid crystal moiety of the side-chain liquid crystal polymer (A) in the thermosetting liquid crystal composition formed into the film, and changing the heating temperature, the thermosetting liquid crystal composition formed into the film may be further heated at the changed heating temperature. In this case, while the liquid crystal moiety is in the aligned state, the thermally crosslinkable group of the copolymer (B) in the thermosetting liquid crystal composition formed into the film may be reacted with the thermal crosslinking agent (C) therein to cure the thermosetting liquid crystal composition formed into the film.

The heating temperature for thermally curing the thermosetting liquid crystal composition formed into the film may be set to about 40° C. to 250° C., for example. The heating time may be set to about 20 seconds or more and 60 minutes or less, for example.

The thickness of the cured film obtained by thermally curing the photo-alignment thermosetting liquid crystal composition is appropriately selected depending on the intended application, and it can be set to about 0.1 μm to 5 μm, and preferably about 0.5 μm to 3 μm, for example. When the thickness of the cured film is too thin, there is a possibility that the obtained retardation function and liquid crystal aligning ability are poor.

### (3) Providing a Liquid Crystal Aligning Ability to the Cured Film

Next, a liquid crystal aligning ability is provided to the cured film having retardation by irradiating the cured film with polarized ultraviolet light. More specifically, in this step, by irradiating the cured film with polarized ultraviolet light, the cured film further having the function of the alignment layer, is formed.

By irradiating the thus-obtained cured film with polarized ultraviolet light, the photo-alignment group of the copolymer (B) causes a photoreaction and can exhibit anisotropy. The wavelength of the polarized ultraviolet light is generally in a range of from 150 nm to 450 nm. The direction of the polarized ultraviolet light irradiation may be a direction perpendicular or oblique to the substrate surface.

In this manner, the cured film provided with the liquid crystal aligning ability can be formed.

As described above, the cured film obtains the function of the retardation layer and the function of the alignment layer. Accordingly, the cured film that functions as the alignment layer-cum-retardation layer, is obtained.

### (4) Other Steps

The alignment film-cum-retardation film production method of the present disclosure may further include other steps. For example, when the photo-alignment thermosetting liquid crystal composition of the present disclosure contains the compound containing a polymerizable group (e.g., the polymerizable liquid crystal compound), the compound having a polymerizable group may be polymerized by, for example, light irradiation to the coating film fixed in the state that the alignment state of the liquid crystal component is maintained.

The light irradiation is preferably ultraviolet irradiation. For the ultraviolet irradiation, ultraviolet light which is emitted from light rays of, for example, an ultra-high-pressure mercury lamp, a high-pressure mercury lamp, a low-pressure mercury lamp, a carbon arc, a xenon arc, or a metal halide lamp, may be used. The irradiance level of the energy beam source may be appropriately selected. Preferably, the accumulated irradiation dose thereof at an ultraviolet wavelength of 365 nm is, for example, in a range of from 10 mJ/cm² to 10000 mJ/cm².

Also, the alignment film-cum-retardation film made of only the alignment layer-cum-retardation layer 1 can be obtained by peeling off the support after the cured film that functions as the alignment layer-cum-retardation layer is obtained.

### D. Retardation Plate

The retardation plate of the present disclosure is a retardation plate comprising a first retardation layer and a second retardation layer,
wherein the first retardation layer is a cured film of the photo-alignment thermosetting liquid crystal composition of the present disclosure, and
wherein the second retardation layer is located directly adjacent to the first retardation layer and contains a cured product of a polymerizable liquid crystal composition.

FIG. 4 is a schematic sectional view of an example of the retardation plate of the present disclosure. In a retardation plate 20 shown in FIG. 4, a first retardation layer 11, which is the alignment layer-cum-retardation layer, is formed on a substrate 13, and a second retardation layer 12 is formed on the first retardation layer 11.

The retardation plate of the present disclosure has the excellent homeotropic alignment property and the excellent ability of aligning the directly stacked liquid crystal material, since the first retardation layer is a cured film of the photo-alignment thermosetting liquid crystal composition of the present disclosure. Accordingly, the retardation plate 20 of the present disclosure is such that the second retardation layer is formed by directly stacking the liquid crystal material on the first retardation layer 11, without providing another alignment film, and the retardation plate 20 of the present disclosure includes the second retardation layer 12 which is located directly adjacent to the first retardation layer 11.

As described above, the retardation plate of the present disclosure is excellent in solvent resistance, since the first retardation layer is a cured film of the photo-alignment thermosetting liquid crystal composition of the present disclosure. Accordingly, even when stacking the second retardation layer, a deterioration in the retardation of the first retardation layer is suppressed, and the retardation plate having good optical properties is obtained.

Also, since the first retardation layer is a cured film of the photo-alignment thermosetting liquid crystal composition of the present disclosure, as described above, the retardation plate of the present disclosure is less likely to be hard, has flexibility, and shows good adhesion to the directly stacked liquid crystal material, compared to the case where the retardation plate of the present disclosure is a cured product of a photocurable resin composition containing a polymerizable liquid crystal compound. Accordingly, as with the retardation plate of the third embodiment of the present disclosure described below, the retardation plate of the present disclosure is such that the first and second retardation layers are directly stacked in good adhesion, and the retardation plate of the present disclosure can be a thin retardation plate which has good flex resistance.

The retardation plate production method of the present disclosure may be a method for producing a retardation plate, the method comprising:
forming the photo-alignment thermosetting liquid crystal composition of the present disclosure into a film,
forming a cured film having retardation by heating the thermosetting liquid crystal composition formed into the film,
forming an alignment film-cum-first retardation layer by providing a liquid crystal aligning ability to the cured film having retardation by irradiating the cured film with polarized ultraviolet light,
aligning liquid crystal molecules by the alignment film-cum-retardation layer, by forming a coating film of a polymerizable liquid crystal composition by applying the polymerizable liquid crystal composition onto the alignment film-cum-first retardation layer and heating the coating film to a phase transition temperature of the polymerizable liquid crystal composition, and
forming a second retardation layer by curing the coating film of the polymerizable liquid crystal composition, in which the liquid crystal molecules are aligned, by light irradiation.

The substrate will not be described here, since it may be the same as the substrate described above under “B. Alignment film-cum-retardation film”.

### 1. First Retardation Layer

As described above, the first retardation layer functions as the alignment layer-cum-retardation layer, since the first retardation layer is a cured film of the photo-alignment thermosetting liquid crystal composition of the present disclosure.

The first retardation layer will not be described here, since it may be the same as the alignment layer-cum-retardation layer described above under “B. Alignment film-cum-retardation film”.

When the first retardation layer contains a compound which is reactive with the compound containing a polymerizable group or a thermally crosslinkable group contained in the second retardation layer, a reaction product of the compounds contained in the layers may be present at the interface between the first and second retardation layers. For example, a structure in which the polymerizable group of the compound contained in the first retardation layer and the polymerizable group of the polymerizable liquid crystal compound contained in the second retardation layer are polymerized, may be present at the interface between the first and second retardation layers. It is preferable that such a reaction compound is present at the interface between the first and second retardation layers, because the adhesion between the first and the second retardation layers improves.

In the case of the first retardation layer of the thermosetting resin composition of the present disclosure containing the thermal crosslinking agent, compared to the case where the first retardation layer is a cured product of a photocurable resin composition containing a polymerizable liquid crystal compound, a permeation region which is appropriate to the extent that does not inhibit the homeotropic alignment property of the first retardation layer, is likely to be formed at the interface with the directly stacked second retardation layer. Accordingly, the adhesion of the first retardation layer of the thermosetting resin composition of the present disclosure containing the thermal crosslinking agent, improves with ease. Since the first retardation layer of the thermosetting resin composition of the present disclosure containing the thermal crosslinking agent is crosslinked by the thermal crosslinking agent, it is estimated that at the time of directly stacking the second retardation layer, solvent permeation that leads to a decrease in the homeotropic alignment property is less likely to occur, while slight solvent permeation is likely to occur only on the surface.

The first retardation layer is a cured film of the photo-alignment thermosetting liquid crystal composition of the present disclosure. From the point of view that the contained side-chain liquid crystal polymer is homeotropically aligned with ease, the first retardation layer is preferably used as a positive C type retardation layer.

### 2. Second Retardation Layer

The second retardation layer of the retardation plate of the present disclosure is located directly adjacent to the first retardation layer and contains a cured product of a polymerizable liquid crystal composition.

As the polymerizable liquid crystal composition, a polymerizable liquid crystal composition containing a polymerizable liquid crystal compound which contains a polymerizable group may be used. As the polymerizable liquid crystal composition, a polymerizable liquid crystal composition generally used in retardation layers may be used.

As the polymerizable group contained in the polymerizable liquid crystal compound, examples include, but are not limited to, an acryloyl group and a methacryloyl group.

As the polymerizable liquid crystal composition, examples include, but are not limited to, a polymerizable liquid crystal composition having an alignment property such as horizontal alignment, cholesteric alignment, homeotropic alignment and hybrid alignment. The polymerizable liquid crystal composition is appropriately selected depending on the desired retardation and so on.

From the viewpoint of the liquid crystal aligning ability of the first retardation layer, the polymerizable liquid crystal composition of the second retardation layer is preferably a polymerizable liquid crystal composition having a horizontal alignment property.

It is preferable that the polymerizable liquid crystal composition of the second retardation layer shows a liquid crystal property and contains a polymerizable liquid crystal compound containing a polymerizable group (a rod-shaped compound) in the molecules. The polymerizable liquid crystal compound may be appropriately selected from conventionally-known polymerizable liquid crystal compounds having a horizontal alignment property for use.

The polymerizable liquid crystal composition may be composed of one kind of liquid crystal compound, or it may be a mixture of two or more kinds of liquid crystal compounds.

The polymerizable liquid crystal composition of the second retardation layer preferably uses the same polymerizable liquid crystal compound described above as the “polymerizable liquid crystal compound different from the side-chain liquid crystal polymer (A)” under “A. Photo-alignment thermosetting liquid crystal composition”.

In the polymerizable liquid crystal composition of the second retardation layer, the polymerizable liquid crystal compound is preferably one or more kinds of compounds selected from the compounds represented by the general formulae (IV) and (V), from the viewpoint of exhibiting a liquid crystal aligning property and excellent heat resistance. More specifically, as the compounds represented by the general formulae (IV) and (V), polymerizable liquid crystal compounds described in Paragraphs 0057 to 0064 in International Publication No. WO2018/003498, may be used, for example.

As the polymerizable liquid crystal compound in the polymerizable liquid crystal composition of the second retardation layer, polymerizable liquid crystal compounds described in Japanese Patent Nos. 6473537, 5463666, 4186981, 5962760, 5826759, 6568103 and 6427340, Japanese Patent Application Laid-Open (JP-A) No. 2016-166344, and Recueil des Travaux Chimiques des Pays-Bas (1996), 115 (6), 321-328, may be used.

As the polymerizable liquid crystal composition of the second retardation layer, examples include, but are not limited to, compositions described in Paragraphs 0133 to 0143 in JP-A No. 2014-174468 and compositions described in Paragraphs 0083 to 0092 in Japanese Patent No. 6739621.

In addition to the liquid crystal compound, the polymerizable liquid crystal composition of the second retardation layer may further contain a photopolymerization initiator and a solvent. It may further contain other components as described above under “A. Photo-alignment thermosetting liquid crystal composition”.

The second retardation layer can be formed by the following steps:
aligning the liquid crystal component by the liquid crystal aligning ability of the first retardation layer, by forming a coating film of a polymerizable liquid crystal composition by applying the polymerizable liquid crystal composition onto the first retardation layer that also functions as the alignment layer and heating the coating film to a phase transition temperature of the polymerizable liquid crystal composition, and
forming a retardation layer by light irradiation of the coating film of the polymerizable liquid crystal composition, in which the liquid crystal component is aligned.

In the step of aligning the liquid crystal component, the method for forming the coating film of the polymerizable liquid crystal composition and the method for heating the coating film to the phase transition temperature are not particularly limited, and conventionally known methods may be employed. As the application method and the heating method, the same methods as the application and heating methods described above in the method for producing the alignment layer-cum-retardation layer, may be used.

By light irradiation of the coating film of the polymerizable liquid crystal composition, in which the liquid crystal component is aligned, a polymerization reaction is initiated to polymerize the polymerizable groups of the polymerizable liquid crystal compound contained in the second retardation layer. When the first retardation layer contains a compound containing a polymerizable group, by light irradiation of the coating film of the polymerizable liquid crystal composition, in which the liquid crystal component is aligned, the polymerizable group of the polymerizable group-containing compound contained in the first retardation layer and the polymerizable group of the polymerizable liquid crystal compound contained in the second retardation layer are polymerized. The light irradiation method may be selected from conventionally known methods, and it may be the same method as the method described above under “C. Alignment film-cum-retardation film”.

Since the first retardation layer of the retardation plate of the present disclosure functions as the alignment layer-sum-retardation film, the second retardation layer is directly stacked on the first retardation layer, and a substrate, alignment film, adhesive layer and the like for the second retardation layer are not contained in the retardation plate of the present disclosure. Accordingly, the thickness of the retardation plate of the present disclosure can be reduced. For the retardation plate of the present disclosure, the total thickness of the stack of the first and second retardation layers excluding the substrate may be from 0.2 μm to 6 μm, and it is preferably from 1 μm to 4 μm.

In the retardation plate of the present disclosure, it is preferable that the first retardation layer is the positive C type retardation layer and the second retardation layer is the positive A type retardation layer. The positive A property is characterized by Nx>Ny≈Nz where Nx is the refractive index in the x axis direction along the layer surface; Ny is the refractive index in the Y axis direction perpendicular to the x axis in the direction along the layer surface; Nz is the refractive index in the layer thickness direction; and the optical axis is in the Nx direction.

The retardation plate made of a stack of the positive C type retardation layer and the positive A type retardation layer is preferred for the following reason: for example, in organic electroluminescent display devices, it is used as a circularly polarizing plate in the form of a combination of a quarter wavelength retardation plate and a linear polarizing plate, and it functions as an external light antireflection film. Also, the retardation plate made of a stack of the positive C type retardation layer and the positive A type retardation layer is preferred since it is used as a part of a polarizing plate compensation film in liquid crystal display devices.

For the retardation plate of the present disclosure, the thickness direction retardation Rth at a wavelength of 550 nm may be from −35 nm to 35 nm, or it may be from −30 nm to 30 nm.

The in-plane retardation Re at a wavelength of 550 nm may be 120 nm or more, or it may be 135 nm or more.

The retardation plate of the present disclosure may further include another retardation layer.

The retardation plate of the present disclosure may be the retardation plate further comprising a third retardation layer different from the first retardation layer,
wherein the third retardation layer, the first retardation layer and the second retardation layer are located in this order directly adjacent to each other, and
wherein the third retardation layer, the first retardation layer and the second retardation layer are a positive C type retardation layer, a positive C type retardation layer, and a positive A type retardation layer, respectively.

When the third retardation layer is a positive C type retardation layer, as with the first retardation layer, the third retardation layer is preferably formed by use of the side-chain liquid crystal polymer. For example, it can be formed by use of a thermosetting resin composition obtained by excluding the copolymer (B) from the photo-alignment thermosetting resin composition used to form the first retardation layer.

### 4. Applications

The thickness of the retardation plate of the present disclosure can be reduced, since the second retardation layer can be directly stacked on the first retardation layer, and a substrate, alignment film, adhesive layer and the like for the second retardation layer are not contained in the retardation plate of the present disclosure.

The retardation plate of the present disclosure is suitably used as an optical member in various kinds of image display devices aimed at achieving thickness reduction.

### II. The Second Embodiment

### A. Photo-Alignment Thermosetting Liquid Crystal Composition

The photo-alignment thermosetting liquid crystal composition of the present disclosure is a photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a photo-alignment group in a side chain and a thermally crosslinkable constitutional unit containing a constitutional unit represented by the following formula (2), and
a thermal crosslinking agent (C) for bonding to a thermally crosslinkable group of the thermally crosslinkable constitutional unit,
wherein the side-chain liquid crystal polymer (A) satisfies any of the following (i) to (vi):
   (i) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a primary carbon of the alkylene group which optionally contains —O— in its carbon chain and in which a total of a carbon atom number and an oxygen atom number is smaller than a linear alkylene group which contains 4 to 11 carbon atoms and which optionally contains —O— in its carbon chain in the thermally crosslinkable constitutional unit of the copolymer (B);
   (ii) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a secondary or tertiary carbon of the alkylene group;
   (iii) the side-chain liquid crystal polymer (A) contains a non-liquid crystal, thermally crosslinkable constitutional unit containing, in a side chain, an arylene group, an alkylene group and at least one kind of thermally crosslinkable group selected from the group consisting of a hydroxy group, a mercapto group and an amino group, and the non-liquid crystal, thermally crosslinkable constitutional unit of the side-chain liquid crystal polymer (A) has a structure such that the thermally crosslinkable group is bound to the arylene group;
   (iv) the side-chain liquid crystal polymer (A) contains a non-liquid crystal, thermally crosslinkable constitutional unit containing an arylene group, an alkylene group and at least one kind of thermally crosslinkable group selected from the group consisting of a carboxy group, a glycidyl group and an amide group; the non-liquid crystal, thermally crosslinkable constitutional unit of the side-chain liquid crystal polymer (A) has a structure such that the thermally crosslinkable group is bound to the arylene group; and the arylene group has a structure such that it is bound to a carbon or oxygen atom of the alkylene group which optionally contains —O— in its carbon chain or at its terminal and in which a total of a carbon atom number and an oxygen atom number is 3 or more smaller than the linear alkylene group which contains 4 to 11 carbon atoms and which optionally contains —O— in the carbon chain in the thermally crosslinkable constitutional unit of the copolymer (B);
   (v) the side-chain liquid crystal polymer (A) contains a thermally crosslinkable constitutional unit containing no alkylene group in a side chain and a thermally crosslinkable group in the side chain; and
   (vi) the side-chain liquid crystal polymer (A) does not contain a non-liquid crystal, thermally crosslinkable constitutional unit containing a thermally crosslinkable group and an alkylene group in a side chain and a thermally crosslinkable constitutional unit containing a thermally crosslinkable group in a side chain:

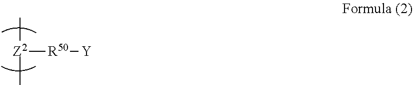

where Z² is at least one kind of monomer unit selected from the group consisting of the following formulae (2-1) to (2-6); R⁵⁰ is a linear alkylene group containing 4 to 11 carbon atoms and optionally containing —O— in its carbon chain; and Y is at least one kind of thermally crosslinkable group selected from the group consisting of a hydroxy group, a carboxy group, a mercapto group, a glycidyl group, an amino group and an amide group:

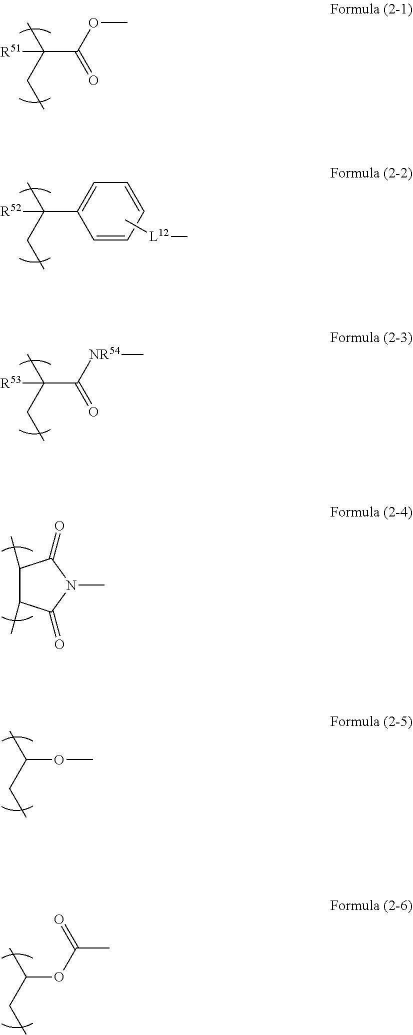

where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L¹² is a single bond, —O—, —S—, —COO—, —COS—, —CO— or —OCO—; and when L¹² is a single bond, R⁵⁴ is directly bound to a styrene skeleton.

In the photo-alignment thermosetting liquid crystal composition of the present disclosure, the side-chain liquid crystal polymer (A) and the copolymer (B) containing the thermally crosslinkable constitutional unit and the photo-alignment constitutional unit which exhibits the ability of aligning the directly stacked liquid crystal material, are combined with each other so as to satisfy the above-specified condition; moreover, the photo-alignment thermosetting liquid crystal composition of the present disclosure contains the thermal crosslinking agent (C) for bonding to the thermally crosslinkable group of the thermally crosslinkable constitutional unit. Accordingly, by forming the cured film of the composition, the alignment layer-cum-retardation layer can be formed, which exhibits the good homeotropic alignment property and the good liquid crystal aligning ability (the ability of aligning the directly stacked liquid crystal material) and which has durability while it functions as both an alignment layer and a retardation layer solely.

The inventors of the present disclosure made diligent research on the formation of an integrated functional layer for the alignment layer-cum-retardation layer having durability from the composition containing the side-chain liquid crystal polymer (A) having the homeotropic alignment property and the photo-alignment material (the copolymer (B) which contains the photo-alignment constitutional unit and the thermally crosslinkable constitutional unit and which exhibits the ability of aligning the directly stacked liquid crystal material). As a result, they found the following fact: in the composition, as the thermal curing of the copolymer (B) (a material for the photo-alignment film) proceeds, the photo-aligning function of the copolymer (B) improves; however, as the thermal curing of the side-chain liquid crystal polymer (A) having the homeotropic alignment property proceeds, the homeotropic alignment property deteriorates. Accordingly, they thought that it is necessary to promote the thermal curing of the copolymer (B) (a material for the photo-alignment film) in the composition and to inhibit the thermal curing of the side-chain liquid crystal polymer (A) having the homeotropic alignment property.

The photo-alignment thermosetting liquid crystal composition of the present disclosure has the structure such that in the thermally crosslinkable constitutional unit of the copolymer (B) (the material for the photo-alignment film), the thermally crosslinkable group is bound to the monomer unit via a linear alkylene group which contains 4 to 11 carbon atoms and which optionally contains —O— in its carbon chain. Accordingly, the thermal crosslinking reaction of the copolymer (B) (the material for the photo-alignment film) easily proceeds, and the copolymer (B) is thermally cured with ease. Meanwhile, since the side-chain liquid crystal polymer (A) having the homeotropic alignment property in the composition satisfies any of the (i) to (vi), compared to the copolymer (B), the thermal crosslinking reaction of the side-chain liquid crystal polymer (A) is relatively less likely to proceed, and the side-chain liquid crystal polymer (A) is less likely to be thermally cured or is not thermally cured.

By facilitating the thermal curing of the copolymer (B), which is the material for the photo-alignment film, by relatively decreasing the thermal crosslinking property of the side-chain liquid crystal polymer (A) having the homeotropic alignment property, the photo-alignment thermosetting liquid crystal composition of the present disclosure can form the alignment layer-cum-retardation layer which exhibits the good homeotropic alignment property and the good liquid crystal aligning ability (the ability of aligning the directly stacked liquid crystal material) and which has durability while it functions as both an alignment layer and a retardation layer solely.

Also, the photo-alignment thermosetting liquid crystal composition of the present disclosure is presumed as follows: as the thermal curing of the copolymer (B) proceeds well, a three-dimensional crosslinked structure is formed in the film and, as a result, the homeotropic alignment property of the homeotropically aligned polymer (A) is more resistant to fluctuation. Accordingly, a change in the homeotropic alignment property caused by heating the alignment layer-cum-retardation layer, is suppressed; a change in the homeotropic alignment property caused by solvent permeation due to the liquid crystal material directly applied on the alignment layer-cum-retardation layer, is also suppressed with ease; and good reproducibility of the homeotropic alignment property or good durability is obtained.

Hereinafter, the components of the photo-alignment thermosetting liquid crystal composition of the present disclosure will be described.

### 1. Side-Chain Liquid Crystal Polymer (A)

The side-chain liquid crystal polymer (A) used in the present disclosure is a side-chain liquid crystal polymer which contains a liquid crystal constitutional unit containing a liquid crystal moiety in a side chain and a non-liquid crystal constitutional unit containing an alkylene group in a side chain.

Hereinafter, the constitutional units of the side-chain liquid crystal polymer (A) will be described.

The side-chain liquid crystal polymer (A) used in the present disclosure satisfies any of the (i) to (vi) in relation to the copolymer (B) described below.

When the (i) is satisfied, in the non-liquid crystal, thermally crosslinkable constitutional unit of the side-chain liquid crystal polymer (A), which contains a thermally crosslinkable group and an alkylene group in a side chain, the total of the carbon atom number and oxygen atom number of the alkylene group which optionally contains —O— in its carbon chain and which binds the thermally crosslinkable group and the monomer unit to each other, is smaller than the linear alkylene group which contains 4 to 11 carbon atoms, which optionally contains —O— in a carbon chain, and which binds the thermally crosslinkable group and the monomer unit to each other in the thermally crosslinkable constitutional unit of the copolymer (B). In the side-chain liquid crystal polymer (A), since the length of the part linking the thermally crosslinkable group and the monomer unit is relatively short, the thermal crosslinking agent is less likely to bind to the thermally crosslinkable group; the reactivity between the thermally crosslinkable constitutional unit and the thermal crosslinking agent decreases; and the thermal crosslinking reaction of the side-chain liquid crystal polymer (A) is relatively less likely to proceed compared to the copolymer (B). When there is a difference in curing speed between the side-chain liquid crystal polymer (A) and the copolymer (B), by controlling the below-described thermal crosslinking agent amount or acid catalyst amount, the condition in which the copolymer (B) can be cured earlier, can be made.

In the non-liquid crystal, thermally crosslinkable constitutional unit of the side-chain liquid crystal polymer (A), the alkylene group which optionally contains —O— in a carbon chain and in which the thermally crosslinkable group is bound to the primary carbon, is preferably such that the total of the carbon atom number and the oxygen atom number is preferably 2 or more smaller than or more preferably 3 or more smaller than the linear alkylene group which contains 4 to 11 carbon atoms and which optionally contains —O— in the carbon chain in the thermally crosslinkable constitutional unit of the copolymer (B). In the side-chain liquid crystal polymer (A), since the length of the linking group linking the thermally crosslinkable group and the monomer unit vary as described above, the thermal crosslinking reaction of the side-chain liquid crystal polymer (A) is relatively less likely to proceed, and a difference in curing speed between the side-chain liquid crystal polymer (A) and the copolymer (B) is likely to be made. Accordingly, in the coating film, the condition in which the copolymer (B) can be thermally cured earlier, is likely to be made, and the homeotropic alignment property and the photo-alignment property can be good with ease.

When the (ii) is satisfied, the non-liquid crystal, thermally crosslinkable constitutional unit of the side-chain liquid crystal polymer (A), which contains a thermally crosslinkable group and an alkylene group in a side chain, has a structure such that the thermally crosslinkable group is bound to a secondary or tertiary carbon of the alkylene group. Accordingly, the thermal crosslinking reaction is relatively less likely to proceed compared to the thermally crosslinkable group of the copolymer (B) having the structure such that the thermally crosslinkable group is bound to the primary carbon by binding to the terminal of the linear alkylene group. As a result, a difference in curing speed between the side-chain liquid crystal polymer (A) and the copolymer (B) is likely to be made. Accordingly, in the coating film, the condition in which the copolymer (B) can be thermally cured earlier, is likely to be made, and the homeotropic alignment property and the photo-alignment property can be good with ease.

Primary carbon is a primary carbon atom, and it means a carbon atom which is bound to one different carbon atom. Secondary carbon is a secondary carbon atom, and it means a carbon atom which is bound to two different carbon atoms. Tertiary carbon is a tertiary carbon atom, and it means a carbon atom which is bound to three different carbon atoms.

When the (iii) is satisfied, the non-liquid crystal, thermally crosslinkable constitutional unit of the side-chain liquid crystal polymer (A) has a structure such that at least one kind of thermally crosslinkable group selected from the group consisting of a hydroxy group, a mercapto group and an amino group is bound to the aryl group. Accordingly, the thermal crosslinking reaction is relatively less likely to proceed compared to the thermally crosslinkable group of the copolymer (B) having the structure such that the thermally crosslinkable group is bound to the primary carbon by binding to the terminal of the linear alkylene group. As a result, a difference in curing speed between the side-chain liquid crystal polymer (A) and the copolymer (B) is likely to be made. Accordingly, in the coating film, the condition in which the copolymer (B) can be thermally cured earlier, is likely to be made, and the homeotropic alignment property and the photo-alignment property can be good with ease.

When the (iv) is satisfied, the side-chain liquid crystal polymer (A) contains a non-liquid crystal, thermally crosslinkable constitutional unit containing an arylene group, an alkylene group and at least one kind of thermally crosslinkable group selected from the group consisting of a carboxy group, a glycidyl group and an amide group; the non-liquid crystal, thermally crosslinkable constitutional unit of the side-chain liquid crystal polymer (A) has a structure such that the thermally crosslinkable group is bound to the arylene group; and the arylene group has a structure such that it is bound to a carbon or oxygen atom of the alkylene group which optionally contains —O— in its carbon chain or at its terminal and in which a total of a carbon atom number and an oxygen atom number is 3 or more smaller than the linear alkylene group which contains 4 to 11 carbon atoms and which optionally contains —O— in the carbon chain in the thermally crosslinkable constitutional unit of the copolymer (B). Accordingly, the thermal crosslinking agent is less likely to bind to the thermally crosslinkable group of the side-chain liquid crystal polymer (A); the reactivity between the thermally crosslinkable constitutional unit and the thermal crosslinking agent decreases; and the thermal crosslinking reaction of the side-chain liquid crystal polymer (A) is relatively less likely to proceed compared to the copolymer (B). As a result, a difference in curing speed between the side-chain liquid crystal polymer (A) and the copolymer (B) is likely to be made. Accordingly, in the coating film, the condition in which the copolymer (B) can be thermally cured earlier, is likely to be made, and the homeotropic alignment property and the photo-alignment property can be good with ease.

When the (v) is satisfied, the side-chain liquid crystal polymer (A) contains, in addition to the non-liquid crystal constitutional unit containing an alkylene group in a side chain, a thermally crosslinkable constitutional unit containing no alkylene group in a side chain and a thermally crosslinkable group in the side chain. In this case, the reaction of the thermally crosslinkable group of the side-chain liquid crystal polymer (A) is relatively less likely to proceed compared to the thermally crosslinkable group of the copolymer (B) having the structure such that the thermally crosslinkable group is bound to the primary carbon by binding to the terminal of the linear alkylene group. As a result, a difference in curing speed between the side-chain liquid crystal polymer (A) and the copolymer (B) is likely to be made. Accordingly, in the coating film, the condition in which the copolymer (B) can be thermally cured earlier, is likely to be made, and the homeotropic alignment property and the photo-alignment property can be good with ease.

When the (vi) is satisfied, the side-chain liquid crystal polymer (A) does not contain a non-liquid crystal, thermally crosslinkable constitutional unit containing a thermally crosslinkable group and an alkylene group in a side chain and a thermally crosslinkable constitutional unit containing a thermally crosslinkable group in a side chain, that is, the side-chain liquid crystal polymer (A) does not contain a thermally crosslinkable group. Accordingly, in the coating film, the condition in which only the copolymer (B) can be thermally cured, is likely to be made, and the homeotropic alignment property and the photo-alignment property can be good with ease.

When the side-chain liquid crystal polymer (A) contains two or more kinds of non-liquid crystal, thermally crosslinkable constitutional units, all of the non-liquid crystal, thermally crosslinkable constitutional units satisfy any of the (i) to (iv).

When the side-chain liquid crystal polymer (A) contains two or more thermally crosslinkable groups per non-liquid crystal, thermally crosslinkable constitutional unit, all of the thermally crosslinkable groups may satisfy any of the (i) to (iv).

### (1) Liquid Crystal Constitutional Unit

In the embodiment of the present disclosure, the liquid crystal constitutional unit contains a side chain including a liquid crystal moiety, that is, a moiety showing a liquid crystal property. The liquid crystal constitutional unit is preferably a constitutional unit containing, in a side chain, a mesogen showing a liquid crystal property. The liquid crystal constitutional unit is preferably a constitutional unit derived from a compound showing a liquid crystal property in which a polymerizable group is bonded to a mesogen group to interpose a spacer therebetween. In the present disclosure, the mesogen denotes a moiety having a high rigidity so as to show a liquid crystal property. Examples thereof include a partial structure which contains two or more cyclic structures, preferably three or more cyclic structures and which is a structure in which the cyclic structures are bonded directly to each other or the cyclic structures are bonded to each other to interpose 1 to 3 atoms therebetween. When the side chain contains such a moiety showing a liquid crystal property, the liquid crystal constitutional unit is homeotropically aligned with ease.

The cyclic structures may each be an aromatic ring such as benzene, naphthalene or anthracene, or may be a cyclic aliphatic hydrocarbon such as cyclopentyl or cyclohexyl.

When the cyclic structures are bound to each other via 1 to 3 atoms, examples of the structure of this linking moiety include —O—, —S—, —O—C(═O)—, —C(═O)—O—, —O—C(═O)—O—, —NR—C(═O)—, —C(═O)—NR—, —O—C(═O)—NR—, —NR—C(═O)—O—, —NR—C(═O)—NR—, —O—NR—, and —NR—O— where Rs are each a hydrogen atom or a hydrocarbon group.

The mesogen is particularly preferably a rodlike mesogen in which, for example, benzene rings are bound to each other at their para-positions, or naphthalene rings are bound to each other at their 2- and 6-positions to make the linkage of the cyclic structures into a rod form.

When the liquid crystal constitutional unit is a constitutional unit containing, in a side chain, a mesogen showing a liquid crystal property, the terminal of the side chain of the constitutional unit is preferably a polar group or preferably contains an alkyl group, from the viewpoint of the homeotropic alignment property. As the polar group, examples include, but are not limited to, —F, —Cl, —CN, —OCF₃, —OCF₂H, —NCO, —NCS, —NO₂, —NHC(═O)—R′, —C(═O)—OR′, —OH, —SH, —CHO, —SO₃H, —NR′₂, —R″ and —OR″ where R′s are each a hydrogen atom or a hydrocarbon, and R″s are each an alkyl group.

As the liquid crystal constitutional unit, examples include a constitutional unit containing, as a side chain, a group represented by —R²-(L¹-Ar¹)ₐ-R³ (where R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; L's may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.)

In R², m and m′ are each independently an integer of from 2 to 10. From the viewpoint of the homeotropic alignment property, m and m are preferably from 2 to 8, and more preferably from 2 to 6.

As the arylene group containing 6 to 10 carbon atoms in Ar², examples include, but are not limited to, a phenylene group and a naphthylene group. Of these groups, a phenylene group is more preferred. The arylene group may contain a substituent besides R¹³, and as the substituent, examples include, but are not limited to, an alkyl group containing 1 to 5 carbon atoms, and a halogen atom such as a fluorine atom, a chlorine atom and a bromine atom.

In R³, R⁴ is a hydrogen atom or an alkyl group containing 1 to 6 carbon atoms. R⁴ is particularly preferably a hydrogen atom or an alkyl group containing 1 to 3 carbon atoms. In R³, R⁵ is an alkyl group containing 1 to 6 carbon atoms. R⁵ is particularly preferably an alkyl group containing 1 to 5 carbon atoms.

The liquid crystal constitutional unit is preferably a constitutional unit derived from a polymerizable monomer which contains an ethylenic double bond-containing group. As the monomer which contains an ethylenic double bond-containing group, examples include, but are not limited to, a derivative such as a (meth)acrylic acid ester, styrene, (meth)acrylamide, maleimide, vinyl ether and vinyl ester. The liquid crystal constitutional unit is particularly preferably a constitutional unit derived from a (meth)acrylic acid ester, from the viewpoint of the homeotropic alignment property.

In the embodiment of the present disclosure, the liquid crystal constitutional unit preferably contains a constitutional unit represented by the following general formula (I) from the viewpoint of the homeotropic alignment property:

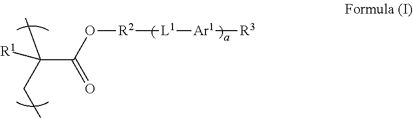

where R¹ is a hydrogen atom or a methyl group; R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; Lis may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.

In the constitutional unit represented by the general formula (I), the group represented by —R²-(L¹-Ar¹)ₐ-R³ may be the same as described above.

The constitutional unit represented by the general formula (I) is preferably a constitutional unit represented by the following chemical formula (I-1), a constitutional unit represented by the following chemical formula (I-2), or a constitutional unit represented by the following chemical formula (I-3), for example. However, the constitutional unit is not limited to these examples.

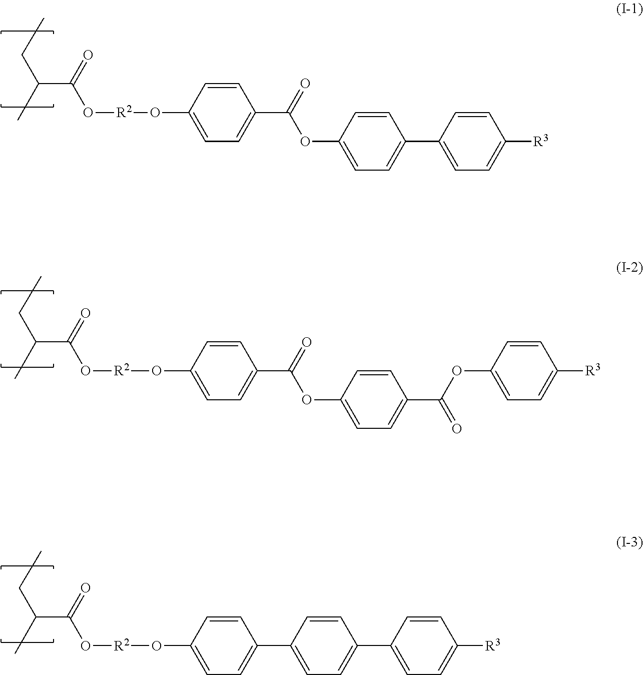

In the constitutional units represented by the general formulae (I-1) to (I-3), R² and R³ are the same as R² and R³ in the general formula (I).

In the embodiment of the present disclosure, the liquid crystal constitutional units may be used solely or in combination of two or more.

For the synthesis of the copolymer, monomers from which the liquid crystal constitutional unit is derived, such as a (meth)acrylic acid ester derivative, can be used. The monomers from which the liquid crystal constitutional unit is derived, such as a (meth)acrylic acid ester derivative, may be used solely or in combination of two or more.

From the viewpoint of improving the homeotropic alignment property of the liquid crystal constitutional unit and obtaining a sufficient liquid crystal aligning property, when the amount of the constitutional units contained in the whole copolymer is 100% by mole, the content of the liquid crystal constitutional unit in the copolymer is preferably in a range of from 40% by mole to 90% by mole, more preferably in a range of from 40% by mole to 80% by mole, still more preferably in a range of from 45% by mole to 70% by mole, and particularly preferably in a range of from 50% by mole to 65% by mole.

The content of the constitutional units in the copolymer can be calculated from integral values obtained by 1H-NMR measurement.

### (2) Non-Liquid Crystal Constitutional Unit Containing an Alkylene Group in a Side Chain

In the non-liquid crystal constitutional unit containing an alkylene group in a side chain, the side chain containing an alkylene group has the effect of promoting, when the side-chain liquid crystal polymer enters a liquid crystal state, the homeotropic alignment of the moiety showing a liquid crystal property (i.e., a mesogen) of the side chain of the liquid crystal constitutional unit.

As the non-liquid crystal constitutional unit containing an alkylene group in a side chain, examples include, but are not limited to, a constitutional unit containing, as a side chain, a group represented by -L²-R¹³ or -L^{2′}-R⁴ (where L² is a linear or branched alkylene group containing 1 to 18 carbon atoms and optionally containing a substituent; L^{2′} is a linking group represented by —(C₂H₄O)_{n′}—; R¹³ is a methyl group optionally containing a substituent, an aryl group optionally containing an alkyl group, or —OR¹⁵; R¹⁴ and R¹⁵ are each independently an alkyl group optionally containing a substituent, or an aryl group optionally containing a substituent; and n′ is an integer of from 1 to 18.)

L² is a linear or branched alkylene group containing 1 to 18 carbon atoms and optionally containing a substituent, and L^{2′} is a linking group represented by —(C₂H₄O)_{n′}—.

As the linear or branched alkylene group containing 1 to 18 carbon atoms and optionally containing a substituent in L², examples include, but are not limited to, a linear alkylene group such as a methylene group, a dimethylene group (an ethylene group), a trimethylene group, a tetramethylene group, a pentamethylene group, a hexamethylene group, an octamethylene group, a decamethylene group, a dodecamethylene group, a tridecamethylene group, a pentadecamethylene group, a hexadecamethylene group, a heptadecamethylene group and an octadecamethylene group, and a branched alkylene group such as a methylmethylene group, a methylethylene group, a 1,1-dimethylethylene group, a 1-methylpentylene group and a 1,4-dimethylbutylene group.

In R¹⁴ and R¹⁵, the alkyl group may be a linear, branched or cyclic alkyl group.

In R¹⁴ and R¹⁵, the alkyl group is preferably an alkyl group containing 1 to 20 carbon atoms. As the alkyl group containing 1 to 20 carbon atoms, examples include, but are not limited to, a linear alkyl group such as a methyl group, an ethyl group, an n-propyl group, an n-butyl group, an n-pentyl group, an n-hexyl group, an n-octyl group and an n-decyl group; a branched alkyl group such as an i-propyl group, an i-butyl group and a t-butyl group; an alkenyl group such as a 1-propenyl group and a 1-butenyl group; an alkynyl group such as an ethynyl group and a 2-propynyl group; a cycloalkyl group such as a cyclopropyl group, a cyclobutyl group, a cyclopentyl group, a cyclohexyl group, a cycloheptyl group, a cyclooctyl group, a cyclodecyl group, a norbornyl group and an adamantyl group; and a cycloalkenyl group such as a 1-cyclohexenyl group. When the alkyl group is a cycloalkyl group, it is preferably a cycloalkyl group substituted with a linear alkyl group.

The alkyl group in R¹⁴ and R¹³ is not particularly limited, and it is preferably an alkyl group containing 1 to 12 carbon atoms, from the viewpoint of in-plane uniformity of retardation.

The aryl group in R¹³, R¹⁴ and R¹⁵ is not particularly limited, and it is preferably an aryl group containing 6 to 20 carbon atoms. As the aryl group, examples include, but are not limited to, a phenyl group, a naphthyl group and an antracenyl group. Of them, a phenyl or naphthyl group is preferred, and a phenyl group is more preferred. The aryl group is preferably an aryl group substituted with a linear alkyl group.

The non-liquid crystal constitutional unit containing an alkylene group in a side chain may contain, as a substituent, a reactive group reactive with other components. For example, it may contain the same thermally crosslinkable group as the copolymer (B) described below.

As the non-liquid crystal constitutional unit containing an alkylene group in a side chain, examples include a non-liquid crystal, non-thermally crosslinkable constitutional unit and a non-liquid crystal, thermally crosslinkable constitutional unit. The non-liquid crystal constitutional unit containing an alkylene group in a side chain may contain only a non-liquid crystal, non-crosslinkable constitutional unit, or it may contain only a non-liquid crystal, thermally crosslinkable constitutional unit.

From the viewpoint of improving the homeotropic alignment property with ease, the non-liquid crystal constitutional unit containing an alkylene group in a side chain preferably contains at least a non-liquid crystal, non-thermally crosslinkable constitutional unit. From the viewpoint of improving the homeotropic alignment property and the durability with ease, the non-liquid crystal constitutional unit containing an alkylene group in a side chain more preferably contains a non-liquid crystal, non-thermally crosslinkable constitutional unit and a non-liquid crystal, thermally crosslinkable constitutional unit.

In the non-liquid crystal, non-thermally crosslinkable constitutional unit containing an alkylene group in a side chain, the substituent optionally contained in the methyl group in R³ may be a non-thermally crosslinkable substituent, for example. As the non-thermally crosslinkable substituent, examples include, but are not limited to, a halogen atom such as a fluorine atom, a chlorine atom and a bromine atom.

In the non-liquid crystal, non-thermally crosslinkable constitutional unit containing an alkylene group in a side chain, the substituent optionally contained in the linear or branched alkylene group in L² and the substituent optionally contained in the alkyl group in R¹⁴ and R¹⁵ may each be a non-thermally crosslinkable substituent, for example. As the non-thermally crosslinkable substituent, examples include, but are not limited to, an alkoxy group, a nitro group, and a halogen atom such as a fluorine atom, a chlorine atom and a bromine atom. Of them, preferred is a halogen atom such as a fluorine atom, a chlorine atom and a bromine atom.

In the non-liquid crystal, non-thermally crosslinkable constitutional unit containing an alkylene group in a side chain, the substituent optionally contained in the aryl group in R¹³, R¹⁴ and R¹⁵ may each be a non-thermally crosslinkable substituent, for example. As the non-thermally crosslinkable substituent, examples include, but are not limited to, an alkyl group, an alkoxy group, a nitro group, and a halogen atom such as a fluorine atom, a chlorine atom and a bromine atom. As the alkyl group, examples include, but are not limited to, an alkyl group containing 1 to 12 carbon atoms, and an alkyl group containing 1 to 9 carbon atoms. The alkyl group may be a linear alkyl group, or it may be an alkyl group containing a branched structure or a cyclic structure. As the non-thermally crosslinkable substituent, preferred is an alkyl group containing 1 to 9 carbon atoms or a halogen atom such as a fluorine atom, a chlorine atom and a bromine atom. As the alkyl group, examples include, but are not limited to, a methyl group, an ethyl group, a propyl group, a butyl group, a pentyl group, a hexyl group, a heptyl group, an octyl group, a nonyl group, a decyl group, a cyclopentyl group, a cyclohexyl group, a cyclohexylmethyl group, a cyclohexylethyl group, and a cyclohexylpropyl group. A hydrogen atom contained in the alkyl group may be substituted with a halogen atom.

In the non-liquid crystal, thermally crosslinkable constitutional unit containing an alkylene group in a side chain, the substituent optionally contained in the methyl group in R¹³, in the linear or branched alkylene group in L², in the alkyl group in R¹⁴ and R¹⁵, and in the aryl group in R¹³, R¹⁴ and R¹⁵ is preferably a thermally crosslinkable group. As the thermally crosslinkable group, examples include, but are not limited to, the same thermally crosslinkable group as the copolymer (B) described below. For example, the thermally crosslinkable group may be at least one kind selected from the group consisting of a hydroxy group, a carboxy group, a mercapto group, a glycidyl group, an amino group and an amide group. From the viewpoint of reactivity, the thermally crosslinkable group is preferably a hydroxy group.

It is preferable that one thermally crosslinkable group is contained per non-liquid crystal, thermally crosslinkable constitutional unit, or two or more thermally crosslinkable groups may be contained per non-liquid crystal, thermally crosslinkable constitutional unit.

In the non-liquid crystal, non-thermally crosslinkable constitutional unit containing an alkylene group in a side chain, from the viewpoint of improving the homeotropic alignment property with ease, L² is preferably —(CH₂)ₙ— (where n is an integer of from 1 to 18). Also, n is preferably an integer of from 3 to 17, and more preferably an integer of from 5 to 17. Also, n′ is an integer of from 1 to 18, preferably an integer of from 3 to 17, and more preferably an integer of from 5 to 17.

Meanwhile, in the non-liquid crystal, thermally crosslinkable constitutional unit containing an alkylene group in a side chain, from the viewpoint of slowing down the progress of a thermal crosslinking reaction, L² is preferably a branched alkyl group, or the carbon atom number is preferably small. In particular, the carbon atom number is preferably 6 or less, more preferably 4 or less, and still more preferably 3 or less.

In the non-liquid crystal, non-thermally crosslinkable constitutional unit containing an alkylene group in a side chain, from the viewpoint of improving the homeotropic alignment property with ease, the alkyl group in R¹⁴ and R¹⁵ is preferably linear. Meanwhile, in the non-liquid crystal, thermally crosslinkable constitutional unit containing an alkylene group in a side chain, to slow down the progress of a thermal crosslinking reaction, a linear, branched or cyclic alkyl group may be appropriately selected and used.

The non-liquid crystal constitutional unit is preferably a constitutional unit derived from a polymerizable monomer which contains an ethylenic double bond-containing group. As the monomer which contains an ethylenic double bond-containing group, examples include, but are not limited to, a derivative such as a (meth)acrylic acid ester, styrene, (meth)acrylamide, maleimide, vinyl ether and vinyl ester. From the viewpoint of the homeotropic alignment property, the non-liquid crystal constitutional unit is preferably a constitutional unit derived from a (meth)acrylic acid ester derivative or styrene, and more preferably a constitutional unit derived from a (meth)acrylic acid ester derivative.

In the embodiment of the present disclosure, among the non-liquid crystal constitutional units, the non-liquid crystal, non-thermally crosslinkable constitutional unit preferably contains the constitutional unit represented by the following formula (II):

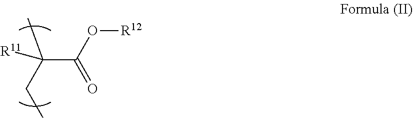

where R¹¹ is a hydrogen atom or a methyl group; R¹² is a group represented by -L²″-R¹³ or -L²′-R¹⁴; L²″ is —(CH₂)ₙ—; L²′ is a linking group represented by —(C₂H₄O)ₙ′—; R¹³ is a methyl group optionally containing a substituent, an aryl group optionally containing an alkyl group, or —OR¹⁵; R¹⁴ and R¹⁵ are each independently an alkyl group optionally containing a substituent, or an aryl group optionally containing a substituent; and n and n′ are each independently an integer of from 1 to 18.

In the constitutional unit represented by the formula (II), the group represented by -L²″-R¹³ or -L²′-R¹⁴ may be the same as described above.

When the non-liquid crystal, non-thermally crosslinkable constitutional unit is the constitutional unit represented by the formula (II), as the substituent optionally contained in the constitutional unit represented by the formula (II), examples include, but are not limited to, the above-described non-thermally crosslinkable substituent.

In the embodiment of the present disclosure, when the non-liquid crystal constitutional unit contains the non-liquid crystal, thermally crosslinkable constitutional unit, the non-liquid crystal, thermally crosslinkable constitutional unit preferably contains the constitutional unit represented by the following formula (III), from the viewpoint of increasing the reactivity and thereby improving the durability:

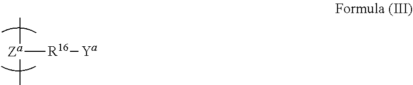

where Z^{a} is at least one kind of monomer unit selected from the group consisting of the following formulae (a-1) to (a-6); R¹⁶ is a group represented by -L^{2a}-R^{13′}— (where L^{2a} is a linear or branched alkylene group which contains 1 to 10 carbon atoms and which optionally contains —O— in its carbon chain; R^{13′} is —OR^{15′}, a residue obtained by removal of a hydrogen atom from an aryl group, or a residue obtained by removal of a hydrogen atom from a methyl group which optionally contains a substituent; and R^{5′} is a residue obtained by removal of a hydrogen atom from an aryl group); and Y^{a} is at least one kind of thermally crosslinkable group selected from the group consisting of a hydroxy group, a carboxy group, a mercapto group, a glycidyl group, an amino group and an amide group:

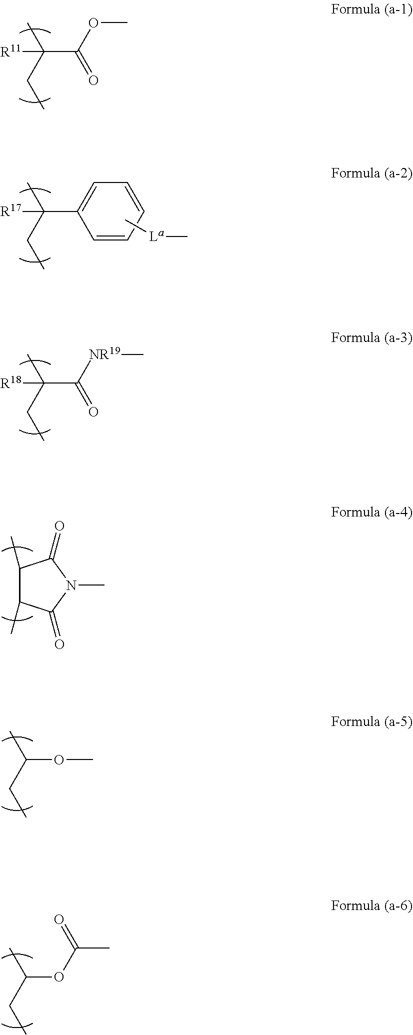

where R¹¹ is a hydrogen atom, a methyl group, a chlorine atom or a phenyl group; R¹⁷ is a hydrogen atom or a methyl group; R¹⁸ is a hydrogen atom, a methyl group, a chlorine atom or a phenyl group; R¹⁹ is a hydrogen atom or an alkyl group containing 1 to 4 carbon atoms; L^{a} is a single bond, —O—, —S—, —COO—, —COS—, —CO— or —OCO—; and when L^{a} is a single bond, R¹⁶ is directly bound to a styrene skeleton.

R¹⁶ is a group represented by -L^{2a}-R^{13′}— (where L²a is a linear or branched alkylene group which contains 1 to 10 carbon atoms and which optionally contains —O— in its carbon chain; R^{13′} is —OR^{15′}, a residue obtained by removal of a hydrogen atom from an aryl group, or a residue obtained by removal of a hydrogen atom from a methyl group which optionally contains a substituent; and R¹⁵′ is a residue obtained by removal of a hydrogen atom from an aryl group).

The methyl group and the aryl group in R^{13′} and in R^{15′}, which optionally contains a substituent and which is before being subjected to the removal of a hydrogen atom, may be the same as those of R¹³ and those of R¹⁵.

L^{2a} may be a linear or branched alkylene group containing 1 to 6 carbon atoms and optionally containing —O— in its carbon chain; it may be a linear or branched alkylene group containing 1 to 4 carbon atoms and optionally containing —O— in its carbon chain; it may be a linear or branched alkylene group optionally containing 1 to 3 carbon atoms and optionally containing —O— in its carbon chain; it may be a linear alkylene group containing 1 or 2 carbon atoms and optionally containing —O— in its carbon chain; or it may be a methylene group.

When the carbon atom number of L^{2a} is small, in the thermally crosslinkable constitutional unit, the distance between the thermally crosslinkable group and the main skeleton of the copolymer is short. Accordingly, the thermal crosslinking agent is less likely to bind to the thermally crosslinkable group, and the reactivity between the thermally crosslinkable constitutional unit and the thermal crosslinking agent decreases.

When L^{2a} is a branched alkylene group optionally containing —O— in its carbon chain, as the branched alkylene group, examples include, but are not limited to, an alkylene group such that the carbon atom to which the thermally crosslinkable group Y^{a} is bound, is a secondary or tertiary carbon. When the R¹⁶ is a branched alkylene group optionally containing —O— in its carbon chain, as the branched alkylene group, example include, but are not limited to, a methylmethylene group, a methylethylene group, a 1,1-dimethylethylene group, a 1-methylpropylene group and an ethylethylene group.

The substituent optionally contained in the linear or branched alkylene group containing 1 to 11 carbon atoms and optionally containing —O— in its carbon chain in R¹⁶, may be a non-thermally crosslinkable substituent, for example. As the non-thermally crosslinkable substituent, examples include, but are not limited to, a halogen atom such as a fluorine atom, a chlorine atom and a bromine atom, an alkoxy group, a nitro group, an aryl group optionally containing a substituent, and an aryloxy group optionally containing a substituent. As the substituent of the aryl group and that of the aryloxy group, examples include, but are not limited to, the same substituent optionally contained in the aryl group in R¹³, R¹⁴ and R¹⁵.

The copolymer may contain one kind of the non-liquid crystal constitutional unit containing an alkylene group in a side chain or may contain two or more kinds of such non-liquid crystal constitutional units.

As the non-liquid crystal, non-thermally crosslinkable constitutional unit containing an alkylene group in a side chain, examples include, but are not limited to, the following chemical formulae (II-1) to (II-10). As the non-liquid crystal, thermally crosslinkable constitutional unit containing an alkylene group in a side chai, examples include, but are not limited to, the following chemical formulae (III-1) to (III-12).

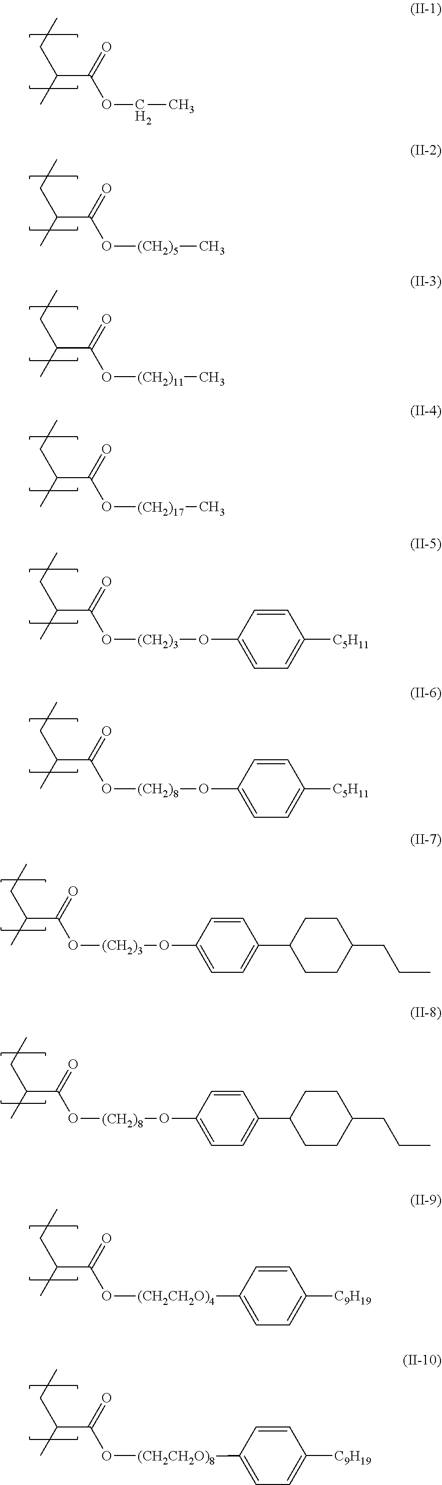

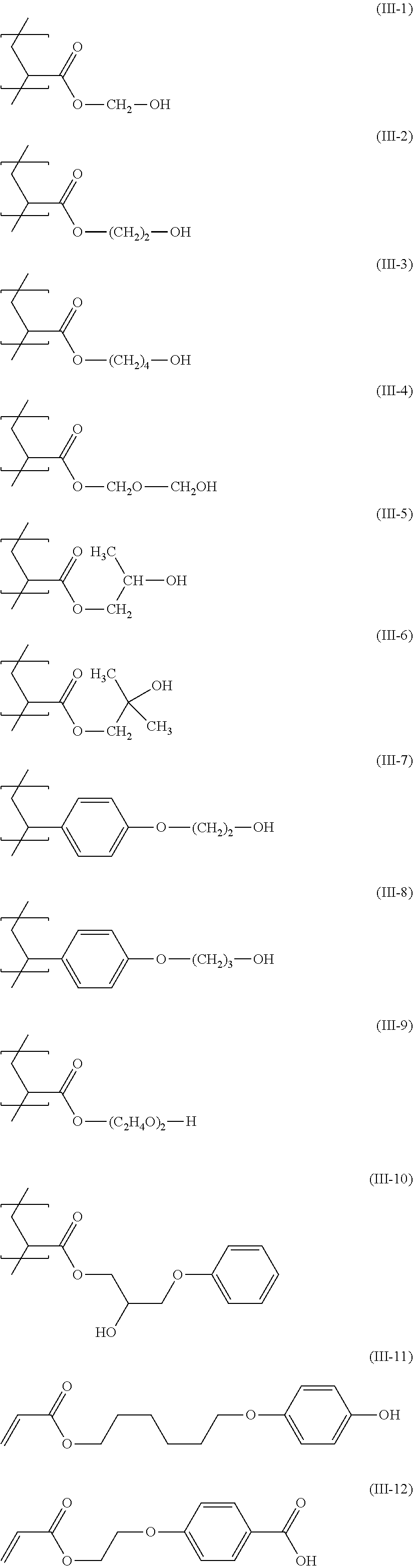

For the synthesis of the copolymer, monomers from which the non-liquid crystal constitutional unit is derived, such as a (meth)acrylic acid ester derivative, can be used. The monomers from which the non-liquid crystal constitutional unit is derived, such as a (meth)acrylic acid ester derivative, may be used solely or in combination of two or more.

From the viewpoint of improving the homeotropic alignment property of the liquid crystal constitutional unit and obtaining a sufficient liquid crystal aligning property, when the amount of the constitutional units contained in the whole copolymer is 100% by mole, the content of the non-liquid crystal constitutional unit in the copolymer is preferably in a range of from 10% by mole to 60% by mole, more preferably in a range of from 15% by mole to 50% by mole, still more preferably in a range of from 15% by mole to 45% by mole, and particularly preferably in a range of from 20% by mole to 40% by mole.

In the case where both the non-liquid crystal, non-thermally crosslinkable constitutional unit and the non-liquid crystal, thermally crosslinkable constitutional unit are contained as the non-liquid crystal constitutional unit of the copolymer, when the total amount of the non-liquid crystal constitutional units contained in the whole copolymer is 100% by mole, the content of the non-liquid crystal, thermally crosslinkable constitutional unit is preferably in a range of from 5% by mole to 70% by mole, and more preferably in a range of from 20% by mole to 50% by mole.

The content of the constitutional units in the copolymer can be calculated from integral values obtained by 1H-NMR measurement.

### (3) Other Constitutional Units

The side-chain liquid crystal polymer (A) used in the present disclosure contains at least the liquid crystal constitutional unit and the non-liquid crystal constitutional unit containing an alkylene group in a side chain. The side-chain liquid crystal polymer (A) may further contain other constitutional units.

Other constitutional units include, for example, a thermally crosslinkable constitutional unit containing the thermally crosslinkable group and containing no alkylene group in a side chain, and a photo-alignment constitutional unit containing the photo-alignment group of the below-described copolymer (B) in a side chain.

As the thermally crosslinkable constitutional unit containing the thermally crosslinkable group and containing no alkylene group in a side chain, examples include, but are not limited to, (meth)acrylic acid, 4-hydroxyphenyl (meth)acrylate, 4-hydroxystyrene and 4-carboxystyrene.

From the viewpoint of improving the endurance reliability of the retardation layer, the side-chain liquid crystal polymer (A) used in the present disclosure preferably contains at least one kind of thermally crosslinkable constitutional unit containing a thermally crosslinkable group in a side chain, which is selected from the group consisting of the non-liquid crystal, thermally crosslinkable constitutional unit containing an alkylene group in a side chain and the thermally crosslinkable constitutional unit containing the thermally crosslinkable group and containing no alkylene group in a side chain.

The photo-alignment constitutional unit may be the same as the photo-alignment constitutional unit which contains a photo-alignment group in a side chain and which is contained in the copolymer (B) described below.

From the viewpoint of improving the homeotropic alignment property of the liquid crystal constitutional unit and obtaining a sufficient liquid crystal aligning property, when the amount of the constitutional units contained in the whole copolymer is 100% by mole, the content of other constitutional units in the copolymer is preferably in a range of 30% by mole or less, and more preferably in a range of 20% by mole or less.

### (4) Copolymer of the Side-Chain Liquid Crystal Polymer (A)

In the embodiment of the present disclosure, the side-chain liquid crystal polymer (A) may be a block copolymer containing block moieties made of the liquid crystal constitutional unit and block moieties made of the non-liquid crystal constitutional unit containing an alkylene group in a side chain, or it may be a random copolymer in which the liquid crystal constitutional unit and the non-liquid crystal constitutional unit containing an alkylene group in a side chain are irregularly arranged. In the present embodiment, the random copolymer is preferred in order to improve the homeotropic alignment property of the side-chain liquid crystal polymer and the in-plane uniformity of the retardation value.

The mass average molecular weight Mw of the side-chain liquid crystal polymer (the copolymer) is not particularly limited, and it is preferably in a range of from 5000 to 80000, more preferably in a range of from 8000 to 50000, and still more preferably in a range of from 10000 to 36000. When the mass-average molecular weight is in any one of the ranges, the resultant liquid crystal composition is excellent in stability, and the composition is excellent in handleability when made into a retardation layer.

The mass average molecular weight Mw is a value measured by gel permeation chromatography (GPC). The measurement is made using an instrument HLC-8120GPC manufactured by Tosoh Corp., using N-methylpyrrolidone into which 0.01 mole/L of lithium bromide is added as an eluting solvent, using polymers of Mw 377400, 210500, 96000, 50400, 206500, 10850, 5460, 2930, 1300, and 580 (Easi PS-2 series, each manufactured by Polymer Laboratories Ltd.) and a polymer of Mw 1090000 (manufactured by Tosoh Corp.) as polystyrene standards for calibration curves, and using two columns TSK-GEL ALPHA-M (manufactured by Tosoh Corp.) as measuring columns.

As the method for synthesizing the copolymer of the side-chain liquid crystal polymer (A), examples include, but are not limited to, copolymerization of a monomer from which the liquid crystal constitutional unit is derived and a monomer from which the non-liquid crystal constitutional unit containing an alkylene group in a side chain is derived, by a conventional production method.

The side-chain liquid crystal polymer (A) may be used in any of the following forms: the form of a solution in synthesizing the copolymer, the form of a powder, and the form of a solution obtained by re-dissolving a refined powder in a solvent described below.

As the side-chain liquid crystal polymer (A), one kind of the side-chain liquid crystal polymer may be used solely, or two or more kinds of such polymers may be used in combination. From the viewpoint of exhibiting the homeotropic alignment property, with respect to 100 parts by mass of the solid content of the liquid crystal composition, the content of the side-chain liquid crystal polymer (A) may be from 60 parts by mass to 99 parts by mass. It is preferably from 70 parts by mass to 95 parts by mass, and more preferably from 80 parts by mass to 90 parts by mass.

In the present disclosure, the solid content denotes all components from which any solvent is removed. Examples thereof include the below-described polymerizable liquid crystal compound even when this compound is in a liquid form.

### 2. Copolymer (B)

The copolymer (B) used in the present disclosure contains a photo-alignment constitutional unit containing a photo-alignment group and a thermally crosslinkable constitutional unit containing a thermally crosslinkable group in a side chain by a specific structure.

Hereinafter, the constitutional units of the copolymer (B) will be described.

### (1) Photo-Alignment Constitutional Unit

In the present invention, the photo-alignment constitutional unit is a moiety that exhibits anisotropy by causing a photoreaction by light irradiation. The photoreaction is preferably a photodimerization reaction or a photoisomerization reaction. That is, the photo-alignment constitutional unit is preferably a photodimerization constitutional unit that exhibits anisotropy by causing a photodimerization reaction by light irradiation, or it is preferably a photoisomerization constitutional unit that exhibits anisotropy by causing a photoisomerization reaction by light irradiation.

The photo-alignment constitutional unit contains a photo-alignment group. As described above, the photo-alignment group is a functional group that exhibits anisotropy by causing a photoreaction by light irradiation. The photo-alignment group is preferably a functional group that causes a photodimerization reaction or a photoisomerization reaction.

As the photo-alignment group that causes a photodimerization reaction, examples include, but are not limited to, a cinnamoyl group, a chalcone group, a coumarin group, an anthracene group, a quinoline group, an azobenzene group and a stilbene group. The benzene ring of these functional groups may contain a substituent. The substituent is not particularly limited, as long as it does not interfere with a photodimerization reaction. As the substituent, examples include, but are not limited to, an alkyl group, an aryl group, a cycloalkyl group, an alkoxy group, an aryloxy group, a hydroxy group, a halogen atom, a trifluoromethyl group and a cyano group.

The photo-alignment group that causes a photoisomerization reaction, is preferably a photo-alignment group that causes a cis-trans isomerization reaction, such as a cinnamoyl group, a chalcone group, an azobenzene group and a stilbene group. The benzene ring of these functional groups may contain a substituent. The substituent is not particularly limited, as long as it does not interfere with a photoisomerization reaction. As the substituent, examples include, but are not limited to, an alkoxy group, an alkyl group, a halogen atom, a trifluoromethyl group and a cyano group.

Of them, the photo-alignment group is preferably a cinnamoyl group. More specifically, the photo-alignment group is preferably at least one kind of cinnamoyl group selected from the group consisting of the following formulae (x-1) and (x-2).

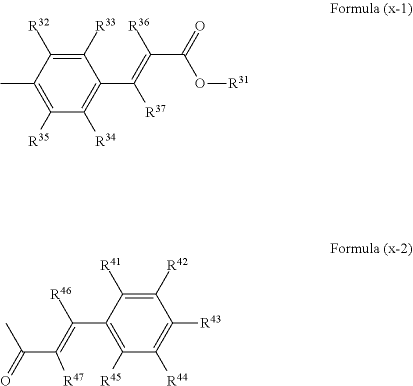

In the formula (x-1), R³¹ is a hydrogen atom, an alkyl group containing 1 to 18 carbon atoms, an aryl group containing 1 to 18 carbon atoms, or a cycloalkyl group containing 1 to 18 carbon atoms. However, the alkyl group, the aryl group and the cycloalkyl group may be bound via an ether bond, an ester bond, an amide bond or a urea bond and may contain a substituent. R³², R³³, R³⁴ and R³⁵ are each independently a hydrogen atom, a halogen atom, an alkyl group containing 1 to 18 carbon atoms, an aryl group containing 1 to 18 carbon atoms, a cycloalkyl group containing 1 to 18 carbon atoms, an alkoxy group containing 1 to 18 carbon atoms, or a cyano group. However, the alkyl group, the aryl group and the cycloalkyl group may be bound via an ether bond, an ester bond, an amide bond or a urea bond and may contain a substituent. R^{3′} and R³, are each independently a hydrogen atom, a halogen atom, an alkyl group containing 1 to 18 carbon atoms, an aryl group containing 1 to 18 carbon atoms, or an alkoxy group containing 1 to 18 carbon atoms.

In the formula (x-2), R⁴¹, R⁴², R⁴³, R⁴⁴ and R⁴⁵ are each independently a hydrogen atom, a halogen atom, an alkyl group containing 1 to 18 carbon atoms, an aryl containing 1 to 18 carbon atoms, a cycloalkyl group containing 1 to 18 carbon atoms, an alkoxy group containing 1 to 18 carbon atoms, or a cyano group. However, the alkyl group, the aryl group and the cycloalkyl group may be bound via an ether bond, an ester bond, an amide bond or a urea bond and may contain a substituent. R⁴⁶ and R⁴⁷ are each independently a hydrogen atom, a halogen atom, an alkyl group containing 1 to 18 carbon atoms, an aryl group containing 1 to 18 carbon atoms, or an alkoxy group containing 1 to 18 carbon atoms.

When the photo-alignment group is a cinnamoyl group and is a group represented by the formula (x-1), the benzene ring of the styrene skeleton (the formula (1-2) contained in the monomer unit may be the benzene ring of the cinnamoyl group.

The cinnamoyl group represented by the formula (x-1) is more preferably a group represented by the following formula (x-3):

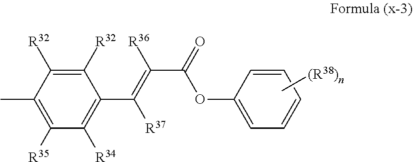

where R³² to R³⁷ are the same as those of the formula (x-1); R³⁸ is a hydrogen atom, an alkoxy group containing 1 to 18 carbon atoms, a cyano group an alkyl group containing 1 to 18 carbon atoms, a phenyl group, a biphenyl group or a cyclohexyl group (however, the alkyl group, the phenyl group, the biphenyl group and the cyclohexyl group may be bound via an ether bond, an ester bond, an amide bond or a urea bond); n is from 1 to 5; and R³⁸ may be bound to any of the ortho-, meta- and para-positions. When n is from 2 to 5, R³⁸s may be the same or different from each other. It is preferable that n is 1 and R³⁸ is bound to the para-position.

When the photo-alignment group is at least one kind of group selected from the group consisting of the groups represented by the formulae (x-3) and (x-2), aromatic rings are arranged near the terminals of the photo-alignment constitutional units, and many r electrons are contained. Accordingly, it is thought that affinity for the liquid crystal layer formed on the alignment layer increases; the liquid crystal aligning ability improves; and the adhesion to the liquid crystal layer increases.

As the monomer unit constituting the photo-alignment constitutional unit, examples include, but are not limited to, acrylic ester, methacrylic ester, styrene, acrylamide, methacrylamide, maleimide, vinyl ether and vinyl ester. Of them, acrylic ester, methacrylic ester and styrene are preferred from the viewpoint of raw material availability.

For example, the photo-alignment constitutional unit of the present disclosure may be a constitutional unit represented by the following formula (1):

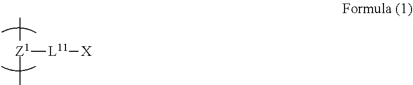

where Z¹ is at least one kind of monomer unit selected from the group consisting of the following formulae (I-1) to (I-6); X is a photo-alignment group; and L¹¹ is a single bond, —O—, —S—, —COO—, —COS—, —CO—, —OCO—, an alkylene group, an arylene group, a cycloalkylene group or any combination thereof,

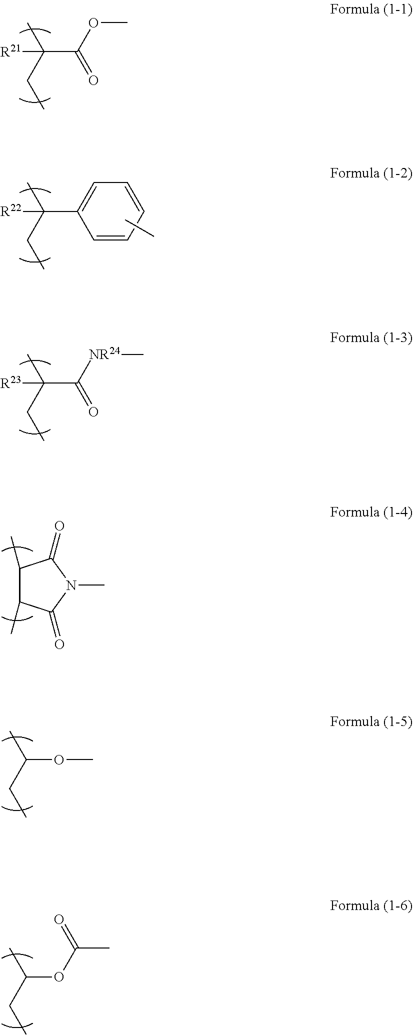

where R²¹ is a hydrogen atom, a methyl group, a chlorine atom or a phenyl group; R²² is a hydrogen atom or a methyl group; R²³ is a hydrogen atom, a methyl group, a chlorine atom or a phenyl group; and R²⁴ is a hydrogen atom or an alkyl group containing 1 to 4 carbon atoms).

As the monomer unit constituting the photo-alignment constitutional unit, examples include at least one kind selected from the group consisting of the formulae (1-1) to (1-6). When Z¹ is at least one kind selected from the group consisting of constitutional units represented by the formula (1-2), -L¹¹-X may be bound to any of the ortho-, meta- and para-positions. Of them, -L¹¹-X is preferably bound to the para-position, since the distance between the photo-alignment groups decreases with ease, and the photo-alignment property is easily obtained.

As the monomer unit constituting the photo-alignment constitutional unit, from the viewpoint of raw material availability, at least one kind selected from the group consisting of constitutional units represented by the formulae (1-1) and (1-2) is preferred. The monomer unit constituting the photo-alignment constitutional unit is more preferably at least one kind selected from the group consisting of constitutional units represented by the formula (1-2), and since the rigidity of the photo-alignment constitutional unit of the copolymer (B) increases, the distance between the photo-alignment groups decreases with ease, and the excellent photo-alignment property is easily obtained. When the copolymer contains a styrene skeleton and thereby contains many n-electron systems, due to the interaction of the n-electron systems, the adhesion of the alignment layer-cum-retardation layer formed from the photo-alignment thermosetting liquid crystal composition of the present disclosure to the liquid crystal material directly stacked on the alignment layer-cum-retardation layer, is thought to increase.

In the formula (1), X is a photo-alignment group and may be the same as described above. It may be, for example, at least one kind selected from the group consisting of a cinnamoyl group, a chalcone group, a coumarin group, an anthracene group, a quinoline group, an azobenzene group and a stilbene group. The benzene ring of these functional groups may contain a substituent. The substituent is not particularly limited, as long as it does not interfere with a photodimerization reaction or a photoisomerization reaction. As the substituent, examples include, but are not limited to, an alkyl group, an aryl group, a cycloalkyl group, an alkoxy group, a hydroxy group, a halogen atom, a trifluoromethyl group and a cyano group.

Of them, the photo-alignment group is preferably a cinnamoyl group. More specifically, the photo-alignment group is preferably a group represented by the formula (x-1) or (x-2).

L¹¹ is a single bond, —O—, —S—, —COO—, —COS—, —CO—, —OCO—, an alkylene group, an arylene group, a cycloalkylene group or any combination thereof, and L¹¹ binds the monomer unit to the photo-alignment group X.

When L¹¹ is a single bond, the photo-alignment group X is directly bound to a monomer unit Z¹. As the divalent linking group, examples include, but are not limited to, —O—, —S—, —COO—, —COS—, —CO—, —OCO—, —(CH₂)ₙ—, —(CH₂CH₂O)ₘ—, —C₆H₄—, —C₆H₁₀—, —(CH₂)ₙO—, —(CH₂CH₂O)ₘO—, —C₆H₄O—, —CH₁₀O—, —O(CH₂)ₙO—, —O(CH₂CH₂O)ₘO—, —OC₆H₄O—, —OC₆H₁₀O—, —OCO(CH₂)ₙCOO—, —OCO(CH₂CH₂O)ₘCOO—, —OCOC₆H₄O—, —OCOC₆H₁₀O—, —COO(CH₂)ₙO—, —COO(CH₂CH₂O)ₘ—, —COOC₆H₄O— and —COOC₆H₁₀O— (where —C₆H₄— is a phenylene group; —C₆H₁₀— is a cyclohexylene group; n is from 1 to 20; and m is from 1 to 10).

From the viewpoint of the photo-alignment property, the alkylene chain between the monomer unit and the photo-alignment group X is preferably short. Since the photo-alignment constitutional unit has the structure that the alkylene chain is short, it is estimated that the rigidity of the copolymer (B) increases; the distance between the photo-alignment groups decreases with ease; and the photo-alignment property (the liquid crystal aligning ability) improves.

From the viewpoint of the photo-alignment property, n and m are preferably small. More specifically, n is preferably from 1 to 6, and more preferably 1 to 4, and m is preferably from 1 to 3, and more preferably 1 to 2.

From the viewpoint of the photo-alignment property, the photo-alignment constitutional unit preferably has the structure such that the photo-alignment constitutional unit does not contain an alkylene chain between the photo-alignment group and the main chain of the copolymer (B), and L¹¹ is more preferably a single bond, —O—, —S—, —COO—, —COS—, —CO—, —OCO— or a combination of any of them with an arylene group.

The copolymer (B) may contain one kind of the photo-alignment constitutional unit or may contain two or more kinds of such photo-alignment constitutional units.

For the synthesis of the copolymer (B), monomers which contain a photo-alignment group and from which the photo-alignment constitutional unit is derived, can be used. The monomers containing a photo-alignment group may be used solely or in combination of two or more.

When the amount of the constitutional units contained in the whole copolymer (B) is 100% by mole, the content of the photo-alignment constitutional unit in the copolymer (B) is in a range of from 10% by mole to 90% by mole, and preferably in a range of from 20% by mole to 80% by mole. When the content of the photo-alignment constitutional unit is small, a decrease in sensitivity may be obtained, thereby making it difficult to provide a good liquid crystal aligning ability. On the other hand, when the content of the photo-alignment constitutional unit is large, the content of the thermally crosslinkable constitutional unit is relatively small. Accordingly, a sufficient thermosetting property may not be obtained, thereby making it difficult to maintain a good liquid crystal aligning ability.

### (2) Thermally Crosslinkable Constitutional Unit

In the present disclosure, the thermally crosslinkable constitutional unit of the copolymer (B) is a moiety that binds to the below-described thermal crosslinking agent by heating, and it contains a constitutional unit represented by the following formula (2):

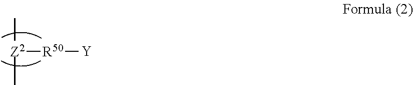

where Z² is at least one kind of monomer unit selected from the group consisting of the following formulae (2-1) to (2-6); R⁵⁰ is a linear alkylene group containing 4 to 11 carbon atoms and optionally containing —O— in its carbon chain; and Y is at least one kind of thermally crosslinkable group selected from the group consisting of a hydroxy group, a carboxy group, a mercapto group, a glycidyl group, an amino group and an amide group:

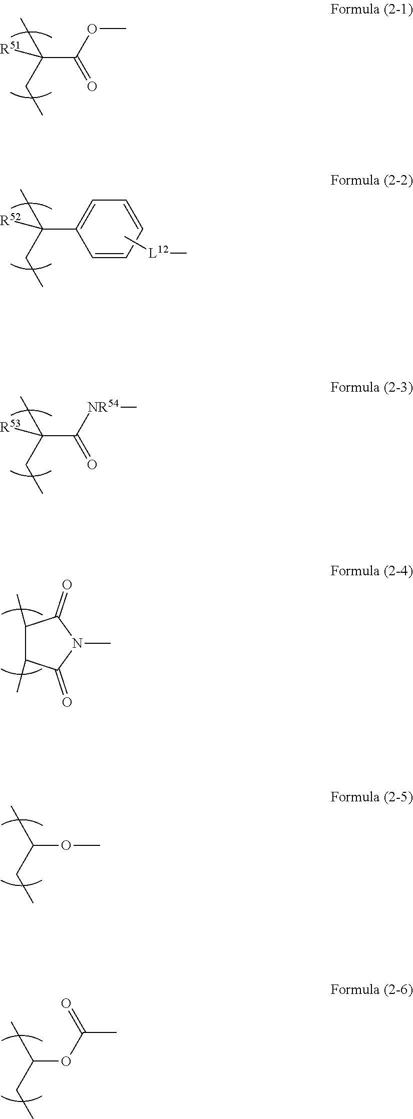

where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L¹² is a single bond, —O—, —S—, —COO—, —COS—, —CO— or —OCO—; and when L¹² is a single bond, R⁵⁰ is directly bound to a styrene skeleton.

In the general formula (2), the thermally crosslinkable group Y binds to the terminal of the linear alkylene group R⁵⁰ which contains 4 to 11 carbon atoms and which may contain —O— in a carbon chain. Accordingly, the carbon atom to which the thermally crosslinkable group binds, is a primary carbon and an increase in reactivity is obtained. From the viewpoint of reactivity, the thermally crosslinkable group is preferably a hydroxy group.

In the formula (2), L¹² is a single bond, —O—, —S—, —COO—, —COS—, —CO— or —OCO—. When L¹² is a single bond, the thermally crosslinkable group Y is directly bound to the monomer unit Z².

R⁵⁰ is a linear alkylene group containing 4 to 11 carbon atoms and optionally containing —O— in its carbon chain. As a result, in the thermally crosslinkable constitutional unit, the distance between the thermally crosslinkable group and the main skeleton of the copolymer appropriately increases. Accordingly, the thermal crosslinking agent is likely to bind to the thermally crosslinkable group; the reactivity between the thermally crosslinkable constitutional unit and the thermal crosslinking agent increases: and the curing speed of the copolymer (B) increases.

R⁵⁰ is preferably —(CH₂)ⱼ— or —(C₂H₄O)ₖ—C₂H₄— where j is from 4 to 11, and k is from 1 to 4. It is more preferable that j is from 6 to 11 and k is from 2 to 4. When j and k are too small, in the thermally crosslinkable constitutional unit, the distance between the thermally crosslinkable group and the main skeleton of the copolymer decreases. Accordingly, there is a possibility that the thermal crosslinking agent is less likely to bind to the thermally crosslinkable group, and the reactivity between the thermally crosslinkable constitutional unit and the thermal crosslinking agent decreases. On the other hand, when j and k are too large, the chain length of the linking group in the thermally crosslinkable constitutional unit increases. Accordingly, there is a possibility that the thermally crosslinkable group at the terminal is less likely to appear on the surface; the thermal crosslinking agent is less likely to bind to the thermally crosslinkable group; and the reactivity between the thermally crosslinkable constitutional unit and the thermal crosslinking agent decreases.

When Z² is at least one kind selected from the group consisting of constitutional units represented by the formula (2-2), -L¹²-R⁵⁰—Y may be bound to any of the ortho-, meta- and para-positions. Of them, -L¹²-R⁵⁰—Y is preferably bound to the para-position, from the viewpoint of excellent crosslinking reactivity.

As the monomer unit constituting the thermally crosslinkable constitutional unit, from the viewpoint of raw material availability, at least one kind selected from the group consisting of constitutional units represented by the formulae (2-1) and (2-2) is preferred.

The copolymer (B) may contain one kind of the thermally crosslinkable constitutional unit or may contain two or more kinds of such thermally crosslinkable constitutional units.

When the copolymer (B) contains two or more kinds of thermally crosslinkable constitutional units each containing the constitutional unit represented by the formula (2), among the linear alkylene groups each containing 4 to 11 carbon atoms and optionally containing —O— in its carbon chain, one having the largest carbon atom number is compared to all of the non-liquid crystal, thermally crosslinkable constitutional units of the side-chain liquid crystal polymer (A), and the side-chain liquid crystal polymer (A) may satisfy any of the (i) to (iv).

For the synthesis of the copolymer (B), monomers which contain a thermally crosslinkable group and from which the thermally crosslinkable constitutional unit is derived, can be used. The monomers containing a thermally crosslinkable group may be used solely or in combination of two or more.

When the amount of the constitutional units contained in the whole copolymer (B) is 100% by mole, the content of the thermally crosslinkable constitutional unit in the copolymer (B) is in a range of from 10% by mole to 90% by mole, and preferably in a range of from 20% by mole to 80% by mole. When the content of the thermally crosslinkable constitutional unit is small, a sufficient thermosetting property may not be obtained, thereby making it difficult to maintain a good liquid crystal aligning ability. On the other hand, when the content of the thermally crosslinkable constitutional unit is large, the content of the photo-alignment constitutional unit is relatively small. Accordingly, a decrease in sensitivity may be obtained, thereby making it difficult to provide a good liquid crystal aligning ability.

### (3) Different Constitutional Unit

In the present disclosure, the copolymer (B) may contain, besides the photo-alignment constitutional unit and the thermally crosslinkable constitutional unit, a different constitutional unit. When the copolymer (B) contains the different constitutional unit, the copolymer (B) can be heightened in, for example, solvent solubility, heat resistance and reactivity.

As the different constitutional unit, a self-crosslinkable constitutional unit containing a self-crosslinkable group capable of crosslinking between crosslinkable groups of the same type, may be contained. As the self-crosslinkable group, examples include, but are not limited to, a hydroxymethyl group, an alkoxymethyl group, a trialkoxysilyl group and a blocked isocyanate group.

In addition to the thermally crosslinkable constitutional unit, the copolymer (B) preferably further contains the self-crosslinkable constitutional unit, since the self-crosslinkable constitutional unit can also function as the thermal crosslinking agent, and the photo-alignment performance and the solvent resistance improve with ease.

When the copolymer (B) further contains the self-crosslinkable constitutional unit, the copolymer (B) easily reacts with the thermally crosslinkable constitutional unit in the molecules. Accordingly, the thermal crosslinking of the copolymer (B) easily proceeds. On the other hand, the thermal crosslinking of the side-chain liquid crystal polymer (A) is less likely to proceed. Accordingly, it is effective in promoting the thermal curing of the copolymer (B) (a material for the photo-alignment film) in the composition and in inhibiting the thermal curing of the side-chain liquid crystal polymer (A) having the homeotropic alignment property.

As the monomers containing a self-crosslinkable group, examples include, but are not limited to, acrylamide compounds or methacrylamide compounds substituted with a hydroxymethyl group or an alkoxymethyl group, such as N-hydroxymethylacrylamide, N-hydroxymethylmethacrylamide, N-methoxymethylacrylamide, N-methoxymethylmethacrylamide, N-ethoxymethylacrylamide, N-ethoxymethylmethacrylamide, N-butoxymethylacrylamide and N-butoxymethylmethacrylamide; monomers containing a trialkoxysilyl group, such as 3-trimethoxysilylpropyl acrylate, 3-triethoxysilylpropyl acrylate, 3-trimethoxysilylpropyl methacrylate and 3-triethoxysilylpropyl methacrylate; and monomers containing a blocked isocyanate group, such as 2-(0-(1′-methylpropylideneamino)carboxyamino)ethyl methacrylate and 2-(3,5-dimethylpyrazolyl)carbonylamino ethyl methacrylate.

As the monomer unit constituting the constitutional unit which does not contain a photo-alignment group and a thermally crosslinkable group, examples include, but are not limited to, acrylic ester, methacrylic ester, maleimide, acrylamide, acrylonitrile, maleic anhydride, styrene and vinyl. As with the thermally crosslinkable constitutional unit described above, preferred are acrylic ester, methacrylic ester and styrene.

Such monomers for forming the constitutional unit which does not contain a photo-alignment group and a thermally crosslinkable group include, for example, an acrylic ester compound, a methacrylic ester compound, a maleimide compound, an acrylamide compound, an acrylonitrile, maleic anhydride, a styrene compound and a vinyl compound. More specifically, among the monomers described in Paragraphs 0036 to 0040 in International Publication No. WO2010/150748, monomers which does not contain any of a photo-alignment group and a thermally crosslinkable group, may be used.

Also, another constitutional unit such as a constitutional unit derived from a monomer containing a fluorinated alkyl group, may be contained. In this case, the copolymer (B) localizes on the surface of the coating film with ease, and the photo-alignment group is easily aligned on the surface of the coating film. From the viewpoint of localizing the copolymer (B) on the surface of the coating film with ease, the fluorinated alkyl group of the fluorinated alkyl group-containing monomer may be a fluorinated alkyl group in which the number of carbon atoms to which a fluorine atom is directly bound, is from 2 to 8.

The copolymer may contain one kind of the constitutional unit or may contain two or more kinds of such constitutional units.

When the amount of the constitutional units contained in the whole copolymer (B) is 100% by mole, the content of the different constitutional unit in the copolymer (B) is preferably in a range of from 0% by mole to 50% by mole, and more preferably in a range of from 0% by mole to 30% by mole. When the content of the different constitutional unit is large, the content of the photo-alignment constitutional unit and the thermally crosslinkable constitutional unit is relatively small. Accordingly, a decrease in sensitivity may be obtained, thereby making it difficult to provide a good liquid crystal aligning ability; moreover, a sufficient thermosetting property may not be obtained, thereby making it difficult to maintain a good liquid crystal aligning ability.

### (4) Copolymer (B)

The mass average molecular weight of the copolymer (B) is not particularly limited, and it may be from about 3,000 to 200,000, and preferably in a range of from 4,000 to 100,000. When the mass average molecular weight is too large, there is a possibility that a decrease in solubility in solvents or an increase in viscosity occurs and causes poor handleability and difficulty in forming a uniform film. When the mass average molecular weight is too small, there is a possibility that insufficient curing occurs during thermal curing, and a reduction in solvent resistance or heat resistance occurs.

The mass average molecular weight can be measured by gel permeation chromatography (GPC).

As the method for synthesizing the copolymer (B), examples include, but are not limited to, copolymerization of a monomer which contains a photo-alignment group and a monomer which contains a thermally crosslinkable group, by a conventional production method.

The copolymer (B) may be used in any of the following forms: the form of a solution in synthesizing the copolymer, the form of a powder, and the form of a solution obtained by re-dissolving a refined powder in a solvent described below.

As the copolymer (B), one kind of the copolymer may be used solely, or two or more kinds of such copolymers may be used in combination. From the viewpoint of exhibiting aligning ability with respect to the directly stacked liquid crystal material, with respect to 100 parts by mass of the solid content of the liquid crystal composition, the content of the copolymer (B) is preferably from 1 part by mass to 50 parts by mass, more preferably from 5 parts by mass to 40 parts by mass, still more preferably from 10 parts by mass to 25 parts by mass.

### 3. Thermal Crosslinking Agent

The photo-alignment thermosetting liquid crystal composition of the present disclosure contains the thermal crosslinking agent for bonding to the thermally crosslinkable group of the thermally crosslinkable constitutional unit.

The thermal crosslinking agent (C) in the second photo-alignment thermosetting liquid crystal composition of the present disclosure will not be described here, since it may be the same as the thermal crosslinking agent (C) of the first photo-alignment thermosetting liquid crystal composition.

In the second photo-alignment thermosetting liquid crystal composition of the present disclosure, a decrease in the homeotropic alignment property can be suppressed by appropriately controlling the content of the thermal crosslinking agent (C) according to the structure of the thermally crosslinkable constitutional unit of the side-chain liquid crystal polymer (A).

The acid or acid generator, the solvent and other components in the second photo-alignment thermosetting liquid crystal composition of the present disclosure will not be described here, since they may be the same as those of the first photo-alignment thermosetting liquid crystal composition.

The production method and applications of the second photo-alignment thermosetting liquid crystal composition of the present disclosure, will not be described here since they may be the same as those of the first photo-alignment thermosetting liquid crystal composition.

### B. Alignment Film-Cum-Retardation Film

The second alignment film-cum-retardation film of the present disclosure is an alignment film-cum-retardation film comprising an alignment layer-cum-retardation layer, wherein the alignment layer-cum-retardation layer is a cured film of the second photo-alignment thermosetting liquid crystal composition of the present disclosure.

The second alignment film-cum-retardation film of the present disclosure will not be described here, since it may be the same as the first alignment film-cum-retardation film of the present disclosure, except for the photo-alignment thermosetting liquid crystal composition used.

### C. Method for Producing an Alignment Film-Cum-Retardation Film

The method for producing the second alignment film-cum-retardation film of the present disclosure comprises:
forming the second photo-alignment thermosetting liquid crystal composition of the present disclosure into a film,
forming a cured film having retardation by heating the thermosetting liquid crystal composition formed into the film, and
providing a liquid crystal aligning ability to the cured film having retardation by irradiating the cured film with polarized ultraviolet light.

The method for producing the second alignment film-cum-retardation film of the present disclosure will not be described here, since it may be the same as the method for producing the first alignment film-cum-retardation film of the present disclosure, except for the photo-alignment thermosetting liquid crystal composition used.

### D. Retardation Plate

The second retardation plate of the present disclosure is a retardation plate comprising a first retardation layer and a second retardation layer,
wherein the first retardation layer is a cured film of the second photo-alignment thermosetting liquid crystal composition of the present disclosure, and
wherein the second retardation layer is located directly adjacent to the first retardation layer and contains a cured product of a polymerizable liquid crystal composition.

The second retardation plate of the present disclosure and the method for producing the second retardation plate will not be described here, since they may be the same as the first retardation plate of the present disclosure and the method for producing the first retardation plate, except for the photo-alignment thermosetting liquid crystal composition used.

### III. The Third Embodiment

The present disclosure provides the third retardation plate comprising a positive C type retardation layer and a positive A type retardation layer,
wherein the positive C type retardation layer is a cured product of a thermosetting resin composition containing a photo-alignment component and a thermal crosslinking agent, and
wherein the positive A type retardation layer is located directly adjacent to the positive C type retardation layer and contains a cured product of a polymerizable liquid crystal composition.

FIG. 5 is a schematic sectional view of an example of the third retardation plate of the present disclosure. In the retardation plate 30 shown in FIG. 5, a positive C type retardation layer 21 is formed on a substrate 23, and the positive C type retardation layer 21 and a positive A type retardation layer 22 are directly stacked.

In the third retardation plate 30 of the present disclosure, the positive C type retardation layer 21 is a cured product of a thermosetting resin composition containing a photo-alignment component and a thermal crosslinking agent, and the positive C type retardation layer 21 and the positive A type retardation layer 22 are directly stacked. Accordingly, the positive C type retardation layer 21 also obtains a liquid crystal aligning ability. The positive C type retardation layer 21 is a cured product of a thermosetting resin composition containing a thermal crosslinking agent. Accordingly, the positive C type retardation layer 21 is less likely to be hard, has flexibility, and shows good adhesion to the directly stacked positive A type retardation layer, compared to the case where the positive C type retardation layer 21 is a cured product of a photocurable resin composition containing a polymerizable liquid crystal compound. In the case of the positive C type retardation layer of the thermosetting resin composition of the present disclosure containing the thermal crosslinking agent, compared to the case where the positive C type retardation layer is a cured product of a photocurable resin composition containing a polymerizable liquid crystal compound, a permeation region which is appropriate to the extent that does not inhibit the homeotropic alignment property of the positive C type retardation layer, is likely to be formed at the interface with the directly stacked positive A type retardation layer. Accordingly, the adhesion of the positive C type retardation layer of the thermosetting resin composition of the present disclosure containing the thermal crosslinking agent, improves with ease.

In the third retardation plate of the present disclosure, the positive C type retardation layer and the positive A type retardation layer are directly stacked in good adhesion, and the use of a conventional adhesive layer is not necessary to attach them together. Accordingly, the thickness of the third retardation plate of the present disclosure can be reduced. In the third retardation plate of the present disclosure, the positive C type retardation layer and the positive A type retardation layer are directly stacked in good adhesion; the thickness thereof can be reduced; and the positive C type retardation layer has flexibility. Accordingly, the third retardation plate of the present disclosure can be a retardation plate having good flex resistance.

In an embodiment of the third retardation plate 30 shown in FIG. 5, the substrate 23 and the positive C type retardation layer 21 are directly stacked. The third retardation plate shown in FIG. 5 may be provided with a means to exhibit an alignment-regulating force on the positive C type retardation layer 21-side surface of the substrate 23. In an embodiment of the third retardation plate, the substrate, an alignment film and the positive C type retardation layer may be stacked in this order. The substrate and the alignment film will not be described here, since they may be the same as those described above under “B. Alignment film-cum-retardation film”.

In the third retardation plate of the present disclosure, from the viewpoint of improving productivity, it is preferable that the alignment film is not disposed between the substrate and the positive C type retardation layer. The third retardation plate of the present disclosure preferably includes a substrate which is located directly adjacent to the positive C type retardation layer.

The third retardation plate of the present disclosure may be free of the substrate by removing the substrate from the produced third retardation plate, from the point of view that the thickness of the produced third retardation plate can be reduced.

### 1. Positive C Type Retardation Layer

In the positive C type retardation layer which is a cured product of a thermosetting resin composition containing a photo-alignment component and a thermal crosslinking agent, as the photo-alignment component used in the positive C type retardation layer, examples include, but are not limited to, a compound or polymer containing a photo-alignment group. As the photo-alignment component, examples include, but are not limited to, a copolymer which contains a photo-alignment constitutional unit containing a photo-alignment group in a side chain and a thermally crosslinkable constitutional unit containing a thermally crosslinkable group in a side chain, and a compound containing a different photo-alignment group and a different thermally crosslinkable group from those of the copolymer. In the copolymer, the photo-alignment constitutional unit containing a photo-alignment group in a side chain may be the same as the photo-alignment constitutional unit of the copolymer (B) in the first or second photo-alignment thermosetting liquid crystal composition. Also in the copolymer, the thermally crosslinkable constitutional unit containing a thermally crosslinkable group in a side chain may be the same as the thermally crosslinkable constitutional unit of the copolymer (B). Other structures and properties of the copolymer may be the same as those of the copolymer (B).

As the compound containing a different photo-alignment group and a different thermally crosslinkable group from those of the copolymer, may be the same as the compound containing a different photo-alignment group and a different thermally crosslinkable group from these of the copolymer (B) in the first or second photo-alignment thermosetting liquid crystal composition.

In the positive C type retardation layer which is a cured product of a thermosetting resin composition containing a photo-alignment component and a thermal crosslinking agent, from the viewpoint of exerting the good homeotropic alignment property and the good liquid crystal aligning ability, the copolymer which contains a photo-alignment constitutional unit containing a photo-alignment group in a side chain and a thermally crosslinkable constitutional unit containing a thermally crosslinkable group in a side chain is preferably used as the photo-alignment component, or the copolymer (B) of the first or second photo-alignment thermosetting liquid crystal composition may be used.

In the positive C type retardation layer which is a cured product of a thermosetting resin composition containing a photo-alignment component and a thermal crosslinking agent, the thermal crosslinking agent used may be the same as the thermal crosslinking agent (C) of the first or second photo-alignment thermosetting liquid crystal composition.

Structures derived from the photo-alignment component and thermal crosslinking agent contained in the positive C type retardation layer can be analyzed by a method such as NMR, IR, GC-MS, XPS, TOF-SIMS and any combination thereof. For example, the chemical structure of the photo-alignment component and that of the thermal crosslinking agent can be analyzed by collecting a material from the positive C type retardation layer and analyzing the material by nuclear magnetic resonance spectroscopy (NMR). Also, a fragment derived from the photo-alignment group can be detected by time-of-flight secondary ion mass spectroscopy (TOF-SIMS). Also, the peaks of bonds and functional groups derived from the thermal crosslinking agent and the photo-alignment component can be verified by X-ray photoelectron spectroscopy (XPS), infrared spectroscopy (IR) or Raman spectroscopy. By comprehensive evaluation of the analysis results, the structures of the components contained in the positive C type retardation layer can be analyzed.

The thermosetting resin composition used in the positive C type retardation layer contains a liquid crystal component for exerting retardation. As the liquid crystal component, a side-chain liquid crystal polymer which contains a liquid crystal constitutional unit containing a liquid crystal moiety in a side chain is preferably used, from the point of view that the homeotropic alignment property can improve with ease even when mixed with the photo-alignment component, and flexibility can be provided with ease. The liquid crystal constitutional unit containing a liquid crystal moiety in a side chain in the side-chain liquid crystal polymer may be the same as the liquid crystal constitutional unit of the side-chain liquid crystal polymer (A) in the first or second photo-alignment thermosetting liquid crystal composition.

The side-chain liquid crystal polymer may contain or may be free of a non-liquid crystal constitutional unit containing an alkylene group in a side chain. The non-liquid crystal constitutional unit that may be contained in the side-chain liquid crystal polymer may be the same as the non-liquid crystal constitutional unit or other constitutional units of the side-chain liquid crystal polymer (A) in the first or second photo-alignment thermosetting liquid crystal composition. Other structures and properties of the side-chain liquid crystal polymer may be the same as those of the side-chain liquid crystal polymer (A).

The thermosetting resin composition used in the positive C type retardation layer may contain an acid or acid generator, a solvent and other components. The acid or acid generator, the solvent and other components may be the same as those of the first photo-alignment thermosetting liquid crystal composition.

The positive C type retardation layer may have a structure such that a single layer contains the homeotropically aligned side-chain liquid crystal polymer, the photodimerization or photoisomerization structure of the photo-alignment group, and the crosslinked structure formed by binding of the thermal crosslinking agent to the thermally crosslinkable group. Also, the positive C type retardation layer may have a structure such that a single layer contains the homeotropically aligned side-chain liquid crystal polymer, and the copolymer which has the photodimerization or photoisomerization structure of the photo-alignment group of the photo-alignment constitutional unit and which has the crosslinked structure formed by binding of the thermal crosslinking agent to the thermally crosslinkable group of the thermally crosslinkable constitutional unit.

The above-described structures contained in the positive C type retardation layer, that is, the photodimerization or photoisomerization structure of the photo-alignment group and the crosslinked structure formed by binding of the thermal crosslinking agent to the thermally crosslinkable group, may be the same as those of the alignment layer-cum-retardation layer described above under “B. Alignment film-cum-retardation film”.

In the third retardation plate of the present disclosure, from the viewpoint of obtaining a retardation plate which has good flex resistance, it is preferable to control the composite modulus of the positive C type retardation layer. The composite modulus of the positive C type retardation layer may be 4.5 GPa or more and 9.0 GPa or less, may be 5.0 GPa or more and 8.5 GPa or less, or may be 5.0 GPa or more and 8.0 GPa or less. Since the positive C type retardation layer is a cured product of a thermosetting resin composition, the composite modulus can be easily controlled.

The composite modulus of the positive C type retardation layer is defined as Er which is calculated by the following equation (1) using a projected contact area Aₚ that is obtained in the measurement of an indentation hardness (H_{IT}) of the surface of the positive C type retardation layer. The “indentation hardness” is a value obtained from a load-displacement curve from the application to removal of the load of an indenter, which is obtained by the measurement of hardness by the nanoindentation method. The composite modulus of the positive C type retardation layer is a modulus containing the elastic deformation of the positive C type retardation layer and the elastic deformation of the indenter.

The composite modulus of the positive C type retardation layer is measured on a surface of the positive C type retardation layer, which is opposite to the interface with the positive A type retardation layer. In particular, the composite modulus of the positive C type retardation layer can be obtained by the method for obtaining the composite modulus described below under “Examples”.

$${E}_{r} = \frac{S \sqrt{π}}{2 \sqrt{{A}_{p}}} \qquad ( 1 )$$

(where Ap is the projected contact surface area; Er is the composite modulus of the alignment film-cum-retardation layer; and S is contact rigidity.)

In the third retardation plate of the present disclosure, the positive C type retardation layer may contain a region which is permeated with a specific component contained in the positive A type retardation layer described below. The specific component may contain a polymerizable liquid crystal compound or a cured product thereof.

The presence of the permeated region and the specific component can be analyzed by the following process.

First, the third retardation plate of the present disclosure is measured by time-of-flight secondary ion mass spectrometry (TOF-SIMS) while etching the third retardation plate in the thickness direction from the positive A type retardation layer surface with a gas cluster ion beam (Ar-GCIB) gun. Then, the thickness direction distribution of the fragment ions derived from the component of the polymerizable liquid crystal compound contained in the positive A type retardation layer described below and that of the fragment ions derived from the photo-alignment component contained in the positive C type retardation layer, are analyzed. The permeated region can be measured as a part where both the fragment ions derived from the component of the polymerizable liquid crystal compound and the fragment ions derived from the photo-alignment component are detected.

The thickness of the permeated region can be roughly estimated from the proportion of the permeated region in the thickness direction distribution of the fragment ions of each kind in TOF-SIMS, by comparing to the thickness measured by use of a scanning transmission electron microscope (STEM).

The thickness of the positive C type retardation layer may be appropriately set in accordance with the intended application thereof. In particular, the thickness is preferably from 0.1 μm to 5 μm, and more preferably from 0.5 μm to 3 μm.

### 2. Positive A Type Retardation Layer

The positive A type retardation layer of the third retardation plate of the present disclosure contains a cured product of a polymerizable liquid crystal composition.

The positive A type retardation layer of the third retardation plate of the present disclosure may be the same as the second retardation layer of the first or second retardation plate.

### 3. Retardation Plate

In the third retardation plate of the present disclosure, a thickness direction retardation Rth at a wavelength of 550 nm may be from −35 nm to 35 nm; an in-plane retardation Re at a wavelength of 550 nm may be 100 nm or more; and a total thickness of the positive C type retardation layer and the positive A type retardation layer may be from 0.2 μm to 6 μm.

The thickness direction retardation Rth at a wavelength of 550 nm may be from −30 nm to 30 nm, or it may be from −25 nm to 25 nm.

The in-plane retardation Re at a wavelength of 550 nm may be 120 nm or more, or it may be 135 nm or more.

The thickness direction retardation Rth at a wavelength of 550 nm and the in-plane retardation Re can be obtained by the methods described below under “Examples”.

The total thickness of the positive C type retardation layer and the positive A type retardation layer may be from 0.8 μm to 5 μm, or it may be from 1 μm to 4 μm.

The total thickness of the positive C type retardation layer and the positive A type retardation layer can be obtained by a scanning transmission electron microscope (STEM) described below under “Examples”.

### 4. Method for Producing the Retardation Plate

The method for producing the third retardation plate is not particularly limited, as long as the third retardation plate can be provided.

The method for forming the third retardation plate may include the following steps, for example:
forming, into a film, a photo-alignment thermosetting liquid crystal composition comprising:
a side-chain liquid crystal polymer which contains a liquid crystal constitutional unit containing a liquid crystal moiety in a side chain,
a copolymer which contains a photo-alignment constitutional unit and a thermally crosslinkable constitutional unit containing a thermally crosslinkable group in a side chain, and
a thermal crosslinking agent for bonding to the thermally crosslinkable group of the thermally crosslinkable constitutional unit,
forming a cured film having retardation by heating the thermosetting liquid crystal composition formed into the film,
forming a positive C type retardation layer provided with a liquid crystal aligning ability by irradiating the cured film having retardation with polarized ultraviolet light,
aligning liquid crystal molecules by the positive C type retardation layer, by forming a coating film of a polymerizable liquid crystal composition by applying the polymerizable liquid crystal composition onto the positive C type retardation layer and heating the coating film to a phase transition temperature of the polymerizable liquid crystal composition, and
forming a positive A type retardation layer by curing the coating film of the polymerizable liquid crystal composition, in which the liquid crystal molecules are aligned, by light irradiation.

The components of the photo-alignment thermosetting liquid crystal composition may be the same as the components of the third retardation plate described above.

The steps of the method for producing the third retardation plate may be carried out in the same manner as and in reference to the method for producing the first or second retardation plate.

Next, the optical member using the first, second or third retardation plate of the present disclosure, the method for producing the optical member using the first, second or third retardation plate of the present disclosure, and the display device using the first, second or third retardation plate of the present disclosure, will be described.

### E. Optical Member

In the present disclosure, there is provided an optical member comprising the first, second or third retardation plate and a polarizing plate.

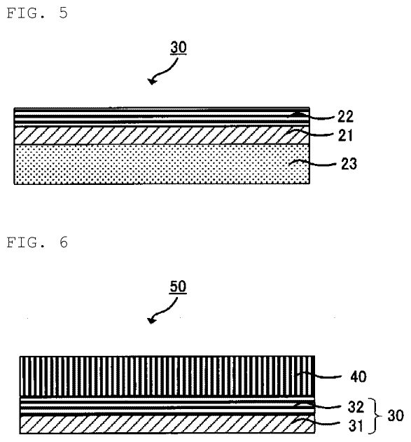

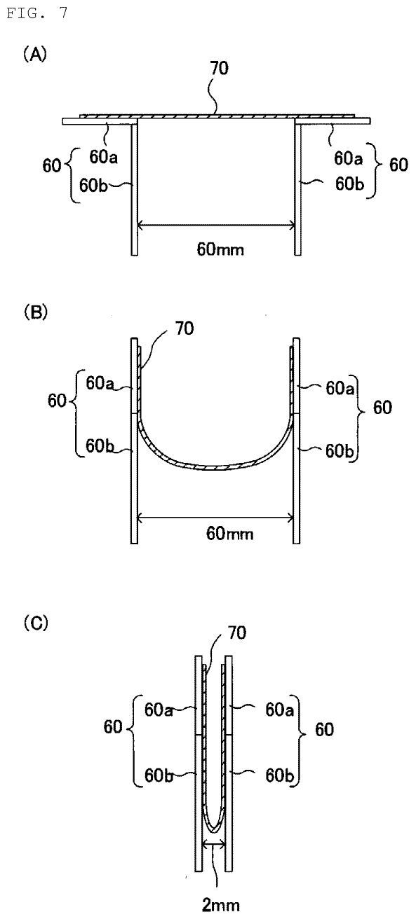

The optical member of the present disclosure will be described in reference to FIG. 6. FIG. 6 is a schematic sectional view of an embodiment of the optical member.

In the example shown in FIG. 6, an optical member 50 includes a retardation plate 30 (the retardation plate of the present disclosure) and a polarizing plate 40 located adjacent to the retardation plate. As needed, a pressure-sensitive adhesive layer (an adhesive layer) (not shown) may be disposed between the retardation plate 30 and the polarizing plate 40. As the retardation plate 30 of the present disclosure, the first, second or third retardation plate may be used.

In the optical member 50 shown in FIG. 6, the polarizing plate 40 is disposed on the retardation plate 30 which is formed by directly stacking a first retardation layer 31 and a second retardation layer 32 of the present disclosure. The first retardation layer 31 and the second retardation layer 32 may be the positive C type retardation layer and the positive A type retardation layer, respectively.

In the present embodiment, the first, second or third retardation plate of the present disclosure will not be described here, since it may be the same as the first, second or third retardation plate described above.

In the present embodiment, the polarizing plate is a plate which allows only light vibrating in a certain direction to pass through, and it can be appropriately selected from conventionally known polarizing plates. In the present embodiment, the polarizing plate may be a linear polarizing plate.

As the linear polarizing plate, examples include, but are not limited to, a polarizing plate comprising a polarizer and a polarizer protection layer disposed on at least one surface of the polarizer.

As the polarizer, examples include, but are not limited to, a stretched film or layer to which a pigment having absorption anisotropy is adsorbed, and a film formed by applying a pigment having absorption anisotropy and drying the applied pigment. As the pigment having absorption anisotropy, examples include, but are not limited to, a dichroic pigment. As the dichroic pigment, examples include, but are not limited to, iodine and a dichroic organic dye.

As the stretched film to which the pigment having absorption anisotropy is adsorbed, examples include, but are not limited to, a polyvinyl alcohol film, a polyvinyl formal film, a polyvinyl acetal film and an ethylene-vinyl acetate copolymer-based saponified film, each of which is dyed with iodine or a dye and stretched.

The linear polarizing plate may be used in reference to Paragraphs 0025 to 0059 of JP-A No. 2021-51287, for example. The thickness of the polarizing plate is 2 μm or more and 100 μm or less, for example. It is preferably 10 μm or more and 60 μm or less.

In the present embodiment, a pressure-sensitive adhesive (an adhesive) for the pressure-sensitive adhesive layer (the adhesive layer) may be appropriately selected from conventionally known adhesives. As the pressure-sensitive adhesive (the adhesive), any kind of adhesive such as a pressure-sensitive adhesive, a two-component curable adhesive, an ultraviolet curable adhesive, a thermosetting adhesive and a thermofusible adhesive, is preferably used. From the viewpoint of transparency, weather resistance, heat resistance and so on, the pressure-sensitive adhesive for the pressure-sensitive adhesive layer is preferably a pressure-sensitive adhesive composition using a (meth)acrylic resin as a base polymer.

The thickness of the pressure-sensitive adhesive layer (the adhesive layer) is determined depending on its adhesion and so on. For example, it may be from 1 μm to 50 μm, preferably from 2 μm to 45 μm, more preferably from 3 μm to 40 μm, and still more preferably from 5 μm to 35 μm.

In addition to the polarizing plate, the optical member of the present embodiment may further include other layers that conventionally-known optical members have. As such layers, examples include, but are not limited to, a retardation layer different from the retardation layer of the present disclosure, an antireflection layer, a diffusion layer, an antiglare layer, an antistatic layer and a protection film.

The optical member of the present disclosure is preferably used as a circularly polarizing plate, for example. The optical member of the present disclosure is preferably used as an optical member for suppressing external light reflection in light-emitting display devices, for example.

### F. Method for Producing an Optical Member

In the present disclosure, there is provided a method for producing an optical member, the method comprising:
preparing a polarizing plate,
preparing the first, second or third retardation plate, and
stacking the retardation plate and the polarizing plate.

In the optical member production method of the present disclosure, the order of the steps may be any order.

For example, the first, second or third retardation plate may be prepared by carrying out the steps of preparing a polarizing plate and forming the first, second or third retardation plate on the polarizing plate. In this case, the step of stacking the retardation plate and the polarizing plate proceeds simultaneously with the step of preparing the retardation plate.

### 1. Step of Preparing the Polarizing Plate

As the step of preparing the polarizing plate, examples include, but are not limited to, the case of using a stretched film to which a pigment having absorption anisotropy is adsorbed, as a polarizer. In general, a stretched film to which a pigment having absorption anisotropy is adsorbed can be produced by the steps of uniaxially stretching a polyvinyl alcohol resin film, dyeing the polyvinyl alcohol resin film with a dichroic pigment to adsorb the dichroic pigment to the resin film, treating the polyvinyl alcohol resin film to which the dichroic pigment is adsorbed, with a boric acid aqueous solution, and then washing the resin film with water after the treatment. A polarizer protection layer is attached to one or both surfaces of the obtained polarizer, and the resulting product can be prepared as the polarizing plate.

The polarizing plate can be prepared in reference to Paragraphs 0025 to 0059 of JP-A No. 2021-51287, for example.

### 2. Step of Preparing the Retardation Plate

The step of preparing the first, second or third retardation plate is not particularly limited, as long as the first, second or third retardation plate can be prepared.

The step of preparing the first, second or third retardation plate can be carried out in the same manner as the above-described method for producing the first, second or third retardation plate, for example.

In the preparation of the retardation plate, the first and second retardation layers are preferably formed on a peelable substrate.

The peelable substrate can be appropriately selected and used so that it is peelable. The substrate may be a surface-treated substrate; it may be a substrate subjected to a release treatment; or it may be a substrate on which a release layer is formed.

### 3. Step of Stacking the Retardation Plate and the Polarizing Plate

In the step of stacking the retardation plate and the polarizing plate, the retardation plate and the polarizing plate may be attached by the pressure-sensitive adhesive layer (the adhesive layer), or as described above, by directly forming the retardation plate on the polarizing plate, the retardation plate and the polarizing plate may be stacked at the same time as preparing the retardation plate.

As the pressure-sensitive adhesive layer (the adhesive layer), the same layer as described above may be used.

At the time of stacking the retardation plate and the polarizing plate, an angle between the slow axis of the positive A type retardation layer of the retardation layer and the absorption axis of the polarizing plate, is preferably 45°±5°.

When the retardation plate and the polarizing plate are attached by the pressure-sensitive adhesive layer (the adhesive layer) in the step of stacking the retardation plate and the polarizing plate, it is preferable to peel off the substrate from the retardation plate after the retardation plate and the polarizing plate are attached. By peeling off the substrate later from the retardation plate, the optical member made of the polarizing plate and, among the retardation plates of the present disclosure, only the first and second retardation layers, is obtained.

### G. Display Device

In the present disclosure, there is provided a display device comprising the first, second or third retardation plate or comprising an optical member comprising the first, second or third retardation plate and a polarizing plate.

As the display device, examples include, but are not limited to, a light-emitting display device and a liquid crystal display device. The display device may be a touch panel provided with a touch sensor. Also, the display device may be a flexible display device.

The display device of the present disclosure is preferably a light-emitting display device.

Especially, the light-emitting display device including the retardation plate or optical member of the present disclosure, such as an organic light-emitting display device including a transparent electrode layer, a light emitting layer and an electrode layer in this order, has the effect of improving a viewing angle while suppressing external light reflection.

The display device of the present disclosure is particularly preferably a flexible display device.

The retardation plate or optical member of the present disclosure enables thickness reduction and has good adhesion and flex resistance. Accordingly, a flexible display device including the retardation plate or optical member of the present disclosure has the effect of improving flex resistance. The flexible display device may be a foldable display device.

In the display device of the present disclosure, structures other than the retardation plate or optical member may be conventionally-known, appropriately-selected structures.

The present disclosure is not limited to the above-mentioned embodiments. The above-mentioned embodiments are examples, and any that has the substantially same essential features as the technical ideas described in the claims of the present disclosure and exerts the same effects and advantages as the embodiments is included in the technical scope of the present disclosure.

### EXAMPLES

The present disclosure will be described in more detail, with reference to the following examples and comparative examples.

### Example I Series: The First Embodiment of the Present Disclosure

### Synthesis Example 1: Synthesis of Liquid Crystal Monomer 1

In reference to Paragraphs 0121 to 0124 in International Publication No. WO2018/003498, 4′-cyano-4-{4-[2-(acryloyloxy)ethoxy]benzoate} (the following chemical formula (i-1)) was obtained.

### Synthesis Example 2: Synthesis of Liquid Crystal Monomer 2

A liquid crystal monomer 2 represented by the following chemical formula (i-2) was obtained in the same manner as Synthesis Example 1, except that 6-chloro-1-n-hexanol was used instead of 2-bromoethanol.

### Synthesis Example 3: Synthesis of Liquid Crystal Monomer 3

In reference to Paragraphs 0127 to 0130 in International Publication No. WO2018/003498, 4-[(4-propoxycarbonylphenyloxycarbonyl)phenyl-4-[6-(acryloyloxy)hexyloxy]benzoate (the following chemical formula (i-3)) was obtained.

TABLE 1

| | Chemical | |
|---|---|---|
| | Formula | Liquid crystal monomer |
| 1 | (i-1) | 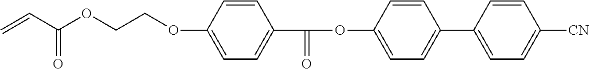 [SMILES: C=CC(=O)OCCOc1ccc(C(=O)Oc2ccc(-c3ccc(C#N)cc3)cc2)cc1] |
| 2 | (i-2) | 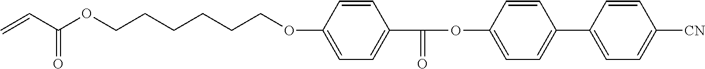 [SMILES: C=CC(=O)OCCCCCCOc1ccc(C(=O)Oc2ccc(-c3ccc(C#N)cc3)cc2)cc1] |
| 3 | (i-3) | 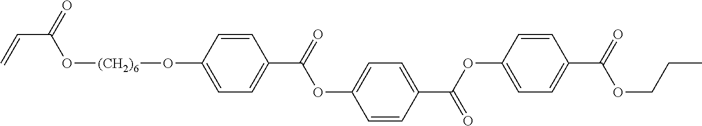 |

Stearyl acrylate (the following chemical formula (ii-1), manufactured by Tokyo Chemical Industry Co., Ltd.) was used as a non-liquid crystal monomer 1; hexyl acrylate (the following chemical formula (ii-2), manufactured by Tokyo Chemical Industry Co., Ltd.) was used as a non-liquid crystal monomer 2; and nonylphenoxypolyethylene glycol acrylate manufactured by Hitachi Chemical Co., Ltd. (the following chemical formula (ii-3)) was used as a non-liquid crystal monomer 3. The non-liquid crystal monomer 3 is a mixture where n′ of the following chemical formula (ii-3) is from 1 to 12; it contains at least a monomer where n′ is 8 and a monomer where n′ is 12; and the average of n′ is 8.

Also, 2-hydroxyethyl methacrylate (the following chemical formula (ii-4), manufactured by Kyoeisha Chemical Co., Ltd.) was used as a thermally crosslinkable group-containing non-liquid crystal monomer 4tc; 4-hydroxybutyl acrylate (the following chemical formula (ii-5), manufactured by Tokyo Chemical Industry Co., Ltd.) was used as a thermally crosslinkable group-containing non-liquid crystal monomer 5tc; and N-(methoxymethyl)methacrylamide (the following chemical formula (ii-8), manufactured by Tokyo Chemical Industry Co., Ltd.) was used as a thermally crosslinkable group-containing non-liquid crystal monomer 8tc.

### Synthesis Example 4: Synthesis of Thermally Crosslinkable Group-Containing Non-Liquid Crystal Monomer 6

A thermally crosslinkable group-containing non-liquid crystal monomer 6tc represented by the following chemical formula (ii-6) was synthesized in the same manner as the thermally crosslinkable monomer B8 of Synthesis Example 6 in JP Patent No. 5668881.

### Synthesis Example 5: Synthesis of Thermally Crosslinkable Group-Containing Non-Liquid Crystal Monomer 7

A thermally crosslinkable group-containing non-liquid crystal monomer 7tc represented by the following chemical formula (ii-7) was synthesized in the same manner as the thermally crosslinkable monomer B9 of Synthesis Example 7 in JP Patent No. 5668881.

TABLE 2

| | Chemical | |
|---|---|---|
| | Formula | Non-liquid crystal monomer |
| 1 | (ii-1) | 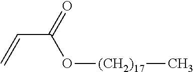 |
| 2 | (ii-2) | 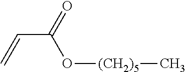 |
| 3 | (ii-3) | 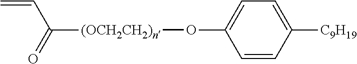 |
| | Chemical | Thermally crosslinkable group-containing |
| | Formula | non-liquid crystal monomer |
| 4tc | (ii-4) | 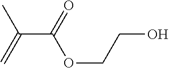 |
| 5tc | (ii-5) | 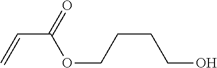 |
| 6tc | (ii-6) | 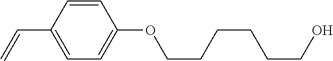 [SMILES: C=Cc1ccc(OCCCCCCO)cc1] |
| 7tc | (ii-7) | 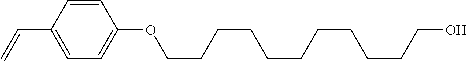 [SMILES: C=Cc1ccc(OCCCCCCCCCCCO)cc1] |
| 8tc | (ii-8) | 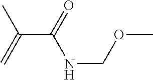 |

### Synthesis Example 6: Synthesis of Photo-Alignment Monomer 1

A photo-alignment monomer 1 represented by the following chemical formula (iii-1) was synthesized in the same manner as the photo-alignment monomer 3 of Synthesis Example 3 in JP Patent No. 5626492.

### Synthesis Example 7: Synthesis of Photo-Alignment Monomer 2

A photo-alignment monomer 2 represented by the following chemical formula (iii-2) was synthesized in the same manner as the photo-alignment monomer 1 of Synthesis Example 1 in JP Patent No. 5626492.

### Synthesis Example 8: Synthesis of Photo-Alignment Monomer 3

A photo-alignment monomer 3 represented by the following chemical formula (iii-3) was synthesized in the same manner as the photo-alignment monomer 8 of Synthesis Example 8 in JP Patent No. 5626492.

### Synthesis Example 9: Synthesis of Photo-Alignment Monomer 4

A photo-alignment monomer 4 represented by the following chemical formula (iii-4) was synthesized in the same manner as the photo-alignment monomer 9 of Synthesis Example 9 in JP Patent No. 5626492.

### Synthesis Example 10: Synthesis of Photo-Alignment Monomer 5

A photo-alignment monomer 5 represented by the following chemical formula (iii-5) was synthesized in the same manner as the photo-alignment monomer 4 of Synthesis Example 4 in JP Patent No. 5626492.

### Synthesis Example 11: Synthesis of Photo-Alignment Monomer 6

A suspension of 4′-hydroxychalcone (manufactured by Tokyo Chemical Industry Co., Ltd.) (20 g, 90 mmol), acryloyl chloride (7.4 g, 82 mmol) and dimethylaniline (DMA) (9.9 g, 82 mmol) in tetrahydrofuran (400 mL) was stirred for 12 hours. After a reaction was completed, water and ethyl acetate were added to the suspension for separation. The solvent was removed by distillation; a residue thus obtained, was purified by silica-gel chromatography; and the solvent was then removed by distillation, thereby synthesizing a photo-alignment monomer 6 represented by the following chemical formula (iii-6) in a yield of 89% (22 g, 80 mmol).

### Synthesis Example 12: Synthesis of Photo-Alignment Monomer 7

A photo-alignment monomer 7 represented by the following chemical formula (iii-7) was synthesized by condensation in the same manner as Synthesis Example a in JP Patent No. 5626492, except that an equimolar amount of 4-methoxycinnamic acid was used instead of 4-vinylbenzoic acid, and an equimolar amount of 4-hydroxyphenylmethacrylate (manufactured by Seiko Chemical Co., Ltd.) was used instead of ethylene glycol.

### Synthesis Example 13: Synthesis of Comparative Photo-Alignment Monomer 1

A comparative photo-alignment monomer 1 represented by the following chemical formula (iii-c1) was synthesized in the same manner as Synthesis Example 2 in JP Patent No. 5668881, except that an equimolar amount of methyl trans-4-hydroxycinnamate was used instead of methyl ferulate, and an equimolar amount of 6-chloro-1-hexanol was used instead of 4-chloro-1-butanol.

As a comparative photo-alignment monomer 2 represented by the following chemical formula (iii-c2), 4-(6-methacryloxyhexyl-1-oxy)cinnamic acid methyl ester was prepared.

### Synthesis Example 15: Synthesis of Comparative Photo-Alignment Monomer 3

A comparative photo-alignment monomer 3 represented by the following chemical formula (iii-c3) was synthesized in the same manner as the reference photo-alignment monomer 2 of Reference Synthesis Example 1 in JP Patent No. 5626492.

TABLE 3

| | Chemical | |
|---|---|---|
| | Formula | Photo-alignment monomer |
| 1 | (iii-1) | 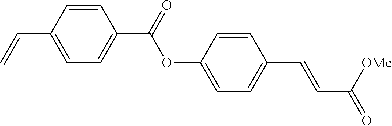 [SMILES: C=Cc1ccc(C(=O)Oc2ccc(/C=C/C(=O)OC)cc2)cc1] |
| 2 | (iii-2) | 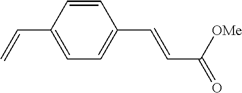 |
| 3 | (iii-3) | 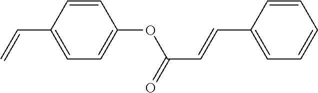 [SMILES: C=Cc1ccc(OC(=O)/C=C/c2ccccc2)cc1] |
| 4 | (iii-4) | 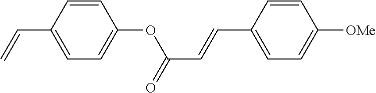 [SMILES: C=Cc1ccc(OC(=O)/C=C/c2ccc(OC)cc2)cc1] |
| 5 | (iii-5) | 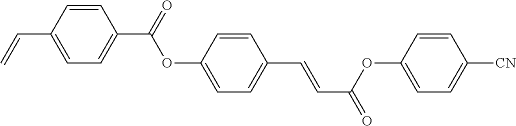 [SMILES: C=Cc1ccc(C(=O)Oc2ccc(/C=C/C(=O)Oc3ccc(C#N)cc3)cc2)cc1] |
| 6 | (iii-6) | 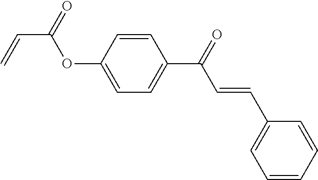 [SMILES: C=CC(=O)Oc1ccc(C(=O)/C=C/c2ccccc2)cc1] |
| 7 | (iii-7) | 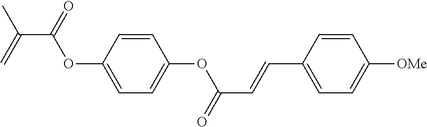 [SMILES: C=C(C)C(=O)Oc1ccc(OC(=O)/C=C/c2ccc(OC)cc2)cc1] |
| Comparative 1 | (iii-c1) | 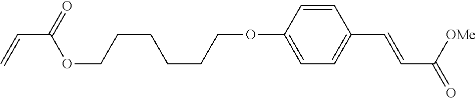 [SMILES: C=CC(=O)OCCCCCCOc1ccc(/C=C/C(=O)OC)cc1] |
| Comparative 2 | (iii-c2) | 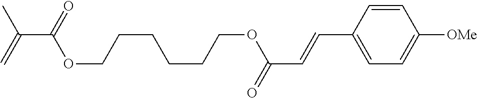 [SMILES: C=C(C)C(=O)OCCCCCCOC(=O)/C=C/c1ccc(OC)cc1] |
| Comparative 3 | (iii-c3) | 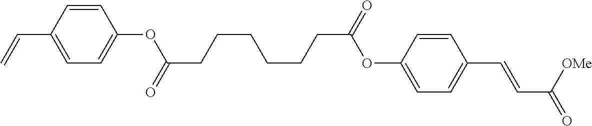 [SMILES: C=Cc1ccc(OC(=O)CCCCCCC(=O)Oc2ccc(/C=C/C(=O)OC)cc2)cc1] |

As a thermally crosslinkable monomer 1, 2-hydroxyethyl methacrylate (the following chemical formula (iv-1), manufactured by Kyoeisha Chemical Co., Ltd.) was used. As a thermally crosslinkable monomer 2, 4-hydroxybutyl acrylate (the following chemical formula (iv-2), manufactured by Tokyo Chemical Industry Co., Ltd.) was used.

### Synthesis Example 16: Synthesis of Thermally Crosslinkable Monomer 3

A thermally crosslinkable monomer 3 represented by the following chemical formula (iv-3) was synthesized in the same manner as the thermally crosslinkable monomer B3 of Synthesis Example 4 in JP Patent No. 5668881.

### Synthesis Example 17: Synthesis of Thermally Crosslinkable Monomer 4

A thermally crosslinkable monomer 4 represented by the following chemical formula (iv-4) was synthesized in the same manner as the thermally crosslinkable monomer 5 of Synthesis Example e in JP Patent No. 5626492.

### Synthesis Example 18: Synthesis of Thermally Crosslinkable Monomer 5

A thermally crosslinkable monomer 5 represented by the following chemical formula (iv-5) was synthesized in the same manner as the thermally crosslinkable monomer 6 of Synthesis Example f in JP Patent No. 5626492.

### Synthesis Example 19: Synthesis of Thermally Crosslinkable Monomer 6

A thermally crosslinkable monomer 6 represented by the following chemical formula (iv-6) was synthesized in the same manner as the compound 46 of Example 9 in Japanese translation of PCT International Application No. 2016-538400.

### Synthesis Example 20: Synthesis of Thermally Crosslinkable Monomer 7

A thermally crosslinkable monomer 7 represented by the following chemical formula (iv-7) was synthesized in the same manner as Paragraph 124 in Japanese translation of PCT International Application No. 2018-525444.

As third component monomers, N-(methoxymethyl)methacrylamide (the following chemical formula (iv-8), manufactured by Tokyo Chemical Industry Co., Ltd.), which is a self-crosslinkable group-containing thermally crosslinkable monomer 8, and VISCOAT 13F (the following chemical formula (v-1), manufactured by Osaka Organic Chemical Industry Ltd.), which is a fluorinated alkyl group-containing monomer 1, were used.

TABLE 4

| | Chemical | |
|---|---|---|
| | Formula | Thermally crosslinkable monomer |
| 1 | (iv-1) | 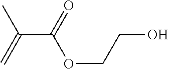 |
| 2 | (iv-2) | 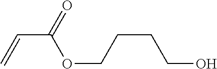 |
| 3 | (iv-3) | 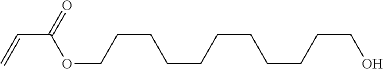 [SMILES: C=CC(=O)OCCCCCCCCCCCO] |
| 4 | (iv-4) | 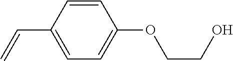 |
| 5 | (iv-5) | 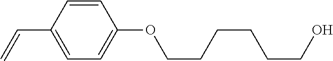 [SMILES: C=Cc1ccc(OCCCCCCO)cc1] |
| 6 | (iv-6) | 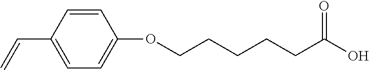 [SMILES: C=Cc1ccc(OCCCCCC(=O)O)cc1] |
| 7 | (iv-7) | 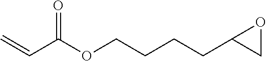 |
| 8 | (iv-8) | 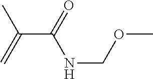 |
| | Chemical | |
| | Formula | Fluorinated alkyl group-containing monomer |
| 1 | (v-1) | 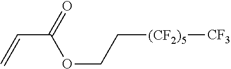 |

### Production Examples A1 to A14: Production of Side-Chain Liquid Crystal Polymers A1 to A14

Side-chain liquid crystal polymers were synthesized by combining the liquid crystal monomers 1 to 3, the non-liquid crystal monomers 1 to 3 and 4tc to 8tc and the photo-alignment monomer 1 according to Table 5.

An example of the synthesis of a side-chain liquid crystal polymer A2 will be described in detail.

The non-liquid crystal monomer 1 and the non-liquid crystal monomer 2 were mixed in a molar ratio of 50:50. The mixture of the non-liquid crystal monomers and the liquid crystal monomer 1 were combined in a molar ratio of 40:60 and mixed. N,N-dimethylacetamide (DMAc) was added thereto, and they were stirred at 40° C. to dissolve the monomers. After dissolving the monomers, the mixture was cooled to 24° C., and azobisisobutyronitrile (AIBN) was added thereto and dissolved at the same temperature. The reaction solution thus obtained was added in a dropwise manner over 30 minutes to DMAc heated to 80° C. After the addition was completed, the mixture was stirred for 6 hours at 80° C. After a reaction was completed, the reaction solution thus obtained was cooled to room temperature; the cooled solution was added in a dropwise manner to another container in which methanol was under stirring; and they were stirred for 20 minutes. Supernatant was removed therefrom; the slurry thus obtained was filtered to obtain a crude product; the crude product was stirred in methanol for 20 minutes again; and after removal of the supernatant, filtration was performed. The obtained crystals were dried, thereby obtaining the side-chain liquid crystal polymer A2 in a yield of 76.5%.

For the obtained side-chain liquid crystal polymer, the mass average molecular weight was measured, and the structure was analyzed. By Py-GC-MS or MALDI-TOFMS, it was confirmed that the liquid crystal polymer contained a constitutional unit derived from one kind of non-liquid crystal monomer used or constitutional units derived from two or three kinds of non-liquid crystal monomers used.

TABLE 5
Side-chain liquid crystal polymer (A)
Liquid crystal monomer:Non-liquid crystal monomer = 60:40 (molar ratio)

| | Liquid | | | | | Molecular |
|---|---|---|---|---|---|---|
| | crystal | Non-liquid crystal monomer | | | Molar ratio | weight |
| | monomer | a | b | c | a:b:c | Mw |
| A1 | 1 | 1 | | | 100:00:00 | 22000 |
| A2 | 1 | 1 | 2 | | 50:50:00 | 23500 |
| A3 | 1 | 1 | | 4tc | 50:00:50 | 31500 |
| A4 | 1 | 1 | 2 | 4tc | 25:25:50 | 25000 |
| A5 | 3 | 1 | | 4tc | 50:50:00 | 26000 |
| A6 | 2 | 1 | | 4tc | 50:00:50 | 28000 |
| A7 | 1 | 3 | | | 100:00:00 | 22500 |
| A8 | 1 | 3 | | 4tc | 50:00:50 | 25000 |
| A9 | 1 | 1 | | 5tc | 50:00:50 | 20000 |
| A10 | 1 | 1 | | 6tc | 50:00:50 | 21500 |
| A11 | 1 | 1 | | 7tc | 50:00:50 | 20000 |
| A12 | 1 | 1 | Photo-alignment | 4tc | 25:25:50 | 36500 |
| | | | monomer 1 | | | |
| A13 | 1 | 1 | | 4tc | 00:00:100 | 34000 |
| A14 | 1 | 1 | | 8tc | 50:00:50 | 22000 |

### Production Examples B1 to B15: Production of Copolymers B1 to B15

Copolymers (B) were synthesized by combining the photo-alignment monomers 1 to 7, the thermally crosslinkable monomers 1 to 7 and the third component monomer according to Table 6.

An example of the synthesis of a copolymer B1 will be described in detail.

First, 3.08 g of the photo-alignment monomer 1, 1.30 g of the thermally crosslinkable monomer 1 (hydroxybutyl methacrylate) and 50 mg of α,α′-azobisisobutyronitrile (AIBN) as a polymerization catalyst, were dissolved in 25 ml of dioxane, and 3.08 g of the photo-alignment monomer 1, 1.30 g of the thermally crosslinkable monomer 1 (hydroxybutyl methacrylate) and 50 mg of α,α′-azobisisobutyronitrile (AIBN) as a polymerization catalyst were reacted at 90° C. for 6 hours. After the reaction was completed, the reaction solution thus obtained was purified by reprecipitation, thereby obtaining a copolymer B1. The mass average molecular weight of the obtained copolymer B1 was 18000.

The mass average molecular weight (hereinafter, it will be simply referred to as Mw) of each of the synthesized copolymers was calculated by gel permeation chromatography (GPC) with HLC-8220 GPC manufactured by Tosoh Corporation, using polystyrene as a standard substance and NMP as an eluent.

### [Comparative Production Examples B′1 to B′3] Synthesis of Comparative Copolymers B′¹ to B′3

In the same manner as the copolymer B1, comparative copolymers B′1 to B′3 were synthesized by combining the comparative photo-alignment monomers 1 to 3 and the thermally crosslinkable monomer 1 according to Table 6.

TABLE 6
Copolymer (B)

| | | Thermally | | | |
|---|---|---|---|---|---|
| | Photo-alignment | crosslinkable | Third component | Molar | |
| | monomer | monomer | monomer | ratio | Mw |
| B1 | 1 | 1 | | 50:50:00 | 18000 |
| B2 | 2 | 1 | | 50:50:00 | 18500 |
| B3 | 3 | 1 | | 50:50:00 | 16500 |
| B4 | 4 | 1 | | 50:50:00 | 17000 |
| B5 | 5 | 1 | | 50:50:00 | 20000 |
| B6 | 6 | 1 | | 50:50:00 | 14000 |
| B7 | 7 | 1 | | 50:50:00 | 10000 |
| B8 | 1 | 2 | | 50:50:00 | 15000 |
| B9 | 1 | 3 | | 50:50:00 | 19000 |
| B10 | 1 | 4 | | 50:50:00 | 18000 |
| B11 | 1 | 5 | | 50:50:00 | 14500 |
| B12 | 1 | 6 | | 50:50:00 | 17000 |
| B13 | 1 | 7 | | 50:50:00 | 14000 |
| B14 | 1 | 1 | Fluorinated alkyl | 50:45:05 | 17500 |
| | | | group-containing | | |
| | | | monomer 1 | | |
| B15 | 1 | 1 | Self-crosslinkable | 50:30:20 | 15000 |
| | | | group-containing | | |
| | | | thermally | | |
| | | | crosslinkable | | |
| | | | monomer 8 | | |
| B′1 | Comparative 1 | 1 | | 50:50:00 | 13500 |
| B′2 | Comparative 2 | 1 | | 50:50:00 | 11000 |
| B′3 | Comparative 3 | 1 | | 50:50:00 | 11500 |

### [Comparative Production Example C1] Synthesis of Comparative Copolymer C1

In the same manner as the polymer 1 described in Paragraphs 0073 to 0076 and 0079 in JP-A No. 2016-004142, a comparative copolymer C1 was obtained by copolymerizing a monomer 1 represented by the following chemical formula (vi-1) and a monomer 2 represented by the following chemical formula (vi-2) in a molar ratio of 3:7.

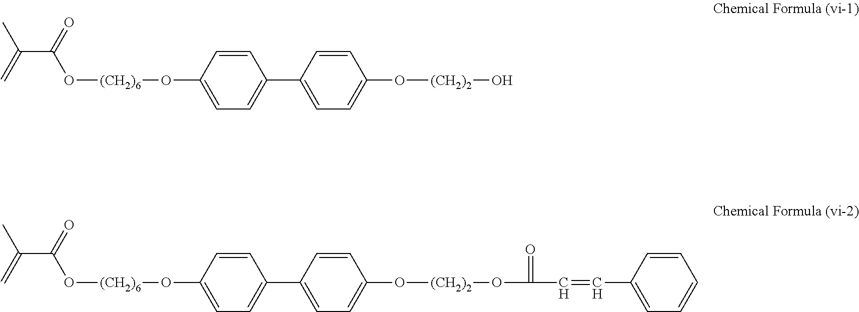

### Examples 1 to 32

### Preparation of Photo-Alignment Thermosetting Liquid Crystal Compositions 1 to 32

Compositions were obtained by mixing the side-chain liquid crystal polymer (A) and copolymer (B) shown in Table 7 in mass ratios shown in Table 7.

Photo-alignment thermosetting liquid crystal compositions of the following composition were prepared.
Composition shown in Table 7: 0.1 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Example 33

### Preparation of Photo-Alignment Thermosetting Liquid Crystal Composition 33

A photo-alignment thermosetting liquid crystal composition of the following composition was prepared.
Side-chain liquid crystal polymer A-3: 0.09 parts by mass
Copolymer B-1: 0.01 parts by mass
Polymerizable liquid crystal compound (product name: LC242, manufactured by: BASF): 0.01 parts by mass
Photopolymerization initiator (product name: OMNIRAD 907, manufactured by: IGM Resins): 0.004 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Example 34

### Preparation of Photo-Alignment Thermosetting Liquid Crystal Composition 34

A photo-alignment thermosetting liquid crystal composition of the following composition was prepared.
Side-chain liquid crystal polymer A-3: 0.09 parts by mass
Copolymer B-1: 0.01 parts by mass
Polyfunctional monomer (Pentaerythritol triacrylate (PETA)): 0.01 parts by mass
Photopolymerization initiator (product name: OMNIRAD 907, manufactured by: IGM Resins): 0.004 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Example 35

### Preparation of Photo-Alignment Thermosetting Liquid Crystal Composition 35

A photo-alignment thermosetting liquid crystal composition of the following composition was prepared.
Side-chain liquid crystal polymer A-3: 0.09 parts by mass
Copolymer B-1: 0.01 parts by mass
Photo-alignment group and thermally crosslinkable group-containing compound (methyl 4-hydroxycinnamate, manufactured by Tokyo Chemical Industry Co., Ltd.): 0.01 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### (Formation of Alignment Film-Cum-Retardation Film)

The photo-alignment thermosetting liquid crystal composition was applied onto one surface of a PET substrate (“E5100” manufactured by Toyobo Co., Ltd., thickness 38 μm) by bar coating so that the thickness when cured was 1.6 μm. The applied composition was dried by heating in an oven at 120° C. for one minute to align and thermally cure the liquid crystal component, thereby forming a cured film having a retardation layer function. Then, using an Hg—Xe lamp and a Glan-Taylor prism, 100 mJ/cm² of polarized ultraviolet light containing an emission line of 313 nm was applied to the surface of the cured film from the substrate normal in the vertical direction, thereby forming an alignment layer-cum-retardation layer as a cured film having an alignment layer function. Accordingly, an alignment film-cum-retardation film comprising an alignment layer-cum-retardation layer was obtained.

### (Production of Retardation Plate)

A solution was obtained by dissolving the following polymerizable liquid crystal compound (product name: LC242, manufactured by: BASF) in cyclohexanone so as to have a solid content of 15% by mass. To this solution, 5% by mass of a photopolymerization initiator (IRGACURE 184 manufactured by BASF) was added, thereby preparing a polymerizable liquid crystal composition.

The polymerizable liquid crystal composition was applied onto the alignment layer-cum-retardation layer (the first retardation layer) of the obtained alignment film-cum-retardation film by bar coating so that the thickness when cured was 1 μm. The applied composition was dried at 85° C. for 120 seconds to form a coating film. In a nitrogen atmosphere, using an Hg—Xe lamp, 300 mJ/cm² of non-polarized ultraviolet light containing an emission line of 365 nm was applied to the coating film, thereby forming the second retardation layer. Accordingly, a retardation plate was produced.

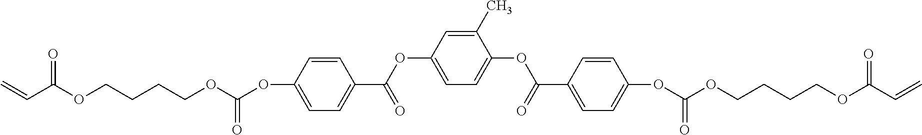 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

### Comparative Example 1

In the same manner as Example 1 described in Paragraph 0082 in JP-A No. 2016-004142, the obtained comparative copolymer C1 was dissolved in cyclohexanone; 4,4′-bis(diethylamino)benzophenone was added thereto so that the added 4,4′-bis(diethylamino)benzophenone was 2 parts by mass with respect to 100 parts by mass of the comparative copolymer C1, thereby preparing a comparative composition 1; and the first coating film was formed, which is a homeotropic alignment layer having a liquid crystal aligning ability. In the same manner as Examples, the second retardation layer was formed on the first coating film (corresponding to the alignment film-cum-retardation film and the first retardation layer). Accordingly, a retardation plate was produced.

### Comparative Examples 2 to 5

The preparation of a thermosetting liquid crystal composition, the formation of an alignment film-cum-retardation film, and the production of a retardation plate were carried out in the same manner as Example 1, except that a composition was obtained by mixing the side-chain liquid crystal polymer (A) shown in Table 5 and any of the comparative copolymers B′1 to B′3 in a mass ratio shown in Table 7.

### Evaluation

The obtained alignment film-cum-retardation films and retardation plates were evaluated as follows.

### (1) Homeotropic Alignment Property

A sample was obtained by peeling off the PET substrate from the alignment film-cum-retardation film and then transferring the alignment layer-cum-retardation layer to a glass with adhesive. The thickness direction retardation Rth at a wavelength of 550 nm of the sample was measured by a retardation measuring device (“KOBRA-WR” manufactured by Oji Scientific Instruments Co., Ltd.)

### (Evaluation Criterion for Homeotropic Alignment Property)

A: Rth≤−60 nm
B: −40 nm≥Rth>−60 nm
C: Rth>−40 nm

### (2) Photo-Alignment Property (the Ability of Aligning the Directly Stacked Liquid Crystal Component)

A sample was obtained by peeling off the PET substrate from the retardation plate and then transferring the alignment layer-cum-retardation layer (the first retardation layer) and the second retardation layer to a glass with adhesive. The in-plane retardation Re at a wavelength of 550 nm of the sample was measured by a retardation measuring device (“KOBRA-WR” manufactured by Oji Scientific Instruments Co., Ltd.)

### (Evaluation Criterion for Photo-Alignment Property)

A: Re≥135 nm
B: 100 nm≤Re<135 nm
C: Re<100 nm

TABLE 7

| | Side-chain liquid | | | | | |
|---|---|---|---|---|---|---|
| | crystal polymer (A) | | Copolymer (B) | | Homeotropic | Photo- |
| | Used | Mass | Used | Mass | alignment | alignment |
| | compound | ratio | compound | ratio | property | property |
| Example 1 | A1 | 90 | B1 | 10 | A | A |
| Example 2 | A1 | 90 | B2 | 10 | A | A |
| Example 3 | A1 | 90 | B3 | 10 | A | A |
| Example 4 | A1 | 90 | B4 | 10 | A | A |
| Example 5 | A1 | 90 | B5 | 10 | A | A |
| Example 6 | A1 | 90 | B6 | 10 | A | A |
| Example 7 | A1 | 90 | B7 | 10 | A | A |
| Example 8 | A1 | 90 | B8 | 10 | A | A |
| Example 9 | A1 | 90 | B9 | 10 | A | A |
| Example 10 | A1 | 90 | B10 | 10 | A | A |
| Example 11 | A1 | 90 | B11 | 10 | A | A |
| Example 12 | A1 | 90 | B12 | 10 | A | A |
| Example 13 | A1 | 90 | B13 | 10 | A | A |
| Example 14 | A1 | 99 | B14 | 1 | A | A |
| Example 15 | A1 | 90 | B15 | 10 | A | A |
| Example 16 | A2 | 90 | B1 | 10 | A | A |
| Example 17 | A3 | 90 | B1 | 10 | A | A |
| Example 18 | A4 | 90 | B1 | 10 | A | A |
| Example 19 | A5 | 90 | B1 | 10 | A | A |
| Example 20 | A6 | 90 | B1 | 10 | A | A |
| Example 21 | A7 | 90 | B1 | 10 | A | A |
| Example 22 | A8 | 90 | B1 | 10 | A | A |
| Example 23 | A9 | 90 | B1 | 10 | A | A |
| Example 24 | A10 | 90 | B1 | 10 | A | A |
| Example 25 | A11 | 90 | B1 | 10 | A | A |
| Example 26 | A12 | 90 | B1 | 10 | A | A |
| Example 27 | A13 | 90 | B1 | 10 | A | A |
| Example 28 | A14 | 90 | B1 | 10 | A | A |
| Example 29 | A3 | 99 | B1 | 1 | A | B |
| Example 30 | A3 | 95 | B1 | 5 | A | A |
| Example 31 | A3 | 80 | B1 | 20 | A | A |
| Example 32 | A3 | 70 | B1 | 30 | B | A |
| Comparative | C1 | 100 | — | 0 | B | C |
| Example 1 | | | | | | |
| Comparative | A1 | 90 | B′1 | 10 | C | C |
| Example 2 | | | | | | |
| Comparative | A3 | 90 | B′1 | 10 | C | C |
| Example 3 | | | | | | |
| Comparative | A3 | 90 | B′2 | 10 | C | C |
| Example 4 | | | | | | |
| Comparative | A3 | 90 | B′3 | 10 | C | C |
| Example 5 | | | | | | |

TABLE 8

| | Thermosetting | Homeotropic | Photo- |
|---|---|---|---|
| | liquid crystal | alignment | alignment |
| | composition | property | property |
| Example 33 | 33 | A | A |
| Example 34 | 34 | A | A |
| Example 35 | 35 | A | A |

### Example II Series: The Second Embodiment of the Present Disclosure

The Example II series presents examples of the second embodiment of the present disclosure, and it allows to understand that when the side-chain liquid crystal polymer (A) is combined with the copolymer (B) in the first embodiment of the present disclosure so as to satisfy the conditions relating to the second embodiment of the present disclosure, the effects of the second embodiment of the present disclosure can be obtained by the same action.

### Synthesis Example II-1: Synthesis of Liquid Crystal Monomer II-1

In reference to Paragraphs 0121 to 0124 in International Publication No. WO2018/003498, 4′-cyano-4-{4-[2-(acryloyloxy)ethoxy]benzoate} (the following chemical formula (II-i-1)) was obtained.

### Synthesis Example II-2: Synthesis of Liquid Crystal Monomer II-2

A liquid crystal monomer II-2 represented by the following chemical formula (II-i-2) was obtained in the same manner as Synthesis Example 1, except that 6-chloro-1-n-hexanol was used instead of 2-bromoethanol.

### Synthesis Example II-3: Synthesis of Liquid Crystal Monomer II-3

In reference to Paragraphs 0127 to 0130 in International Publication No. WO2018/003498, 4-[(4-propoxycarbonylphenyloxycarbonyl)phenyl-4-[6-(acryloyloxy)hexyloxy]benzoate (the following chemical formula (II-i-3)) was obtained.

TABLE 9

| | Chemical | |
|---|---|---|
| | Formula | Liquid crystal monomer |
| II-1 | (II-i-1) | 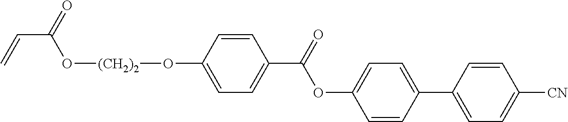 |
| II-2 | (II-i-2) | 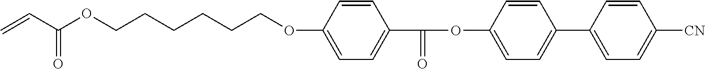 [SMILES: C=CC(=O)OCCCCCCOc1ccc(C(=O)Oc2ccc(-c3ccc(C#N)cc3)cc2)cc1] |
| II-3 | (II-i-3) | 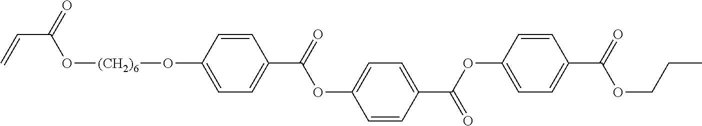 |

Stearyl acrylate (the following chemical formula (II-ii-1), manufactured by Tokyo Chemical Industry Co., Ltd.) was used as a non-liquid crystal monomer II-1; hexyl acrylate (the following chemical formula (II-ii-2), manufactured by Tokyo Chemical Industry Co., Ltd.) was used as a non-liquid crystal monomer II-2; and nonylphenoxypolyethylene glycol acrylate manufactured by Hitachi Chemical Co., Ltd. (the following chemical formula (II-ii-3)) was used as a non-liquid crystal monomer II-3. The non-liquid crystal monomer II-3 is a mixture where n′ of the following chemical formula (II-ii-3) is from 1 to 12; it contains at least a monomer where n′ is 8 and a monomer where n′ is 12; and the average of n′ is 8 (n′ T 8).

As a thermally crosslinkable group-containing non-liquid crystal monomer II-4tc, 2-hydroxyethyl methacrylate (the following chemical formula (II-ii-4), manufactured by Kyoeisha Chemical Co., Ltd., the thermally crosslinkable group is bound to a primary carbon, the total of the carbon atom number and oxygen atom number of a linear alkylene group optionally containing —O— in a carbon chain=2) was used; as a thermally crosslinkable group-containing non-liquid crystal monomer II-5tc, 4-hydroxybutyl acrylate (the following chemical formula (II-ii-5), manufactured by Tokyo Chemical Industry Co., Ltd., the thermally crosslinkable group is bound to a primary carbon, the total of the carbon atom number and oxygen atom number of a linear alkylene group optionally containing —O— in a carbon chain=4) was used; and as a thermally crosslinkable group-containing non-liquid crystal monomer II-6tc, 2-hydroxypropyl acrylate (the following chemical formula (II-ii-6), manufactured by Kyoeisha Chemical Co., Ltd., the thermally crosslinkable group is bound to a secondary carbon) was used.

### Synthesis Example II-4: Synthesis of Thermally Crosslinkable Group-Containing Non-Liquid Crystal Monomer II-7tc

As a thermally crosslinkable group-containing non-liquid crystal monomer II-7tc, 2-hydroxy-2-methylpropyl acrylate (the following chemical formula (II-ii-7), the thermally crosslinkable group is bound to a tertiary carbon) was obtained in the same manner as the synthesis of the compound 1 of Example 1A in JP-A No. 2016-155997.

### Synthesis Example II-5: Synthesis of Thermally Crosslinkable Group-Containing Non-Liquid Crystal Monomer II-8tc

A solution of acrylic acid chloride (13.6 g, 0.15 mol), diethylene glycol (31.8 g, 0.30 mol) and triethylamine (16.2 g, 0.16 mol) in tetrahydrofuran (100 ml) was stirred for 16 hours at room temperature. After a reaction was completed, the thus-obtained reaction solution was filtered and concentrated. The residue thus obtained was dissolved in chloroform. An organic layer was washed with 5% hydrochloric acid, 5% sodium hydrogen carbonate aqueous solution, and brine. After the washed organic layer was dried with sodium sulfate, the solvent was removed therefrom by distillation. The residue thus obtained was purified by column chromatography. Accordingly, as a thermally crosslinkable group-containing non-liquid crystal monomer II-8tc, 2-[(2-hydroxyethyl)oxy]ethyl acrylate (the following chemical formula (II-ii-8), the thermally crosslinkable group was bound to a primary carbon, the total of the carbon atom number and oxygen atom number of a linear alkylene group optionally containing —O— in a carbon chain=5) was obtained.

### Synthesis Example II-6: Synthesis of Thermally Crosslinkable Group-Containing Non-Liquid Crystal Monomer II-9tc

A thermally crosslinkable group-containing non-liquid crystal monomer II-9tc represented by the following chemical formula (II-ii-9) was synthesized in the same manner as the thermally crosslinkable monomer 5 of Synthesis Example e in JP Patent No. 5626492. In the non-liquid crystal monomer 9tc, the thermally crosslinkable group was bound to a primary carbon, and the total of the carbon atom number and oxygen atom number of a linear alkylene group optionally containing —O— in a carbon chain, was 2.

### Synthesis Example II-7: Synthesis of Thermally Crosslinkable Group-Containing Non-Liquid Crystal Monomer II-10tc

Acrylic acid chloride (27.2 g, 0.30 mol) was added in a dropwise manner to a tetrahydrofuran (10 ml) solution cooled to −30° C. of p-hydroquinone (33.0 g, 0.30 mol) and triethylamine (60.7 g, 0.60 mol). After the addition was completed, the solution was stirred for two hours. After a reaction was completed, the thus-obtained reaction solution was filtered and concentrated. The residue thus obtained was dissolved in ethyl acetate. An organic layer was washed with water and brine. After the washed organic layer was dried with magnesium sulfate, the solvent was removed therefrom by distillation. The residue thus obtained was purified by column chromatography. Accordingly, as a thermally crosslinkable group-containing non-liquid crystal monomer II-10tc, 4-hydroxyphenyl acrylate (the following chemical formula (II-ii-10), a hydroxy group was bound to an arylene group) was synthesized.

As a thermally crosslinkable group-containing non-liquid crystal monomer II-11tc, 6-(4-hydroxyphenyl)hexyl acrylate (the following chemical formula (II-ii-11), manufactured by DKSH, a hydroxy group was bound to an arylene group) was used.

### Synthesis Example 8: Synthesis of Thermally Crosslinkable Group-Containing Non-Liquid Crystal Monomer II-12tc

As a thermally crosslinkable group-containing non-liquid crystal monomer II-12tc, 4-[2-(acryloyloxy)ethoxy]benzoic acid (the following chemical formula (II-ii-12), a carboxy group was bound to an arylene group, the total of the carbon atom number and oxygen atom number of an alkylene group optionally containing —O— in a carbon chain or at a terminal to which the arylene group is bound, was 3) was obtained in the same manner as Synthesis Example 1 of International Publication No. WO2019/065608.

TABLE 10

| | Chemical | |
|---|---|---|
| | Formula | Non-liquid crystal monomer |
| II-1 | (II-ii-1) | 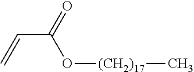 |
| II-2 | (II-ii-2) | 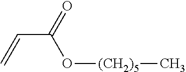 |
| II-3 | (II-ii-3) | 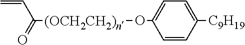 |
| | Chemical | Thermally crosslinkable group-containing non-liquid |
| | Formula | crystal monomer |
| II-4tc | (II-ii-4) | 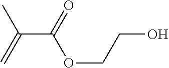 |
| Il-5tc | (II-ii-5) | 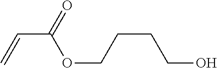 |
| II-6tc | (II-ii-6) | 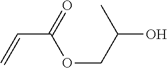 |
| II-7tc | (II-ii-7) | 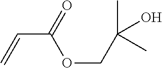 |
| II-8tc | (II-ii-8) | 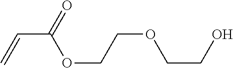 |
| II-9tc | (II-ii-9) | 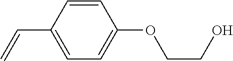 |
| II-10tc | (II-ii-10) | 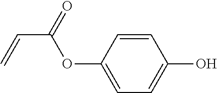 |
| Il-11tc | (II-ii-11) | 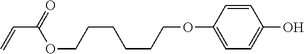 [SMILES: C=CC(=O)OCCCCCCOc1ccc(O)cc1] |
| II-12tc | (II-ii-12) | 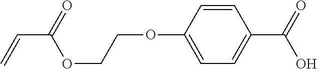 [SMILES: C=CC(=O)OCCOc1ccc(C(=O)O)cc1] |

### Synthesis Example II-9: Synthesis of Photo-Alignment Monomer II-1

A photo-alignment monomer II-1 represented by the following chemical formula (II-iii-1) was synthesized in the same manner as Synthesis Example 2 in JP Patent No. 5668881, except that an equimolar amount of methyl trans-4-hydroxycinnamate was used instead of methyl ferulate, and an equimolar amount of 6-chloro-1-hexanol was used instead of 4-chloro-1-butanol.

### Synthesis Example II-10: Synthesis of Photo-Alignment Monomer II-2

A photo-alignment monomer II-2 represented by the following chemical formula (II-iii-2) was synthesized in the same manner as Synthesis Example 2 of International Publication No. WO2018/003498, except that an equimolar amount of methyl trans-4-hydroxycinnamate was used instead of 4′-cyano-4-hydroxybiphenyl.

### Synthesis Example II-11: Synthesis of Photo-Alignment Monomer II-3

A photo-alignment monomer II-3 represented by the following chemical formula (II-iii-3) was synthesized in the same manner as the photo-alignment monomer A1 of Synthesis Example 1 in JP Patent No. 5668881.

### Synthesis Example II-12: Synthesis of Photo-Alignment Monomer II-4

A photo-alignment monomer II-4 represented by the following chemical formula (II-iii-4) was synthesized in the same manner as the photo-alignment monomer A2 of Synthesis Example 2 in JP Patent No. 5668881.

### Synthesis Example II-13: Synthesis of Photo-Alignment Monomer II-5

A photo-alignment monomer II-5 represented by the following chemical formula (II-iii-5) was synthesized in the same manner as the photo-alignment monomer 14 of Synthesis Example 14 in JP Patent No. 5626492.

### Synthesis Example II-14: Synthesis of Photo-Alignment Monomer II-6

A photo-alignment monomer II-6 represented by the following chemical formula (II-iii-6) was synthesized in the same manner as the photo-alignment monomer 3 of Synthesis Example 3 in JP Patent No. 5626492.

### Synthesis Example II-15: Synthesis of Photo-Alignment Monomer II-7

A photo-alignment monomer II-7 represented by the following chemical formula (II-iii-7) was synthesized in the same manner as Synthesis Example 2 in JP Patent No. 5668881, except that an equimolar amount of methyl trans-4-hydroxycinnamate was used instead of methyl ferulate.

TABLE 11

| | Chemical | |
|---|---|---|
| | Formula | Photo-alignment monomer |
| II-1 | (II-iii-1) | 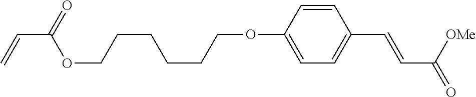 [SMILES: C=CC(=O)OCCCCCCOc1ccc(/C=C/C(=O)OC)cc1] |
| II-2 | (II-iii-2) | 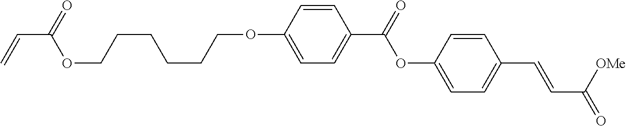 [SMILES: C=CC(=O)OCCCCCCOc1ccc(C(=O)Oc2ccc(/C=C/C(=O)OC)cc2)cc1] |
| II-3 | (Il-iii-3) | 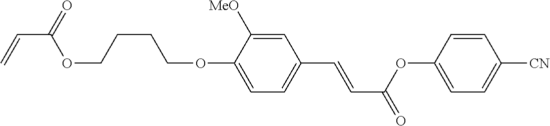 [SMILES: C=CC(=O)OCCCCOc1ccc(/C=C/C(=O)Oc2ccc(C#N)cc2)cc1OC] |
| II-4 | (II-iii-4) | 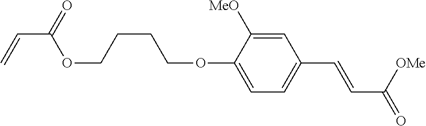 [SMILES: C=CC(=O)OCCCCOc1ccc(/C=C/C(=O)OC)cc1OC] |
| II-5 | (II-iii-5) | 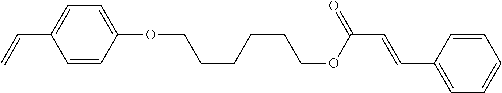 [SMILES: C=Cc1ccc(OCCCCCCOC(=O)/C=C/c2ccccc2)cc1] |
| II-6 | (II-iii-6) | 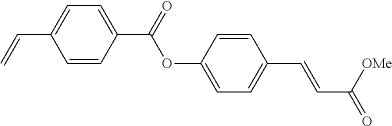 [SMILES: C=Cc1ccc(C(=O)Oc2ccc(/C=C/C(=O)OC)cc2)cc1] |
| II-7 | (II-iii-7) | 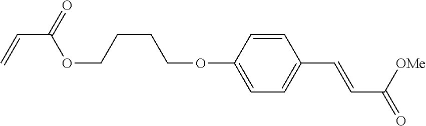 [SMILES: C=CC(=O)OCCCCOc1ccc(/C=C/C(=O)OC)cc1] |

### Synthesis Example 11-16: Synthesis of Thermally Crosslinkable Monomer II-1

A catalytic amount of concentrated sulfuric acid was added to a mixed solution of acrylic acid (20 g, 0.27 mol) and 1,6-hexanediol (33 g, 0.27 mol). The mixed solution was stirred for 4 hours at 90° C. After a reaction was completed, the reaction solution was added to ethyl acetate and washed with water. An organic layer was dried with sodium sulfate. Then, the solvent of the organic layer was removed by distillation. Accordingly, 6-hydroxyhexyl acrylate (the following chemical formula (II-iv-1), the total of the carbon atom number and oxygen atom number of a linear alkylene group optionally containing —O— in a carbon chain=6) was obtained as a thermally crosslinkable monomer II-1.

As a thermally crosslinkable monomer II-2, 4-hydroxybutyl acrylate (the following chemical formula (II-iv-2), manufactured by Tokyo Chemical Industry Co., Ltd., the total of the carbon atom number and oxygen atom number of a linear alkylene group optionally containing —O— in a carbon chain=4) was used.

### Synthesis Example II-17: Synthesis of Thermally Crosslinkable Monomer II-3

A thermally crosslinkable monomer II-3 (the total of the carbon atom number and oxygen atom number of a linear alkylene group optionally containing —O— in its carbon chain=11) represented by the following chemical formula (II-iv-3) was synthesized in the same manner as the thermally crosslinkable monomer B3 of Synthesis Example 4 in JP Patent No. 5668881.

### Synthesis Example II-18: Synthesis of Thermally Crosslinkable Monomer II-4

A thermally crosslinkable monomer II-4 (the total of the carbon atom number and oxygen atom number of a linear alkylene group optionally containing —O— in a carbon chain=4) represented by the following chemical formula (II-iv-4) was synthesized in the same manner as the thermally crosslinkable monomer B7 of Synthesis Example 5 in JP Patent No. 5668881.

### Synthesis Example II-19: Synthesis of Thermally Crosslinkable Monomer II-5

A thermally crosslinkable monomer II-5 (the total of the carbon atom number and oxygen atom number of a linear alkylene group optionally containing —O— in a carbon chain=6) represented by the following chemical formula (II-iv-5) was synthesized in the same manner as the thermally crosslinkable monomer B8 of Synthesis Example 6 in JP Patent No. 5668881.

### Synthesis Example II-20: Synthesis of Thermally Crosslinkable Monomer II-6

A thermally crosslinkable monomer II-6 (the total of the carbon atom number and oxygen atom number of a linear alkylene group optionally containing —O— in a carbon chain=6) represented by the following chemical formula (II-iv-6) was synthesized in the same manner as the thermally crosslinkable monomer B10 of Synthesis Example 8 in JP Patent No. 5668881.

### Synthesis Example II-21: Synthesis of Thermally Crosslinkable Monomer II-7

A thermally crosslinkable monomer II-7 (the total of the carbon atom number and oxygen atom number of a linear alkylene group optionally containing —O— in a carbon chain=5) represented by the following chemical formula (II-iv-7) was synthesized in the same manner as Example 9 in Japanese translation of PCT International Application No. 2016-538400.

### Synthesis Example II-22: Synthesis of Thermally Crosslinkable Monomer II-8

A thermally crosslinkable monomer II-8 (the total of the carbon atom number and oxygen atom number of a linear alkylene group optionally containing —O— in a carbon chain=4) represented by the following chemical formula (II-iv-8) was synthesized in the same manner as Paragraph 124 in Japanese translation of PCT International Application No. 2018-525444.

A thermally crosslinkable monomer 11-9 (the total of the carbon atom number and oxygen atom number of a linear alkylene group optionally containing —O— in a carbon chain=5) represented by the following chemical formula (II-iv-9) was prepared in the same manner as the thermally crosslinkable group-containing non-liquid crystal monomer II-8tc of Synthesis Example II-5.

TABLE 12

| | Chemical | |
|---|---|---|
| | Formula | Thermally crosslinkable monomer |
| II-1 | (Il-iv-1) | 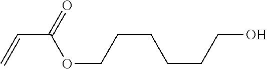 |
| II-2 | (Il-iv-2) | 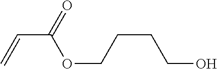 |
| II-3 | (Il-iv-3) | 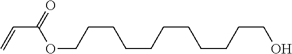 [SMILES: C=CC(=O)OCCCCCCCCCCCO] |
| II-4 | (II-iv-4) | 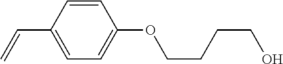 |
| II-5 | (Il-iv-5) | 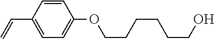 [SMILES: C=Cc1ccc(OCCCCCCO)cc1] |
| II-6 | (Il-iv-6) | 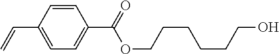 [SMILES: C=Cc1ccc(C(=O)OCCCCCCO)cc1] |
| II-7 | (Il-iv-7) | 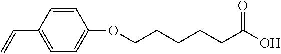 [SMILES: C=Cc1ccc(OCCCCCC(=O)O)cc1] |
| II-8 | (Il-iv-8) | 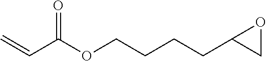 |
| II-9 | (Il-iv-9) | 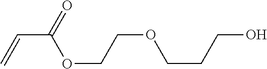 |

For the third constitutional unit, N-(methoxymethyl)methacrylamide (the following chemical formula (II-v-1), manufactured by Tokyo Chemical Industry Co., Ltd.) was used as a self-crosslinkable group-containing monomer II-1, and VISCOAT 13F (the following chemical formula (II-v-2), manufactured by Osaka Organic Chemical Industry Ltd.) was used as a fluorinated alkyl group-containing monomer II-1.

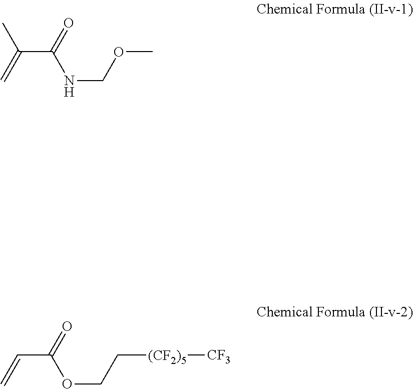

### Production Examples II-A1 to II-A19: Production of Side-Chain Liquid Crystal Polymers II-A1 to II-A19

Side-chain liquid crystal polymers were synthesized by combining the liquid crystal monomers II-1 to II-3, the non-liquid crystal monomers II-1 to II-3 and II-4tc to II-12tc and the photo-alignment monomer II-7 according to Table 13.

An example of the synthesis of a side-chain liquid crystal polymer II-A2 will be described in detail.

The non-liquid crystal monomer II-1 and the non-liquid crystal monomer II-2 were mixed in a molar ratio of 50:50. The mixture of the non-liquid crystal monomers and the liquid crystal monomer 1 were combined in a molar ratio of 40:60 and mixed. N,N-dimethylacetamide (DMAc) was added thereto, and they were stirred at 40° C. to dissolve the monomers. After dissolving the monomers, the mixture was cooled to 24° C., and azobisisobutyronitrile (AIBN) was added thereto and dissolved at the same temperature. The reaction solution thus obtained was added in a dropwise manner over 30 minutes to DMAc heated to 80° C. After the addition was completed, the mixture was stirred for 6 hours at 80° C. After a reaction was completed, the reaction solution thus obtained was cooled to room temperature; the cooled solution was added in a dropwise manner to another container in which methanol was under stirring; and they were stirred for 20 minutes. Supernatant was removed therefrom; the slurry thus obtained was filtered to obtain a crude product; the crude product was stirred in methanol for 20 minutes again; and after removal of the supernatant, filtration was performed. The obtained crystals were dried, thereby obtaining the side-chain liquid crystal polymer II-A2 in a yield of 76.5%.

For the obtained side-chain liquid crystal polymer, the mass average molecular weight was measured, and the structure was analyzed. By Py-GC-MS or MALDI-TOFMS, it was confirmed that the liquid crystal polymer contained a constitutional unit derived from one kind of non-liquid crystal monomer used or constitutional units derived from two or three kinds of non-liquid crystal monomers used.

TABLE 13
Side-chain liquid crystal polymer (A)
Liquid crystal monomer:Non-liquid crystal monomer = 60 : 40 (molar ratio)

| Liquid | Liquid | | | | Composition | Molecular |
|---|---|---|---|---|---|---|
| crystal | crystal | Non-liquid crystal monomer | | | ratio | weight |
| polymer | monomer | a | b | c | a:b:c | Mw |
| II-A1 | II-1 | II-1 | | | 100:00:00 | 22000 |
| II-A2 | II-1 | II-1 | II-2 | | 50:50:00 | 23500 |
| II-A3 | II-1 | II-1 | | II-4tc | 50:00:50 | 31500 |
| II-A4 | II-1 | II-1 | II-2 | II-4tc | 25:25:50 | 25000 |
| II-A5 | II-3 | II-1 | | II-4tc | 50:00:50 | 26000 |
| II-A6 | II-2 | II-1 | | II-4tc | 50:00:50 | 28000 |
| II-A7 | II-1 | II-3 | | | 100:00:00 | 22500 |
| II-A8 | II-1 | II-3 | | II-4tc | 50:00:50 | 25000 |
| II-A9 | II-1 | II-1 | | II-6tc | 50:00:50 | 24000 |
| II-A10 | II-1 | II-1 | | II-7tc | 50:00:50 | 27500 |
| II-A11 | II-1 | II-1 | | II-5tc | 50:00:50 | 20000 |
| II-A12 | II-1 | II-1 | | II-9tc | 50:00:50 | 26500 |
| II-A13 | II-1 | II-1 | | II-8tc | 50:00:50 | 28000 |
| II-A14 | II-1 | | | II-10tc | 50:00:50 | 24000 |
| II-A15 | II-1 | II-1 | | II-11tc | 50:00:50 | 25500 |
| II-A16 | II-1 | II-1 | | II-12tc | 50:00:50 | 28000 |
| II-A17 | II-1 | II-1 | Photo-alignment | II-4tc | 25:25:50 | 30500 |
| | | | monomer II-7 | | | |
| II-A18 | II-1 | | | II-4tc | 0:0:100 | 34000 |
| II-A19 | II-1 | II-1 | II-5tc | II-4tc | 50:25:25 | 20500 |

### Production Examples II-B1 to II-B17: Production of Copolymers II-B1 to II-B17

Copolymers (B) were synthesized by combining the photo-alignment monomers II-1 to II-7, the thermally crosslinkable monomers II-1 to II-9, the fluorinated alkyl group-containing monomer II-1 and the self-cross linkable group-containing monomer II-1 according to Table 14.

An example of the synthesis of a copolymer II-B1 will be described in detail.

First, 3.32 g of the photo-alignment monomer II-1, 1.72 g of the thermally crosslinkable monomer II-1 and 50 mg of α,α′-azobisisobutyronitrile (AIBN) as a polymerization catalyst, were dissolved in 25 ml of dioxane and reacted at 90° C. for 6 hours. After the reaction was completed, the reaction solution thus obtained was purified by reprecipitation, thereby obtaining a copolymer II-B1. The mass average molecular weight of the obtained copolymer II-B1 was 21300.

The mass average molecular weight (hereinafter, it will be simply referred to as Mw) of each of the synthesized copolymers was calculated by gel permeation chromatography (GPC) with HLC-8220 GPC manufactured by Tosoh Corporation, using polystyrene as a standard substance and NMP as an eluent.

### [Comparative Production Examples II-B′1 and II-B′2] Synthesis of Comparative Copolymers II-B′1 and II-B′2

As a comparative thermally crosslinkable monomer II-1, a thermally crosslinkable group-containing non-liquid crystal monomer II-9tc (the total of the carbon atom number and oxygen atom number of a linear alkylene group optionally containing —O— in a carbon chain, was 2) represented by the chemical formula (II-ii-9) of Synthesis Example 4 was prepared. As a comparative thermally crosslinkable monomer II-2, a thermally crosslinkable group-containing non-liquid crystal monomer II-4tc (the total of the carbon atom number and oxygen atom number of a linear alkylene group optionally containing —O— in a carbon chain, was 2) represented by the chemical formula (II-ii-4) was prepared.

In the same manner as the copolymer II-B1, comparative copolymers II-B′1 and II-B′2 were synthesized by combining the photo-alignment monomer II-1 and the comparative thermally crosslinkable monomers II-1 and II-2 according to Table 14.

TABLE 14
Copolymer (B)

| | Photo- | Thermally | Third | | |
|---|---|---|---|---|---|
| | alignment | crosslinkable | constitutional | Molar | |
| Copolymer | monomer | monomer | unit | ratio | Mw |
| II-B1 | II-1 | II-1 | | 50:50:0 | 14000 |
| II-B2 | II-2 | II-1 | | 50:50:0 | 14500 |
| II-B3 | II-3 | II-1 | | 50:50:0 | 12000 |
| II-B4 | II-4 | II-1 | | 50:50:0 | 15000 |
| II-B5 | II-5 | II-1 | | 50:50:0 | 15000 |
| II-B6 | II-6 | II-1 | | 50:50:0 | 18000 |
| II-B7 | II-7 | II-1 | | 50:50:0 | 20000 |
| II-B8 | II-7 | II-2 | | 50:50:0 | 16000 |
| II-B9 | II-7 | II-3 | | 50:50:0 | 16500 |
| II-B10 | II-7 | II-4 | | 50:50:0 | 13000 |
| Il-B11 | II-7 | II-5 | | 50:50:0 | 17000 |
| II-B12 | II-7 | II-6 | | 50:50:0 | 16000 |
| II-B13 | II-7 | II-7 | | 50:50:0 | 20000 |
| II-B14 | II-7 | II-8 | | 50:50:0 | 15000 |
| II-B15 | II-7 | II-9 | | 50:50:0 | 17000 |
| II-B16 | II-7 | II-1 | Fluorinated alkyl | 50:45:5 | 15000 |
| | | | group-containing | | |
| | | | monomer II- 1 | | |
| II-B17 | II-7 | II-1 | Self-crosslinkable | 50:30:20 | 13500 |
| | | | group-containing | | |
| | | | monomer II- 1 | | |
| II-B′1 | II-1 | 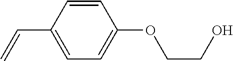 | | 50:50:0 | 13000 |
| II-B′2 | II-1 | 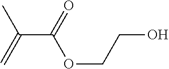 | | 50:50:0 | 12000 |

### [Comparative Production Example II-C1] Synthesis of Comparative Copolymer II-C1

In the same manner as the polymer 1 described in Paragraphs 0073 to 0076 and 0079 in JP-A No. 2016-004142, a comparative copolymer II-C1 was obtained by copolymerizing a monomer 1 represented by the following chemical formula (II-vi-1) and a monomer 2 represented by the following chemical formula (II-vi-2) in a molar ratio of 3:7.

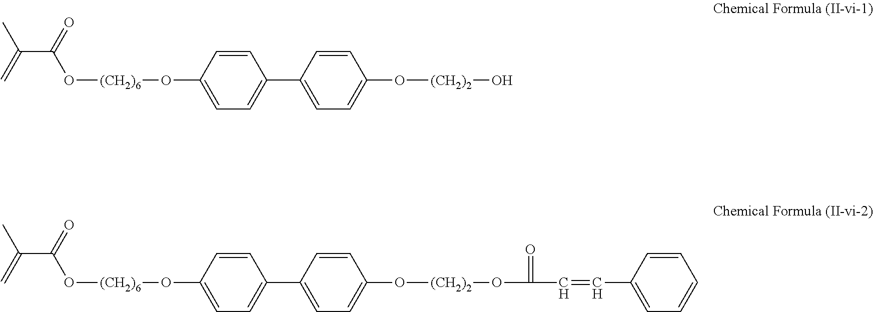

### Examples II-1 to II-38

### Preparation of Photo-Alignment Thermosetting Liquid Crystal Compositions II-1 to II-38

Compositions were obtained by mixing the side-chain liquid crystal polymer (A) and copolymer (B) shown in Table 15 or 16 in mass ratios shown in Table 15 or 16.

Photo-alignment thermosetting liquid crystal compositions of the following composition were prepared.
Composition of the side-chain liquid crystal polymer (A) and copolymer (B) shown in Table 15 or 16: 100 parts by mass
Thermal crosslinking agent (Hexamethoxymethylmelamine (HMM)): In parts by mass shown in Table 15 or 16 (10 parts by mass or 7 parts by mass)
p-Toluenesulfonic acid monohydrate (PTSA): 1 part by mass
Propylene glycol monomethyl ether (PGME): 170 parts by mass
Cyclohexanone: 400 parts by mass

### Example II-39

### Preparation of Photo-Alignment Thermosetting Liquid Crystal Composition II-39

A photo-alignment thermosetting liquid crystal composition of the following composition was prepared.
Side-chain liquid crystal polymer II-A3: 0.09 parts by mass
Copolymer II-B1: 0.01 parts by mass
Polymerizable liquid crystal compound (product name: LC242, manufactured by: BASF): 0.01 parts by mass
Photopolymerization initiator (product name: OMNIRAD 907, manufactured by: IGM Resins): 0.004 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Example II-40

### Preparation of Photo-Alignment Thermosetting Liquid Crystal Composition II-40

A photo-alignment thermosetting liquid crystal composition of the following composition was prepared.
Side-chain liquid crystal polymer II-A3: 0.09 parts by mass
Copolymer II-B1: 0.01 parts by mass
Polyfunctional monomer (Pentaerythritol triacrylate (PETA)): 0.01 parts by mass
Photopolymerization initiator (product name: OMNIRAD 907, manufactured by: IGM Resins): 0.004 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Example II-41

### Preparation of Photo-Alignment Thermosetting Liquid Crystal Composition II-41

A photo-alignment thermosetting liquid crystal composition of the following composition was prepared.
Side-chain liquid crystal polymer II-A3: 0.09 parts by mass
Copolymer II-B1: 0.01 parts by mass
Photo-alignment group and thermally crosslinkable group-containing compound (methyl 4-hydroxycinnamate, manufactured by Tokyo Chemical Industry Co., Ltd.): 0.01 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

### Formation of Alignment Film-Cum-Retardation Film

The photo-alignment thermosetting liquid crystal composition was applied onto one surface of a PET substrate (“E5100” manufactured by Toyobo Co., Ltd., thickness 38 μm) by bar coating so that the thickness when cured was 1.6 μm. The applied composition was dried by heating in an oven at 120° C. for one minute to align and thermally cure the liquid crystal component, thereby forming a cured film having a retardation layer function. Then, using an Hg—Xe lamp and a Glan-Taylor prism, 100 mJ/cm² of polarized ultraviolet light containing an emission line of 313 nm was applied to the surface of the cured film from the substrate normal in the vertical direction, thereby forming an alignment layer-cum-retardation layer as a cured film having an alignment layer function. Accordingly, an alignment film-cum-retardation film comprising an alignment layer-cum-retardation layer was obtained.

### (Production of Retardation Plate)

A solution was obtained by dissolving the following polymerizable liquid crystal compound (product name: LC242, manufactured by: BASF) in cyclohexanone so as to have a solid content of 15% by mass. To this solution, 5% by mass of a photopolymerization initiator (IRGACURE 184 manufactured by BASF) was added, thereby preparing a polymerizable liquid crystal composition.

The polymerizable liquid crystal composition was applied onto the alignment layer-cum-retardation layer (the first retardation layer) of the obtained alignment film-cum-retardation film by bar coating so that the thickness when cured was 1 μm. The applied composition was dried at 85° C. for 120 seconds to form a coating film. In a nitrogen atmosphere, using an Hg—Xe lamp, 300 mJ/cm² of non-polarized ultraviolet light containing an emission line of 365 nm was applied to the coating film, thereby forming the second retardation layer. Accordingly, a retardation plate was produced.

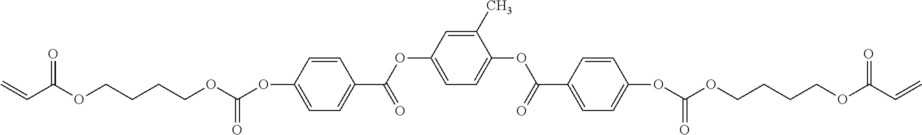 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

### Comparative Example II-1

In the same manner as Example 1 described in Paragraph 0082 in JP-A No. 2016-004142, the obtained comparative copolymer II-C1 was dissolved in cyclohexanone; 4,4′-bis(diethylamino)benzophenone was added thereto so that the added 4,4′-bis(diethylamino)benzophenone was 2 parts by mass with respect to 100 parts by mass of the comparative copolymer II-C1, thereby preparing a comparative composition 1; and the first coating film was formed, which is a homeotropic alignment layer having a liquid crystal aligning ability. In the same manner as Examples, the second retardation layer was formed on the first coating film (corresponding to the alignment film-cum-retardation film and the first retardation layer). Accordingly, a retardation plate was produced.

### Comparative Examples II-2 to II-7

The preparation of a thermosetting liquid crystal composition, the formation of an alignment film-cum-retardation film, and the production of a retardation plate were carried out in the same manner as Example II-1, except that a composition was obtained by mixing the side-chain liquid crystal polymer (A) shown in Table 16 and any of the comparative copolymers II-B′1 and II-B′2 or the copolymer II-B7 in a mass ratio shown in Table 16.

### Evaluation

The obtained alignment film-cum-retardation films and retardation plates were evaluated as follows.

### (1) Homeotropic Alignment Property

A sample was obtained by peeling off the PET substrate from the alignment film-cum-retardation film and then transferring the alignment layer-cum-retardation layer to a glass with adhesive. The thickness direction retardation Rth at a wavelength of 550 nm of the sample was measured by a retardation measuring device (“KOBRA-WR” manufactured by Oji Scientific Instruments Co., Ltd.)

### (Evaluation Criterion for Homeotropic Alignment Property)

A: Rth≤−80 nm
B: −40 nm≥Rth>−80 nm
C: Rth>−40 nm

### (2) Photo-Alignment Property (the Ability of Aligning the Directly Stacked Liquid Crystal Component)

A sample was obtained by peeling off the PET substrate from the retardation plate and then transferring the alignment layer-cum-retardation layer (the first retardation layer) and the second retardation layer to a glass with adhesive. The in-plane retardation Re at a wavelength of 550 nm of the sample was measured by a retardation measuring device (“KOBRA-WR” manufactured by Oji Scientific Instruments Co., Ltd.)

### (Evaluation Criterion for Photo-Alignment Property)

A: Re≥135 nm
B: 100 nm≤Re<135 nm
C: Re<100 nm

### (3) Heat Resistance

The sample evaluated for the homeotropic alignment property was heated in an oven at 100° C. for one hour. After heating, the thickness direction retardation Rth at a wavelength of 550 nm was measured in the same manner as the homeotropic alignment property evaluation. Using the values, the retardation change rate after heating was calculated by the following formula. In accordance with the following evaluation criterion, the heat resistance was evaluated.

Retardation change rate (%) after heating={(Rth before heating−Rth after heating)/Rth before heating}×100

### (Evaluation Criterion for Heat Resistance)

A: The retardation change rate after heating was 10r or less.
B: The retardation change rate after heating was more than 10% and 15% or less.
C: The retardation change rate after heating was more than 15%.

### (4) Solvent Permeation Resistance

Onto the sample evaluated for the homeotropic alignment property, cyclohexanone was applied by bar coating. The sample was dried at 85° C. for 120 seconds. Then, the thickness direction retardation Rth at a wavelength of 550 nm was measured in the same manner as the homeotropic alignment property evaluation. Using the values, the retardation change rate was calculated by the following formula. In accordance with the following evaluation criterion, the solvent permeation resistance was evaluated.

### (Evaluation Criterion for Solvent Permeation Resistance)

A: The retardation change rate after testing was 3% or less.
B: The retardation change rate after testing was more than 3% and 10% or less.
C: The retardation change rate after testing was more than 10′%.

TABLE 15

| | | | | | | | Crosslinking | | | | | |
|---|---|---|---|---|---|---|---|---|---|---|---|---|
| | Liquid crystal polymer (A) | | | Copolymer (B) | | | agent (C) | | Homeotropic | Photo- | | Solvent |
| | Used | (C + O) | Mass | Used | (C + O) | Mass | Used | Mass | alignment | alignment | Heat | permeation |
| Example | compound | Number | ratio | compound | Number | ratio | compound | ratio | property | property | resistance | resistance |
| II-1 | II-A1 | — | 90 | II-B1 | 6 | 10 | HMM | 10 | A | A | A | B |
| II-2 | II-A2 | — | 90 | II-B1 | 6 | 10 | HMM | 10 | A | A | A | B |
| II-3 | II-A3 | 2 | 90 | II-B1 | 6 | 10 | HMM | 10 | A | A | A | A |
| II-4 | II-A4 | 2 | 90 | II-B1 | 6 | 10 | HMM | 10 | A | A | A | A |
| II-5 | II-A5 | 2 | 90 | II-B1 | 6 | 10 | HMM | 10 | A | A | A | A |
| II-6 | II-A6 | 2 | 90 | II-B1 | 6 | 10 | HMM | 10 | A | A | A | A |
| II-7 | II-A7 | — | 90 | II-B1 | 6 | 10 | HMM | 10 | A | A | A | B |
| II-8 | II-A8 | 2 | 90 | II-B1 | 6 | 10 | HMM | 10 | A | A | A | A |
| II-9 | II-A9 | Secondary | 90 | II-B1 | 6 | 10 | HMM | 10 | A | A | A | A |
| II-10 | II-A10 | Tertiary | 90 | II-B1 | 6 | 10 | HMM | 10 | A | A | A | B |
| II-11 | II-A11 | 4 | 90 | II-B1 | 6 | 10 | HMM | 7 | B | A | A | A |
| II-12 | II-A12 | 2 | 90 | II-B1 | 6 | 10 | HMM | 10 | A | A | A | A |
| II-13 | II-A14 | Arylene | 90 | II-B1 | 6 | 10 | HMM | 10 | A | A | A | B |
| II-14 | II-A15 | Arylene | 90 | II-B1 | 6 | 10 | HMM | 10 | A | A | A | B |
| II-15 | II-A16 | 3 | 90 | II-B1 | 6 | 10 | HMM | 7 | A | A | A | B |
| II-16 | II-A17 | 2 | 90 | II-B1 | 6 | 10 | HMM | 10 | A | A | A | A |
| II-17 | II-A18 | 2 | 90 | II-B1 | 6 | 10 | HMM | 10 | A | A | A | A |
| II-18 | II-A19 | 4 | 90 | II-B1 | 6 | 10 | HMM | 7 | A | A | A | A |
| II-19 | II-A3 | 2 | 90 | II-B2 | 6 | 10 | HMM | 10 | A | A | A | A |
| II-20 | II-A3 | 2 | 90 | II-B3 | 6 | 10 | HMM | 10 | A | A | A | A |
| II-21 | II-A3 | 2 | 90 | II-B4 | 6 | 10 | HMM | 10 | A | A | A | A |
| II-22 | II-A3 | 2 | 90 | II-B5 | 6 | 10 | HMM | 10 | A | A | A | A |

TABLE 16

| | | | | | | | Crosslinking | | | | | |
|---|---|---|---|---|---|---|---|---|---|---|---|---|
| | Liquid crystal polymer (A) | | | Copolymer (B) | | | agent (C) | | Homeotropic | Photo- | | Solvent |
| | Used | (C + O) | Mass | Used | (C + O) | Mass | Used | Mass | alignment | alignment | Heat | permeation |
| Example | compound | Number | ratio | compound | Number | ratio | compound | ratio | property | property | resistance | resistance |
| II-23 | II-A3 | 2 | 90 | II-B6 | 6 | 10 | HMM | 10 | A | A | A | A |
| II-24 | II-A3 | 2 | 90 | II-B7 | 6 | 10 | HMM | 10 | A | A | A | A |
| II-25 | II-A3 | 2 | 90 | II-B8 | 4 | 10 | HMM | 10 | A | A | A | A |
| II-26 | II-A3 | 2 | 90 | II-B9 | 11 | 10 | HMM | 10 | A | A | A | A |
| II-27 | II-A3 | 2 | 90 | II-B10 | 4 | 10 | HMM | 10 | A | A | A | A |
| II-28 | II-A3 | 2 | 90 | II-B11 | 6 | 10 | HMM | 10 | A | A | A | A |
| II-29 | II-A3 | 2 | 90 | II-B12 | 6 | 10 | HMM | 10 | A | A | A | A |
| II-30 | II-A3 | 2 | 90 | II-B13 | 5 | 10 | HMM | 10 | A | A | A | A |
| II-31 | II-A3 | 2 | 90 | II-B14 | 4 | 10 | HMM | 10 | A | A | A | A |
| II-32 | II-A3 | 2 | 90 | II-B15 | 5 | 10 | HMM | 10 | A | A | A | A |
| II-33 | II-A3 | 2 | 90 | II-B16 | 6 | 10 | HMM | 10 | A | A | A | A |
| II-34 | II-A3 | 2 | 90 | II-B17 | 6 | 10 | HMM | 10 | A | A | A | A |
| II-35 | II-A3 | 2 | 95 | II-B1 | 6 | 5 | HMM | 10 | A | B | A | A |
| II-36 | II-A3 | 2 | 80 | II-B1 | 6 | 20 | HMM | 10 | A | A | A | A |
| II-37 | II-A3 | 2 | 70 | II-B1 | 6 | 30 | HMM | 10 | B | A | A | A |
| II-38 | II-A13 | 5 | 90 | II-B9 | 11 | 10 | HMM | 7 | B | A | A | A |

| | | | | | | | Crosslinking | | | | | |
|---|---|---|---|---|---|---|---|---|---|---|---|---|
| | Liquid crystal polymer (A) | | | Copolymer (B) | | | agent (C) | | Homeotropic | Photo- | | Solvent |
| Comparative | Used | (C + O) | Mass | Used | (C + O) | Mass | Used | Mass | alignment | alignment | Heat | permeation |
| Example | compound | Number | ratio | compound | Number | ratio | compound | ratio | property | property | resistance | resistance |
| II-1 | II-C1 | — | 100 | — | — | 0 | — | 0 | B | C | C | C |
| II-2 | II-A1 | — | 90 | II-B′1 | 2 | 10 | HMM | 10 | B | C | B | B |
| II-3 | II-A3 | 2 | 90 | II-B′1 | 2 | 10 | HMM | 10 | A | C | A | A |
| II-4 | II-A3 | 2 | 90 | II-B′2 | 2 | 10 | HMM | 10 | A | C | A | A |
| II-5 | II-A11 | 4 | 90 | II-B7 | 4 | 10 | HMM | 7 | B | C | A | A |
| II-6 | II-A11 | 4 | 90 | II-B7 | 4 | 10 | HMM | 10 | C | A | A | A |
| II-7 | II-A1 | — | 100 | — | — | 0 | — | 0 | A | C | C | C |

In Table 15 or 16, “(C+O) number” represents the total of the carbon atom number and oxygen atom number of a linear alkylene group optionally containing —O— in a carbon chain in the thermally crosslinkable constitutional unit.

TABLE 17

| | Thermosetting | Homeotropic | Photo- | | Solvent |
|---|---|---|---|---|---|
| | liquid crystal | alignment | alignment | Heat | permeation |
| | composition | property | property | resistance | resistance |
| Example II-39 | II-39 | A | A | A | A |
| Example II-40 | II-40 | A | A | A | A |
| Example II-41 | II-41 | A | A | A | A |

### Example III Series: The Third Embodiment of the Present Disclosure

The Example III series presents examples of the third embodiment of the present disclosure, and it shows that the same effects can be obtained by the first or second embodiment of the present disclosure.

A liquid crystal monomer III-1 and non-liquid crystal monomers III-1 and III-2tc were prepared in the same manner as the liquid crystal monomer 1 and non-liquid crystal monomers 1 and 4tc of the Example I series. Also, a non-liquid crystal monomer III-3tc was prepared in the same manner as the non-liquid crystal monomer II-10tc of the Example II series.

TABLE 18

| | Chemical | |
|---|---|---|
| | formula | Liquid crystal monomer |
| III-1 | (III-i-1) | 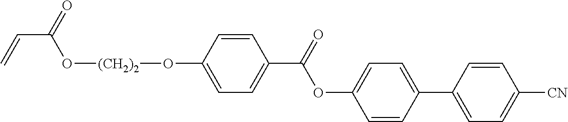 |
| | Chemical | |
| | formula | Non-liquid crystal monomer |
| III-1 | (IM-ii-1) | 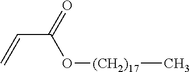 |
| | Chemical | Thermally crosslinkable group-containing non-liquid |
| | formula | crystal monomer |
| III-2tc | (III-ii-2) | 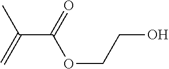 |
| | Chemical | |
| | formula | Non-liquid crystal monomer containing no alkylene group |
| III-3tc | (III-ii-3) | 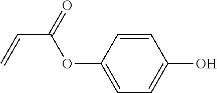 |

A photo-alignment monomer III-1 was prepared in the same manner as the photo-alignment monomer 1 of the Example I series. Also, thermally crosslinkable monomers III-1, III-2 and III-3 were prepared in the same manner as the thermally crosslinkable monomers 1, 2 and 6 of the Example I series.

TABLE 19

| | Chemical | |
|---|---|---|
| | Formula | Photo-alignment monomer |
| | (III-iii-1) | 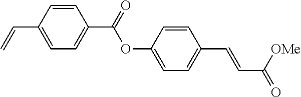 [SMILES: C=Cc1ccc(C(=O)Oc2ccc(/C=C/C(=O)OC)cc2)cc1] |
| | Chemical | |
| | Formula | Thermally crosslinkable monomer |
| III-1 | (III-iv-1) | 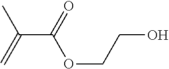 |
| III-2 | (III-iv-2) | 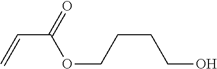 |
| III-3 | (III-iv-3) | 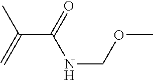 |

### Production Examples III-A1 to III-A4: Production of Side-Chain Liquid Crystal Polymers III-A1 to III-A4

In the same manner as the Example I series, side-chain liquid crystal polymers were synthesized by combining the liquid crystal monomer III-1 and the non-liquid crystal monomers III-1, III-2tc and III-3tc according to Table 20.

TABLE 20
Side-chain liquid crystal polymer
Liquid crystal monomer:Non-liquid crystal monomer = 60:40 (molar ratio)

| Liquid | Liquid | | | | Composition | Molecular |
|---|---|---|---|---|---|---|
| crystal | crystal | Non-liquid crystal monomer | | | ratio | weight |
| polymer | monomer | a | b | c | a:b:c | Mw |

| | | | | | |
|---|---|---|---|---|---|
| III-A1 | III-1 | III-1 | | 100:00:00 | 22000 |
| III-A2 | III-1 | III-1 | III-2tc | 50:00:50 | 31500 |
| III-A3 | III-1 | | III-2tc | 0:0:100 | 34000 |
| III-A4 | III-1 | | III-3tc | 0:0:100 | 30000 |

### Production Examples III-B1 to III-B3: Production of Copolymers III-B1 to III-B3

In the same manner as the copolymer (B) of the Example I series, photo-alignment copolymers were synthesized by combining the photo-alignment monomer III-1 and the thermally crosslinkable monomers III-1 to III-3 according to Table 21.

TABLE 21
Photo-alignment copolymer

| | | Thermally | | | |
|---|---|---|---|---|---|
| | Photo-alignment | crosslinkable | Third component | Molar | |
| | monomer | monomer | monomer | ratio | Mw |
| III-B1 | III-1 | III-1 | | 50:50:00 | 18000 |
| III-B2 | III-1 | III-2 | | 50:50:00 | 15000 |
| III-B3 | III-1 | III-1 | Self-crosslinkable | 50:30:20 | 15000 |
| | | | group-containing | | |
| | | | thermally | | |
| | | | crosslinkable | | |
| | | | monomer III-3 | | |

### Examples III-1 to III-8

### Preparation of Photo-Alignment Thermosetting Liquid Crystal Compositions III-1 to III-8

Compositions were obtained by mixing the side-chain liquid crystal polymer and copolymer shown in Table 22 in mass ratios shown in Table 22.

Photo-alignment thermosetting liquid crystal compositions of the following composition were prepared.
Composition of the side-chain liquid crystal polymer and copolymer shown in Table 22: 100 parts by mass
Thermal crosslinking agent (Hexamethoxymethylmelamine (HMM)): 10 parts by mass
p-Toluenesulfonic acid monohydrate (PTSA): 1 part by mass
Propylene glycol monomethyl ether (PGME): 170 parts by mass
Cyclohexanone: 400 parts by mass

### (Preparation of Retardation Plates)

### (1) Formation of Positive C Type Retardation Layer (Alignment Film-Cum-Retardation Layer)

The photo-alignment thermosetting liquid crystal composition was applied onto one surface of a PET substrate (“E5100” manufactured by Toyobo Co., Ltd., thickness 38 μm) by bar coating so that the thickness when cured was 1.6 μm. The applied composition was dried by heating in an oven at 120° C. for one minute to align and thermally cure the liquid crystal component, thereby forming a cured film having retardation. Then, using an Hg—Xe lamp and a Glan-Taylor prism, 100 mJ/cm² of polarized ultraviolet light containing an emission line of 313 nm was applied to the surface of the cured film from the substrate normal in the vertical direction, thereby forming an alignment layer-cum-retardation layer on the substrate, which is the cured film provided with an alignment layer function. As a result of measuring the retardation, it was found that the alignment layer-cum-retardation layer was a positive C type retardation layer.

### (2) Formation of Positive A Type Retardation Layer

A solution was obtained by dissolving the following polymerizable liquid crystal compound (product name: LC242, manufactured by: BASF) in cyclohexanone so as to have a solid content of 15% by mass. To this solution, 5% by mass of a photopolymerization initiator (IRGACURE 184 manufactured by BASF) was added, thereby preparing a polymerizable liquid crystal composition.

The polymerizable liquid crystal composition was applied onto the obtained positive C type retardation layer (alignment layer-cum-retardation layer) by bar coating so that the thickness when cured was 1 μm. The applied composition was dried at 85° C. for 120 seconds to form a coating film. In a nitrogen atmosphere, using an Hg—Xe lamp, 300 mJ/cm² of non-polarized ultraviolet light containing an emission line of 365 nm was applied to the coating film, thereby forming the second retardation layer. Accordingly, a retardation plate was produced. As a result of measuring the retardation, it was found that the second retardation layer was a positive A type retardation layer.

The total thickness of the positive C type retardation layer and the positive A type retardation layer of the retardation plate was 2.6 μm.

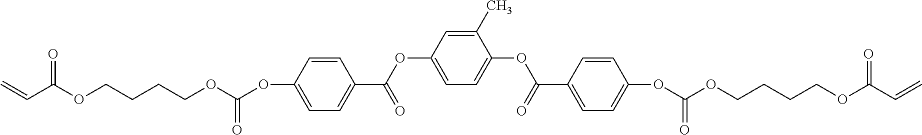 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

### Example III-9

A non-photo-alignment thermosetting liquid crystal composition of the following composition was prepared.
Side-chain liquid crystal polymer III-A2: 0.1 parts by mass
Thermal crosslinking agent (Hexamethoxymethylmelamine (HMM)): 0.01 parts by mass
p-Toluenesulfonic acid monohydrate (PTSA): 0.001 parts by mass
Propylene glycol monomethyl ether (PGME): 0.17 parts by mass
Cyclohexanone: 0.4 parts by mass

The non-photo-alignment thermosetting liquid crystal composition was applied onto one surface of a PET substrate (“E5100” manufactured by Toyobo Co., Ltd., thickness 38 μm) by bar coating so that the thickness when cured was 1.4 μm. The applied composition was dried by heating in an oven at 90° C. for one minute to align and thermally cure the liquid crystal component, thereby forming a retardation layer. Then, the photo-alignment thermosetting liquid crystal composition shown in Example III-1 was applied onto the obtained retardation layer by bar coating so that the thickness when cured was 0.2 μm. The applied composition was dried by heating in an oven at 120° C. for one minute to align and thermally cure the liquid crystal component, thereby forming a cured film having retardation. Then, using an Hg—Xe lamp and a Glan-Taylor prism, 100 mJ/cm² of polarized ultraviolet light containing an emission line of 313 nm was applied to the surface of the cured film from the substrate normal in the vertical direction, thereby forming an alignment layer-cum-retardation layer which is the cured film provided with an alignment layer function. As a result of measuring the retardation, it was found that the thus-obtained stack of the retardation layer and the alignment layer-cum-retardation layer was a positive C type retardation layer.

The polymerizable liquid crystal composition used to form the positive A type retardation layer of Example III-1 was applied onto the obtained alignment layer-cum-retardation layer by bar coating so that the thickness when cured was 1 μm. The applied composition was dried at 85° C. for 120 seconds to form a coating film. In a nitrogen atmosphere, using an Hg—Xe lamp, 300 mJ/cm² of non-polarized ultraviolet light containing an emission line of 365 nm was applied to the coating film, thereby forming the second retardation layer. Accordingly, a retardation plate was produced. As a result of measuring the retardation, it was found that the second retardation layer was a positive A type retardation layer.

The total thickness of the positive C type retardation layer and the positive A type retardation layer of the retardation plate was 2.6 μm.

### Comparative Example III-1

A comparative copolymer III-C1 was synthesized in the same manner as the comparative copolymer C1 of Comparative Example 1 of the Example I series. A retardation plate was produced in the same manner as Comparative Example 1 of the Example I series.

The total thickness of the positive C type retardation layer and the positive A type retardation layer of the retardation plate was 2.6 μm.

### Comparative Example III-2

The liquid crystal 1-1 described in Paragraph 0155 in JP Patent No. 6770634 was applied onto one surface of a triacetyl cellulose (TAC) resin film substrate (“TD80UL” manufactured by FUJIFILM Corporation, thickness 80 μm). Then, aging and ultraviolet irradiation were carried out in the same manner. A positive C type retardation layer was formed in the same manner as the optical anisotropic layer 1 so that the thickness when cured was 1.6 μm. Next, the polymerizable liquid crystal composition used to form the positive A type retardation layer of Example III-1 was applied onto the obtained alignment layer-cum-retardation layer by bar coating so that the thickness when cured was 1 μm. The applied composition was dried at 85° C. for 120 seconds to form a coating film. In a nitrogen atmosphere, using an Hg—Xe lamp, 300 mJ/cm² of non-polarized ultraviolet light containing an emission line of 365 nm was applied to the coating film, thereby forming the second retardation layer. Accordingly, a retardation plate was produced. As a result of measuring the retardation, it was found that the second retardation layer was a positive A type retardation layer.

The total thickness of the positive C type retardation layer and the positive A type retardation layer of the retardation plate was 2.6 μm.

### Evaluation

The obtained retardation plates were evaluated as follows.

### (1) Measurement for the Thickness of Each Retardation Layer

The thickness of each retardation layer was obtained as follows. First, using a scanning transmission electron microscope (STEM) (product name: S-4800, manufactured by: Hitachi High-Technologies Corporation), a cross-sectional image of the retardation layer was taken; in the cross-sectional image, the thicknesses of 10 points of the positive C type retardation layer and those of the positive A type retardation layer were measured; the thickness of each retardation layer was defined as the arithmetic mean value of the thicknesses at the 10 points. More specifically, the cross-sectional image of each retardation layer was taken as follows. First, a sample cut into a size of 1 mm×10 mm was embedded in an embedding resin, thereby forming a block. A thin slice was cut from the block by a general thin slice-cutting method, which was a uniform slice having no pores and having a thickness of 70 nm or more and 100 nm or less. To produce the slice, “ULTRAMICROTOME EM UC7” (manufactured by Leica Microsystems Inc.) and so on were used. Then, the uniform slice having no pores was used as a measurement sample. Then, using the scanning transmission electron microscope (STEM), a cross-sectional image of the measurement sample was taken. To take the cross-sectional image, STEM observation was carried out in the following condition:
Detector: TE
Accelerating voltage: 30 kV
Emission current: 10 μA.
   The magnification was appropriately controlled in a range of from 5,000× to 200,000× by controlling the focus, while monitoring whether or not each layer was able to be distinguished by contrast and brightness.

### (2) Thickness Direction Retardation Rth and In-Plane Retardation Re

A measurement sample was produced by peeling off the substrate from the retardation plate and then transferring the positive C type retardation layer and the positive A type retardation layer to a glass with adhesive in the following order: the positive C type retardation layer/the positive A type retardation layer/the glass with adhesive. The thickness direction retardation Rth and in-plane retardation Re at a wavelength of 550 nm of the measurement sample was measured by a retardation measuring device (“KOBRA-WR” manufactured by Oji Scientific Instruments).

In this Description, the thickness direction retardation Rth and in-plane retardation Re at a wavelength of 550 nm were measured at an incident angle of 0° to 50° in increments of 10°, and the thickness direction retardation Rth and the in-plane retardation Re were calculated from the measurement results at an incident angle of 0° and an incident angle of 40°. Calculation values when the inclined central angle, the average refractive index and the thickness were defined as the slow axis, 1.55, and 1.0 μm, respectively, were used.

### (3) Adhesion

A measurement sample was produced by peeling off the substrate from the retardation plate and then transferring the positive C type retardation layer and the positive A type retardation layer to a glass with adhesive in the following order: the positive C type retardation layer/the positive A type retardation layer/the glass with adhesive. A cross-cut adhesion test was conducted on the measurement sample by a method in accordance with JIS K5400-8.5 (JIS D0202). First, 11 cuts starting from the positive C type retardation layer side to reach the positive A type retardation layer were made in the measurement sample with a cutter knife, followed by making new 11 cuts at an angle of 90 degrees to the original cuts. Sellotape (trade name, (24 mm×35 m CT405AP-24), manufactured by Nichiban Co., Ltd.) was attached to the coating film surface with the cuts. The Sellotape was attached to the coating film surface by rubbing the Sellotape surface with an eraser. After the elapse of one to two minutes, the attached Sellotape was instantly removed by lifting its edge in a direction at right angles to the coating film surface. The ratio of the number of cut parts that remained on the positive C type retardation layer after the removal to the number of cut parts before the removal, was obtained and evaluated by the following criterion.

### (Evaluation Criterion)

A: 90/100 to 100/100
B: 50/100 to 89/100
C: 0/100 to 49/100

### (4) Composite Modulus

The composite modulus of the positive C type retardation layer (the first retardation layer that serve as the alignment layer-cum-retardation layer) was obtained as follows.

First, a measurement sample was produced by peeling off the substrate from the retardation plate and then transferring the positive C type retardation layer and the positive A type retardation layer to a glass with adhesive in the following order: the positive C type retardation layer/the positive A type retardation layer/the glass with adhesive. Using the measurement sample, the indentation hardness of the positive C type retardation layer surface exposed by peeling off the substrate, was measured. The indentation hardness (HIT) measurement was conducted on the measurement sample by use of “TI950 TRIBOINDENTER” manufacture by Bruker Corporation. In the following measurement condition, a Berkovich indenter (a triangular pyramid, “TI-0039” manufactured by Bruker Corporation was vertically pressed into the positive C type retardation layer surface over 10 seconds until a maximum press load of 3 μN was reached. Then, the maximum press load was held for a certain period of time to relax a residual stress. After the load was removed over 10 seconds, the maximum load after relaxing was measured, and the indentation hardness (HIT) was calculated by the formula Pmax/Ap (where Pmax (μN) is the obtained maximum load, and Ap (nm²) is a projected contact area obtained by correcting the tip curvature of the indenter by the Oliver-Pharr method, using fused quartz (“5-0098” manufactured by Bruker Corporation) as a reference sample. When measured values include a value that is deviated from the arithmetic mean value by ±20% or more, the value was excluded, and the measurement was conducted again.

### (Measurement Condition)

Loading speed: 0.3 μN/sec
Load holding time: 5 seconds
Load removal speed: 0.3 μN/sec
Measurement temperature: 25° C.

Next, a composite modulus Er was obtained by the equation (1), using the projected contact area Ap that was obtained above in the measurement of the obtained indentation hardness (HIT) of the positive C type retardation layer. More specifically, the indentation hardness was measured at 10 points, and the composite modulus was also obtained each time. The arithmetic mean value of the obtained composite moduli of the 10 points was defined as the composite modulus.

### (5) Flex Resistance Test

The following dynamic bending test was conducted on the obtained retardation plate to evaluate the flex resistance.

The dynamic bending test method will be described with reference to FIG. 7. First, two moving metal plates 60 (100 mm×30 mm), each of which was made of a moving part 60a and non-moving part 60b, were prepared. They were arranged in parallel so that the distance between the non-moving parts 60b of the two metal plates 60 was 60 mm. As shown in the diagram (A) of FIG. 7, the moving part 60a of each metal plate 60 was bent at a right angle to the non-moving part 60b. A test specimen 70, which was cut into a size of 20 mm×100 mm from the retardation plate, was placed on the moving part 60a so that the slow axis direction of the positive A type retardation layer was in parallel with the two metal plates 60. Both sides of the test specimen 70 were fixed on the moving parts 60a with KAPTON (trade name) tape so that the center of the test specimen 70 was placed at half the distance between the metal plates. Next, the moving part 60a and non-moving part 60b of each metal plate 60 were linearly arranged so that they were in the state shown in the diagram (B) of FIG. 7. More specifically, the test specimen 70, which was bent in the middle of the long side, was sandwiched between the metal plates 60, and the metal plates 60 on both sides were arranged in parallel so that the distance between the metal plates 60 on both sides was 60 mm. While the state of the test specimen 70 was repeatedly and alternately changed to this state and the state in which, as shown in the diagram (C) of FIG. 7, the metal plates 60 on both sides were arranged in parallel so that the distance between the metal plates 60 on both sides was 2.0 mm (in the case of φ2 mm dynamic bending test), the test specimen 70 was repeatedly bent 90 times per minute in a relative humidity (RH) environment at 60° C. and 93%, and the test specimen 70 was repeatedly bent a total of 200,000 times. As a test jig, a constant temperature and humidity environment endurance test system (Tension Free U-shape Folding Test Jig for Planar Objects DMX-FS manufactured by Yuasa System Co., Ltd.) was used.

### EVALUATION CRITERION

A: No breakage and no cracking occurred even after repeated bending of 200,000 times.
B: Breakage or cracking occurred during 200,000 bending cycles.

TABLE 22

| | Side-chain liquid | | Photo-alignment | | | | | | |
|---|---|---|---|---|---|---|---|---|---|
| | crystal polymer | | copolymer | | | | | | φ 2 mm |
| | Used | Mass | Used | Mass | Rth | Re | | Modulus Er | Dynamic |
| | compound | ratio | compound | ratio | (nm) | (nm) | Adhesion | (GPa) | bending test |
| Example III-1 | III-A1 | 90 | III-B1 | 10 | −6 | 139 | A | 5.7 | A |
| Example III-2 | III-A1 | 90 | III-B2 | 10 | −13 | 145 | A | 6.0 | A |
| Example III-3 | III-A1 | 90 | III-B3 | 10 | −12 | 141 | A | 6.3 | A |
| Example III-4 | III-A2 | 90 | III-B1 | 10 | 12 | 167 | A | 6.8 | A |
| Example III-5 | III-A3 | 90 | III-B1 | 10 | 1 | 151 | A | 7.2 | A |
| Example III-6 | III-A2 | 99 | III-B1 | 1 | −24 | 137 | A | 7.0 | A |
| Example III-7 | III-A2 | 70 | III-B1 | 30 | 26 | 162 | A | 6.5 | A |
| Example III-8 | III-A4 | 90 | III-B2 | 10 | 32 | 143 | A | 6.1 | A |
| Example III-9 | III-A1 | 90 | III-B1 | 10 | −22 | 139 | A | 5.8 | A |
| Comparative | III-C1 | 100 | — | — | −9 | 95 | C | 2.9 | B |
| Example 1 | | | | | | | | | |
| Comparative | — | — | — | — | −32 | 142 | B | 9.6 | B |
| Example 2 | | | | | | | | | |

1. A photo-alignment thermosetting liquid crystal composition comprising:
a side-chain liquid crystal polymer (A) which contains a liquid crystal constitutional unit containing a liquid crystal moiety in a side chain and a non-liquid crystal constitutional unit containing an alkylene group in a side chain,
a copolymer (B) which contains a photo-alignment constitutional unit containing a constitutional unit represented by the following formula (1) and a thermally crosslinkable constitutional unit containing a thermally crosslinkable group in a side chain, and
a thermal crosslinking agent (C) for bonding to the thermally crosslinkable group of the thermally crosslinkable constitutional unit: 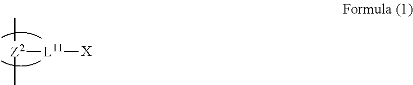
where Z¹ is at least one kind of monomer unit selected from the group consisting of the following formulae (1-1) to (1-6); X is a photo-alignment group; and L¹¹ is a single bond, —O—, —S—, —COO—, —COS—, —CO—, —OCO— or a combination of any of them with an arylene group: 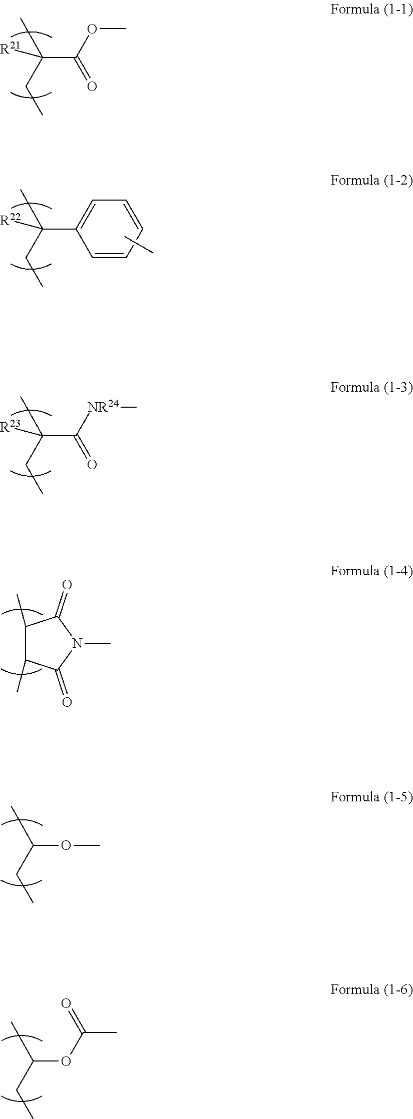
where R²¹ is a hydrogen atom, a methyl group, a chlorine atom or a phenyl group; R²² is a hydrogen atom or a methyl group; R²³ is a hydrogen atom, a methyl group, a chlorine atom or a phenyl group; and R²⁴ is a hydrogen atom or an alkyl group containing 1 to 4 carbon atoms).

2. The photo-alignment thermosetting liquid crystal composition according to claim 1, wherein the photo-alignment group of the copolymer (B) is at least one kind selected from the group consisting of a cinnamoyl group, a chalcone group, a coumarin group, an anthracene group, a quinoline group, an azobenzene group and a stilbene group.

3. The photo-alignment thermosetting liquid crystal composition according to claim 1, wherein the thermally crosslinkable group contains at least one kind selected from the group consisting of a hydroxy group, a carboxy group, a mercapto group, a glycidyl group, an amino group an amide group.

4. The photo-alignment thermosetting liquid crystal composition according to claim 1, wherein the liquid crystal constitutional unit of the side-chain liquid crystal polymer (A) contains a constitutional unit represented by the following formula (I): 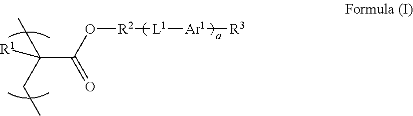
where R¹ is a hydrogen atom or a methyl group; R² is a group represented by —(CH₂)ₘ— or —(C₂H₄O)_{m′}—; L¹ is a single bond or a linking group represented by —O—, —OCO— or —COO—; Ar¹ is an arylene group containing 6 to 10 carbon atoms and optionally containing a substituent; L¹s may be the same or different from each other; Ar¹s may be the same or different from each other; R³ is —F, —Cl, —CN, —OCF₃, —OCF₂H, —NCO, —NCS, —NO₂, —NHCO—R⁴, —CO—OR⁴, —OH, —SH, —CHO, —SO₃H, —NR⁴₂, —R⁵ or —OR⁵; R⁴ is a hydrogen atom or an alkyl group containing 1 to 6 carbon atoms; R⁵ is an alkyl group containing 1 to 6 carbon atoms; a is an integer of from 2 to 4; and m and m′ are each independently an integer of from 2 to 10.

5. The photo-alignment thermosetting liquid crystal composition according to claim 1,
wherein the copolymer (B) contains a thermally crosslinkable constitutional unit containing a constitutional unit represented by the following formula (2), and the side-chain liquid crystal polymer (A) satisfies any of the following (i) to (vi):
(i) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a primary carbon of the alkylene group which optionally contains —O— in its carbon chain and in which a total of a carbon atom number and an oxygen atom number is smaller than a linear alkylene group which contains 4 to 11 carbon atoms and which optionally contains —O— in its carbon chain in the thermally crosslinkable constitutional unit of the copolymer (B);
(ii) the side-chain liquid crystal polymer (A) contains a non-liquid crystal, thermally crosslinkable constitutional unit containing a thermally crosslinkable group and an alkylene group in a side chain, and the non-liquid crystal, thermally crosslinkable constitutional unit of the side-chain liquid crystal polymer (A) has a structure such that the thermally crosslinkable group is bound to a secondary or tertiary carbon of the alkylene group;
(iii) the side-chain liquid crystal polymer (A) contains a non-liquid crystal, thermally crosslinkable constitutional unit containing, in a side chain, an arylene group, an alkylene group and at least one kind of thermally crosslinkable group selected from the group consisting of a hydroxy group, a mercapto group and an amino group, and the non-liquid crystal, thermally crosslinkable constitutional unit of the side-chain liquid crystal polymer (A) has a structure such that the thermally crosslinkable group is bound to the arylene group;
(iv) the side-chain liquid crystal polymer (A) contains a non-liquid crystal, thermally crosslinkable constitutional unit containing an arylene group, an alkylene group and at least one kind of thermally crosslinkable group selected from the group consisting of a carboxy group, a glycidyl group and an amide group; the non-liquid crystal, thermally crosslinkable constitutional unit of the side-chain liquid crystal polymer (A) has a structure such that the thermally crosslinkable group is bound to the arylene group; and the arylene group has a structure such that it is bound to a carbon or oxygen atom of the alkylene group which optionally contains —O— in its carbon chain or at its terminal and in which a total of a carbon atom number and an oxygen atom number is 3 or more smaller than the linear alkylene group which contains 4 to 11 carbon atoms and which optionally contains —O— in the carbon chain in the thermally crosslinkable constitutional unit of the copolymer (B);
(v) the side-chain liquid crystal polymer (A) contains a thermally crosslinkable constitutional unit containing no alkylene group in a side chain and a thermally crosslinkable group in the side chain; and
(vi) the side-chain liquid crystal polymer (A) does not contain a non-liquid crystal, thermally crosslinkable constitutional unit containing a thermally crosslinkable group and an alkylene group in a side chain and a thermally crosslinkable constitutional unit containing a thermally crosslinkable group in a side chain: 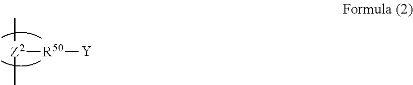
where Z² is at least one kind of monomer unit selected from the group consisting of the following formulae (2-1) to (2-6); R⁵⁰ is a linear alkylene group containing 4 to 11 carbon atoms and optionally containing —O— in its carbon chain; and Y is at least one kind of thermally crosslinkable group selected from the group consisting of a hydroxy group, a carboxy group, a mercapto group, a glycidyl group, an amino group and an amide group: 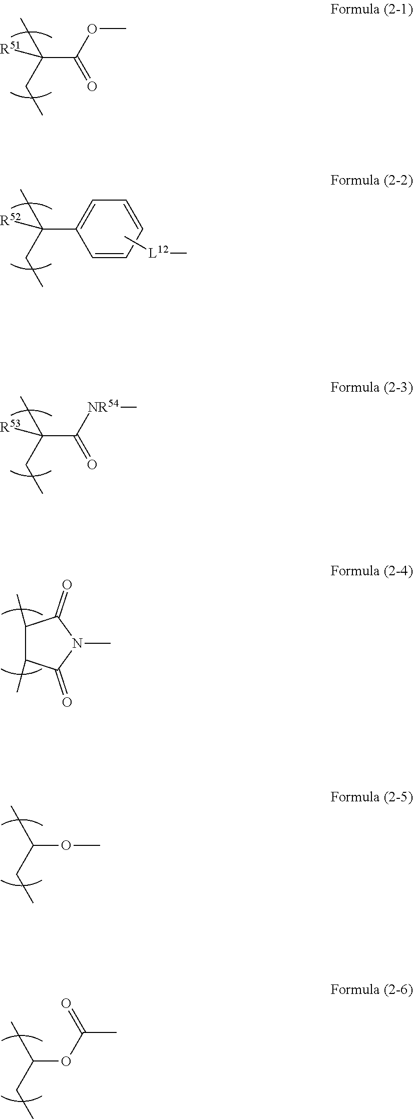
where R⁵¹ is a hydrogen atom, a methyl group, a chlorine atom or a phenyl group; R⁵² is a hydrogen atom or a methyl group; R⁵³ is a hydrogen atom, a methyl group, a chlorine atom or a phenyl group; R⁵⁴ is a hydrogen atom or an alkyl group containing 1 to 4 carbon atoms; L² is a single bond, —O—, —S—, —COO—, —COS—, —CO— or —OCO—; and when L² is a single bond, R⁵⁰ is directly bound to a styrene skeleton.

6. The photo-alignment thermosetting liquid crystal composition according to claim 1, wherein the side-chain liquid crystal polymer (A) contains a non-liquid crystal, thermally crosslinkable constitutional unit, and the non-liquid crystal, thermally crosslinkable constitutional unit contains a constitutional unit represented by the following formula (III): 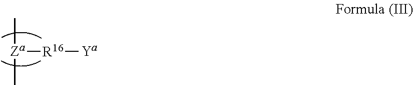
where Z^{a} is at least one kind of monomer unit selected from the group consisting of the following formulae (a-1) to (a-6); R¹⁶ is a group represented by -L²-R^{13′}— (where L^{2a} is a linear or branched alkylene group which contains 1 to 10 carbon atoms and which optionally contains —O— in its carbon chain; R^{13′} is —OR^{15′}, a residue obtained by removal of a hydrogen atom from an aryl group, or a residue obtained by removal of a hydrogen atom from a methyl group which optionally contains a substituent; and R^{15′} is a residue obtained by removal of a hydrogen atom from an aryl group); and Y^{a} is at least one kind of thermally crosslinkable group selected from the group consisting of a hydroxy group, a carboxy group, a mercapto group, a glycidyl group, an amino group and an amide group: 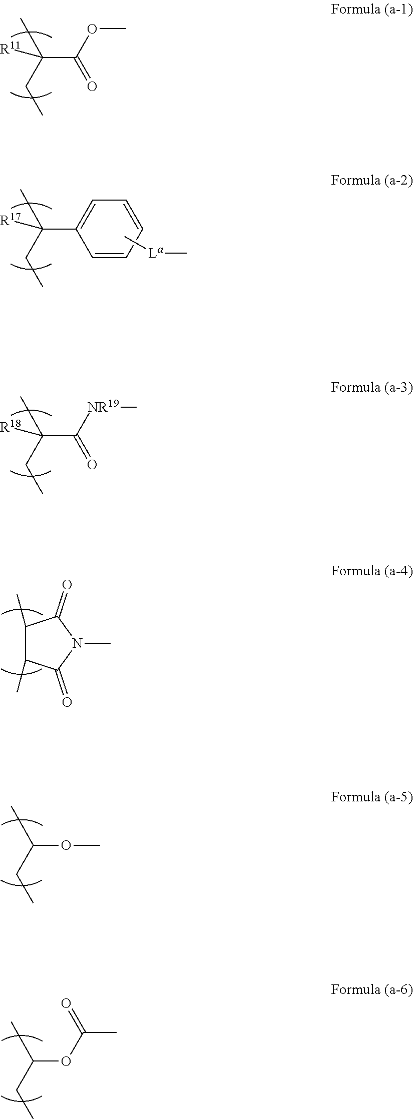
where R¹¹ is a hydrogen atom, a methyl group, a chlorine atom or a phenyl group; R¹⁷ is a hydrogen atom or a methyl group; R¹⁸ is a hydrogen atom, a methyl group, a chlorine atom or a phenyl group; R¹⁹ is a hydrogen atom or an alkyl group containing 1 to 4 carbon atoms; L^{a} is a single bond, —O—, —S—, —COO—, —COS—, —CO— or —OCO—; and when L^{a} is a single bond, R¹⁶ is directly bound to a styrene skeleton.

7. An alignment film-cum-retardation film comprising an alignment layer-cum-retardation layer,
wherein the alignment layer-cum-retardation layer is a cured film of the photo-alignment thermosetting liquid crystal composition defined by claim 1.

8. A method for producing an alignment film-cum-retardation film, the method comprising:
forming the photo-alignment thermosetting liquid crystal composition defined by claim 1 into a film,
forming a cured film having retardation by heating the thermosetting liquid crystal composition formed into the film, and
providing a liquid crystal aligning ability to the cured film having retardation by irradiating the cured film with polarized ultraviolet light.

9. A retardation plate comprising a first retardation layer and a second retardation layer,
wherein the first retardation layer is a cured film of the photo-alignment thermosetting liquid crystal composition defined by claim 1, and
wherein the second retardation layer is located directly adjacent to the first retardation layer and contains a cured product of a polymerizable liquid crystal composition.

10. The retardation plate according to claim 9, wherein the first retardation layer and the second retardation layer are a positive C type retardation layer and a positive A type retardation layer, respectively.

11. The retardation plate according to claim 9, wherein a thickness direction retardation Rth at a wavelength of 550 nm is from −35 nm to 35 nm, and a total thickness of the first retardation layer and the second retardation layer is from 0.2 μm to 6 μm.

12. The retardation plate according to claim 9, further comprising a third retardation layer different from the first retardation layer,
wherein the third retardation layer, the first retardation layer and the second retardation layer are located in this order directly adjacent to each other, and
wherein the third retardation layer, the first retardation layer and the second retardation layer are a positive C type retardation layer, a positive C type retardation layer, and a positive A type retardation layer, respectively.

13. A method for producing a retardation plate, the method comprising:
forming the photo-alignment thermosetting liquid crystal composition defined claim 1 into a film,
forming a cured film having retardation by heating the thermosetting liquid crystal composition formed into the film,
forming an alignment film-cum-first retardation layer by providing a liquid crystal aligning ability to the cured film having retardation by irradiating the cured film with polarized ultraviolet light,
aligning liquid crystal molecules by the alignment film-cum-first retardation layer, by forming a coating film of a polymerizable liquid crystal composition by applying the polymerizable liquid crystal composition onto the alignment film-cum-first retardation layer and heating the coating film to a phase transition temperature of the polymerizable liquid crystal composition, and
forming a second retardation layer by curing the coating film of the polymerizable liquid crystal composition, in which the liquid crystal molecules are aligned, by light irradiation.

14. A retardation plate comprising a positive C type retardation layer and a positive A type retardation layer,
wherein the positive C type retardation layer is a cured product of a thermosetting liquid crystal composition containing a photo-alignment component and a thermal crosslinking agent, and
wherein the positive A type retardation layer is located directly adjacent to the positive C type retardation layer and contains a cured product of a polymerizable liquid crystal composition.

15. The retardation plate according to claim 14, wherein a thickness direction retardation Rth at a wavelength of 550 nm is from −35 nm to 35 nm; an in-plane retardation Re at a wavelength of 550 nm is 100 nm or more; and a total thickness of the positive C type retardation layer and the positive A type retardation layer is from 0.2 μm to 6 μm.

16. The retardation plate according to claim 14, wherein a composite modulus of the positive C type retardation layer is 4.5 GPa or more and 9.0 GPa or less.

17. The retardation plate according to claim 14, further comprising a substrate,
wherein the substrate is located directly adjacent to the positive C type retardation layer.

18. The retardation plate according to claim 14, wherein the positive C type retardation layer contains a region which is permeated with a specific component contained in the positive A type retardation layer.

19. The retardation plate according to claim 18, wherein the specific component contains a polymerizable liquid crystal compound or a cured product thereof.

20. A method for forming a retardation plate, the method comprising:
forming, into a film, a photo-alignment thermosetting liquid crystal composition comprising:
a side-chain liquid crystal polymer which contains a liquid crystal constitutional unit containing a liquid crystal moiety in a side chain,
a copolymer which contains a photo-alignment constitutional unit and a thermally crosslinkable constitutional unit containing a thermally crosslinkable group in a side chain, and
a thermal crosslinking agent for bonding to the thermally crosslinkable group of the thermally crosslinkable constitutional unit,
forming a cured film having retardation by heating the thermosetting liquid crystal composition formed into the film,
forming a positive C type retardation layer provided with a liquid crystal aligning ability by irradiating the cured film having retardation with polarized ultraviolet light,
aligning liquid crystal molecules by the positive C type retardation layer, by forming a coating film of a polymerizable liquid crystal composition by applying the polymerizable liquid crystal composition onto the positive C type retardation layer and heating the coating film to a phase transition temperature of the polymerizable liquid crystal composition, and
forming a positive A type retardation layer by curing the coating film of the polymerizable liquid crystal composition, in which the liquid crystal molecules are aligned, by light irradiation.

21. An optical member comprising the retardation plate defined by claim 9 and a polarizing plate.

22. A method for producing an optical member, the method comprising:
preparing a polarizing plate,
preparing the retardation plate defined by claim 9, and
stacking the retardation plate and the polarizing plate.

23. A display device comprising the retardation plate defined by claim 9 comprising an optical member comprising the retardation plate and a polarizing plate.

24. An optical member comprising the retardation plate defined by claim 14 and a polarizing plate

25. A method for producing an optical member, the method comprising:
preparing a polarizing plate,
preparing the retardation plate defined by claim 14, and
stacking the retardation plate and the polarizing plate.

26. A display device comprising the retardation plate defined by claim 14 or comprising an optical member comprising the retardation plate and a polarizing plate.
